(19) United States
(12) Patent Application Publication
(10) Pub. No.: US 2010/0218984 A1
(43) Pub. Date: Sep. 2, 2010

(54) PHOTOSENSITIVE DRY FILM RESIST, PRINTED WIRING BOARD MAKING USE OF THE SAME, AND PROCESS FOR PRODUCING PRINTED WIRING BOARD

(76) Inventors: Toshio Yamanaka, Osaka (JP); Koji Okada, Shiga (JP); Kohei Kojima, Osaka (JP); Hitoshi Nojiri, Shiga (JP)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 12/223,196

(22) PCT Filed: Jan. 23, 2007
(86) PCT No.: PCT/JP2007/051011

§ 371 Date: Jul. 23, 2008

(30) Foreign Application Priority Data
Jan. 25, 2006 (JP) 2006 016392
May 30, 2006 (JP) 2006 150252
Jun. 21, 2006 (JP) 2006 171927

(51) Int. Cl. H05K 1/00; G03F 7/004

(52) U.S. Cl. 174/258; 430/286.1

(57) ABSTRACT

The present invention is to provide (i) a photosensitive dry film resist which allows water system development and which is excellent in resolution, flame retardancy, adhesiveness, moisture resistance, electric reliability, and preservation stability, (ii) a method for producing the photosensitive dry film resist, and (iii) usage thereof.

The foregoing object can be achieved by using a multi-layer photosensitive dry film resist comprising at least: a first photosensitive layer which essentially includes a binder polymer (A1), a (meth)acrylic compound (B1), a photoreaction initiator (C1), and a flame retardant (D1), and a second photosensitive layer which essentially includes a binder polymer (A2), a (meth)acrylic compound (B2), a photoreaction initiator (C2) and which substantially does not include a flame retardant (D2), wherein: when a weight ratio of the flame retardant (D1) to an entire weight of the first photosensitive layer is defined as a first photosensitive layer flame retardant content and a weight ratio of the flame retardant (D2) to an entire weight of the second photosensitive layer is defined as a second photosensitive layer flame retardant content, the second photosensitive layer flame retardant content is 0 wt % or more and 10 wt % or less, and in case where the first photosensitive layer flame retardant content is 100, the second photosensitive layer flame retardant content is 0 wt % or more and 50 wt % or less.

### TECHNICAL FIELD

The present invention relates to a photosensitive dry film resist, a printed wiring board using the same, and a production method of the printed wiring board. Particularly, the present invention relates to (i) a photosensitive dry film resist which allows water system development and is excellent in resolution, flame retardancy, adhesiveness, moisture resistance, and electric reliability, (ii) a printed wiring board using the photosensitive dry film resist, and (iii) a production method of the printed wiring board.

### BACKGROUND ART

Recently, with improvement in performances and decrease in sizes and weights of electronic devices, electronic components used in these electronic devices are required to have smaller sizes and smaller thickness. Thus, it is required to install a semiconductor element or the like on a printed wiring board in a high density manner, to make wires finer, and to make the printed wiring board multi-layered in order to improve functions and performances of the electronic components. In order to support finer wirings, it is necessary to use an insulative material having high electric insulation property for protecting the wirings.

In producing the printed wiring board, a photosensitive material is used in various manners. That is, the photosensitive material is used in (i) formation of circuit patterned on the printed wiring board (pattern circuit), (ii) formation of a protection layer for protecting a surface and the pattern circuit of the printed wiring board, (iii) formation of an insulation layer between layers in case where the printed wiring board has a plurality of layers, (iv) and the like.

For example, in forming a protection layer for protecting a surface and the pattern circuit of the printed wiring board, use of the photosensitive material results in the following advantages. A polymer film referred to as a cover lay film is combined with a surface of a flexible print circuit board (hereinafter, referred to as “FPC”) so as to protect a conductive surface. In combining the FPC with the cover lay film, it is general to use an epoxy adhesive or an acrylic adhesive. However, use of such adhesive results in problems such as (1) insufficient solder heat resistance, insufficient bonding strength at high temperature, (2) insufficient flexibility, and the like. Thus, in case of combining the cover lay film with the conductive surface with an adhesive, it is impossible to sufficiently make use of a performance of the polyimide film.

Further, in case of combining the cover lay film with the FPC with the foregoing adhesives, it is necessary to substantially manually position the cover lay film on the FPC. This is not preferable in terms of workability and positional accuracy, and the manufacturing cost increases.

In order to improve the workability and the positional accuracy, conventionally, (i) a method in which a protection layer is formed by applying a photosensitive resin composition solution to the conductive surface of the FPC and then drying, (ii) a method in which a film-shaped photosensitive dry film resist (referred to also as a photosensitive cover lay film) is laminated, and (iii) a similar method have been developed. Exposure and development are carried out by placing a photo mask on the photosensitive resin layer formed by these methods, so that the workability and the positional accuracy are improved.

As described above, examples of the photosensitive material include a liquid photosensitive material and a film-shaped photosensitive material. Above all, the film-shaped photosensitive material has such advantage that its thickness evenness and workability are more excellent than those of the liquid photosensitive material. Thus, various kinds of film-shaped photosensitive materials are used according to purpose of use. Examples thereof include: a pattern circuit resist film used to form a pattern circuit (a photosensitive dry film resist used to form a pattern circuit); a photosensitive cover lay film used to form the protection layer; a photosensitive dry film resist used to form the interlayer insulation layer; and the like.

As the photosensitive cover lay film and the photosensitive dry film resist (hereinafter, both of them are generically referred to as a photosensitive dry film resist), acrylic films are focused at present, but there is such a problem that the film is inferior in flame retardancy, so that use thereof is limited.

In view of improvement of the flame retardancy, there is proposed a photosensitive dry film resist produced by curing a photosensitive resin composition containing a bromic flame retardant (for example, Patent Document 1 and the like). However, the flame retardant containing halogen may have an unfavorable influence on the environment, the halogen-free flame retardant is being studied instead of the bromic flame retardant.

Examples of the halogen-free flame retardant include nitrogenous, phosphorus, and similar flame retardants. However, the nitrogenous compound is hard to practically use in view of its influence on a curing property of resin, and the phosphorus compound is likely to increase hygroscopic property of a resin composition, so that this raises such problem that the moisture resistance and electric reliability drop (see Patent Document 2 and the like for example).

While, there is proposed a method in which a resin layer having moisture resistance and a resin layer having flame retardancy are laminated so as to realize both the moisture resistance and the flame retardancy. However, this is not photosensitive, so that this laminate is not suitable for microfabrication. Thus, the method is applied to other field (see Patent Documents 3 and 4 and the like for example).

Further, also the photosensitive film field includes a multi-layer film, but its object is to improve the photosensitive property and is not to improve the flame retardancey, the moisture resistance, and the electric reliability (see Patent Document 5 and the like for example). Patent Document 5 describes a photosensitive transfer sheet made up of (i) two photosensitive layers different from each other in photosensitivity and (ii) a barrier layer. As its effect, it is described that desired patterns different from each other in thickness can be easily formed in an image.

Incidentally, as the photosensitive dry film resist, an acrylic resin is conventionally used. However, a photosensitive dry film resist or the like which is made of acrylic resin fails to realize sufficient heat resistance and sufficient mechanical strength of the film. Thus, there is proposed an arrangement in which, out of various kinds of organic polymers for improving the heat resistance and the mechanical strength of the film, photosensitive polyimide containing polyimide having excellent heat resistance is used for a photosensitive dry film resist or the like.

As the photosensitive polyimide, various compositions have been studied to be used mainly for a semiconductor, and there are reported: ion-linked photosensitive polyimide obtained by mixing a compound having tertiary amine and (meth)acryloyl group with polyamide acid (polyimide precursor); ester-linked photosensitive polyimide obtained by introducing a methacroyl group into a carboxyl group of polyamide acid via an ester bond; photosensitive polyimide obtained by introducing an isocyanate compound having a methacroyl group into a carboxyl group part of polyamide acid (polyimide precursor); photosensitive polyimide obtained by mixing polyamide acid with (meth)acrylic compound; and the like.

It is reported that, above all, photosensitive polyimide (see Patent Documents 6 to 9 and the like) obtained by mixing polyamide acid with (meth)acrylic compound is used as a photosensitive resin composition in producing a dry film for an FPC cover lay material. Each of Patent Document 6 to 9 reports that use of photosensitive polyimide obtained by mixing polyamide acid with (meth)acrylic compound allows for development with alkaline aqueous solution which is more preferable than organic solvent in view of safety in operations, and allows a membrane to be sufficiently cured after exposure, and allows for an excellent stretching property, and results in a similar effect.

Further, in order to improve the flexibility and the bendability of the dry film used as the FPC cover lay material, there is proposed a photosensitive resin composition containing (i) polyamide acid made of polysiloxane diamine and (ii) (meth)acrylic compound (see Patent Document 10 and a similar document for example).
[Patent Document 1]

Japanese Unexamined Patent Publication Tokukai 2001-335619 (Publication date: Dec. 4, 2001)
[Patent Document 2]

Japanese Unexamined Patent Publication Tokukai 2000-241969 (Publication date: Sep. 8, 2000)
[Patent Document 3]

Japanese Unexamined Patent Publication Tokukai 2004-311573 (Publication date: Nov. 4, 2004)
[Patent Document 4]

Japanese Unexamined Patent Publication Tokukai 2005-161778 (Publication date: Jun. 23, 2005)
[Patent Document 5]

Japanese Unexamined Patent Publication Tokukai 2005-202066 (Publication date: Jul. 28, 2005)
[Patent Document 6]

Japanese Unexamined Patent Publication Tokukaihei 11-52569 (Publication date: Feb. 26, 1999)
[Patent Document 7]

Japanese Unexamined Patent Publication Tokukai 2001-5180 (Publication date: Jan. 12, 2001)
[Patent Document 8]

Japanese Unexamined Patent Publication Tokukai 2004-29702 (Publication date: Jan. 29, 2004)
[Patent Document 9]

Japanese Unexamined Patent Publication Tokukai 2000-98604 (Publication date: Apr. 7, 2000)
[Patent Document 10]

Japanese Unexamined Patent Publication Tokukai 2004-361883 (Publication date: Dec. 24, 2004)

### DISCLOSURE OF INVENTION

### Problems to be Solved by the Invention

However, each of the aforementioned photosensitive dry film resists does not have sufficient performance, and a photosensitive dry film resist which satisfies all the developing properties in water system development, i.e., excellent resolution, flame retardancy, adhesiveness, moisture resistance, and electric reliability, has not been produced yet.

As described above, there is reported a photosensitive resin composition obtained by introducing a phosphorous flame retardant into polyamide acid and (meth)acrylic compound so as to enhance the flame retardancy. Such a photosensitive resin composition allows for enhancement of flame retardancy by introduction of the flame retardant. However, in case of using a phosphorous compound as the flame retardant, this raises such problem that the resin composition is likely to have a higher hygroscopic property and a lower moisture resistance and further have lower electric reliability.

Further, the photosensitive resin composition described in Patent Document 10 and containing (i) polyamide acid made of polysiloxane diamine and (ii) (meth)acrylic compound is improved in the flexibility and the bendability, but the flame retardancy of the resultant polyimide made of polyamide acid is insufficient, which results in such problem that a large amount of flame retardant is required, so that its electric reliability drops.

Note that, each of Patent Documents 3 and 4 proposes a method in which a resin layer having moisture resistance and a resin layer having flame retardancy are laminated so as to realize both the moisture resistance and the flame retardancy, but this technique does not cover the photosensitive resin, so that the method is not suitable for microfabrication.

Further, also in the photosensitive film field, there are reports on a multi-layer film whose object is to improve the photosensitivity, but the film is not to improve the flame retardancey, the moisture resistance, and the electric reliability.

The present invention is to provide (i) a photosensitive dry film resist which allows water system development and is excellent in resolution, flame retardancy, adhesiveness, moisture resistance, and electric reliability, and (ii) use thereof.

### Means to Solve the Problems

The present invention is a multi-layer photosensitive dry film resist, comprising at least: a first photosensitive layer which essentially includes a binder polymer (A1), a (meth)acrylic compound (B1), a photoreaction initiator (C1), and a flame retardant (D1); and a second photosensitive layer which essentially includes a binder polymer (A2), a (meth)acrylic compound (B2), and which substantially does not include a flame retardant (D2), wherein: when a weight ratio of the flame retardant (D1) to an entire weight of the first photosensitive layer is defined as a first photosensitive layer flame retardant content and a weight ratio of the flame retardant (D2) to an entire weight of the second photosensitive layer is defined as a second photosensitive layer flame retardant content, the second photosensitive layer flame retardant content is 0 wt % or more and 10 wt % or less, and in case where the first photosensitive layer flame retardant content is 100, the second photosensitive layer flame retardant content is 0 wt % or more and 50 wt % or less.

Further, it is preferable to arrange the multi-layer photosensitive dry film resist so that the second photosensitive layer includes a photoreaction initiator (C2) as an essential component.

Further, it is preferable to arrange the multi-layer photosensitive dry film resist so that the second photosensitive layer is an outermost layer of a multiplayer structure, and it is preferable that the first photosensitive layer serves as the other outermost layer. Further, it is preferable that a phosphorus compound is used as the flame retardant (D1) and/or the flame retardant (D2).

It is preferable to arrange the multi-layer photosensitive dry film resist according to the present invention so that a phosphorus compound is used as the flame retardant (D1) and/or the flame retardant (D2).

Further, it is preferable that vinyl polymer containing carboxyl group is used as the binder polymer (A1) and/or the binder polymer (A2). Further, it is preferable that polyamide acid is used as the binder polymer (A1) and/or the binder polymer (A2). It is more preferable that polyamide acid partially made of polysiloxane diamine represented by formula (1) is used as the binder polymer (A1) and the binder polymer (A2),

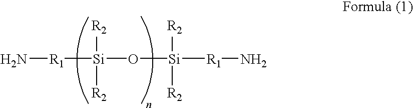

where each R₁ independently represents a hydrocarbon whose carbon number is 1 to 5, and each R₂ independently represents an organic group selected from an alkyl group whose carbon number is 1 to 5 and a phenyl group, and n represents an integer from 1 to 20.

Further, it may be so arranged that polyamide acid having a constitutional unit represented by formula (2) and a constitutional unit represented by formula (3) is used as the binder polymer (A1) and/or the binder polymer (A2),

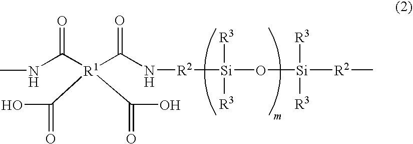

where R¹ represents a tetravalent organic group, each R² independently represents an alkylene group whose carbon number is 2 to 5, and each R³ independently represents a methyl group or a phenyl group, and a content of the phenyl group in R³ is 15% or more and 40% or less, and m is an integer of 4 or more and 20 or less,

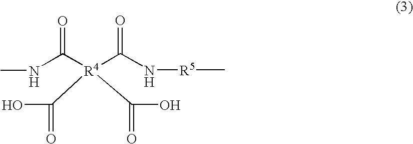

where R⁴ represents a tetravalent organic group, and R⁵ represents a bivalent organic group obtained by excluding two amino groups from aromatic diamine.

The photosensitive dry film resis according to the present invention may be arranged so that the polyamide acid further has a structure represented by formula (4)

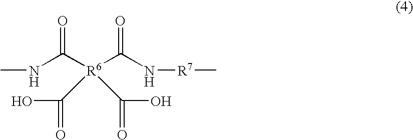

where R⁶ represents a tetravalent organic group and R⁷ has a constitutional unit represented by formula a, b, c, d, e, f, or g,

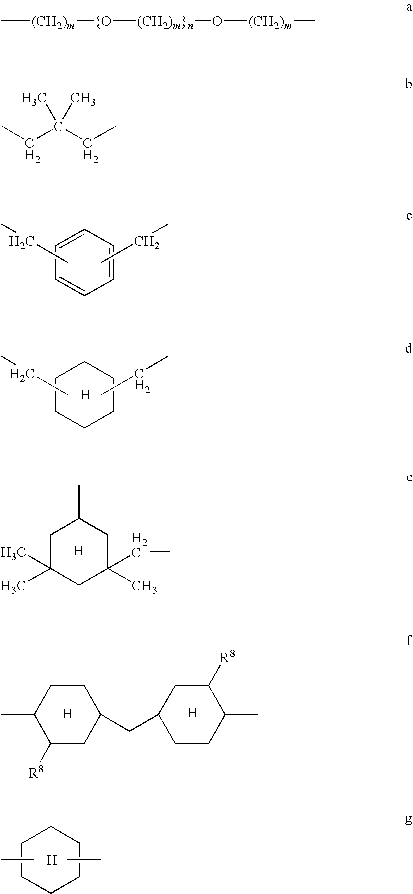

where m of the formula a represents an integer ranging from 1 to 20, n of the formula a represents an integer ranging from 0 to 10, R⁸ of the formula f represents a hydrogen atom, a methyl group, an ethyl group, or a butyl group.

Further, it is preferable that polyamide acid having a constitutional unit represented by formula (4) and a constitutional unit represented by formula (3) is used as the binder polymer (A1) and/or the binder polymer (A2),

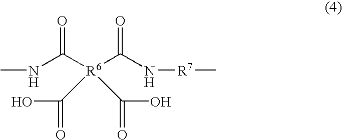

where R⁶ represents a tetravalent organic group and R⁷ has a constitutional unit represented by formula a, b, c, d, e, f, or g,

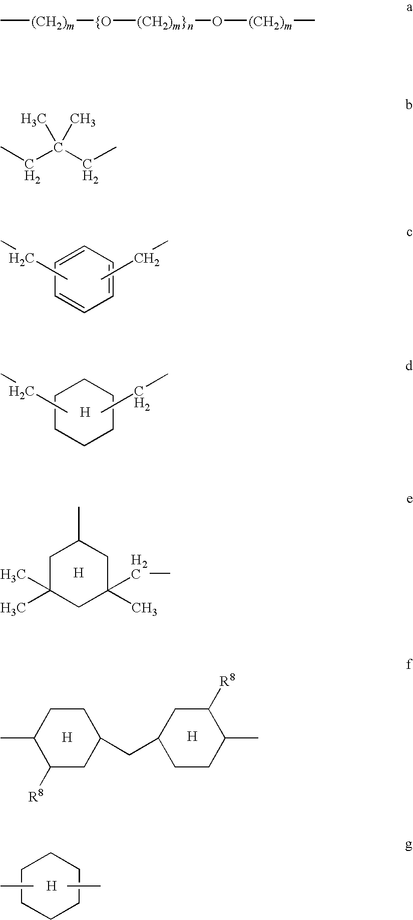

where m of the formula a represents an integer ranging from 1 to 20, n of the formula a represents an integer ranging from 0 to 10, R⁸ of the formula f represents a hydrogen atom, a methyl group, an ethyl group, or a butyl group,

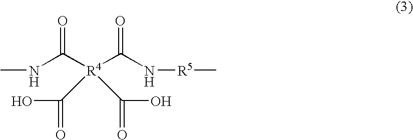

where R⁴ represents a tetravalent organic group, and R⁵ represents a bivalent organic group obtained by excluding two amino groups from aromatic diamine.

It is preferable to arrange the multi-layer photosensitive dry film resist according to the present invention so that the constitutional unit represented by the formula (3) includes a constitutional unit in which at least one of aromatic rings bound to the two amino groups of the aromatic diamine in R⁵ of the formula (3) has two bonds at a meta position with respect to a main chain.

It is preferable that the aromatic diamine is m-phenylene diamine, 3,3′-diaminodiphenylmethane, 3,3′-diaminodiphenylether, 3,3′-diaminodiphenylsulfide, 3,3′-diaminodiphenylsulfone, 3,3′-diamino benzanilide, 2,2-bis(3-aminophenyl)hexafluoropropane, 2,2-bis[4-(3-aminophenoxy)phenyl]propane, 2,2 -bis[4-(3-aminophenoxy)phenyl]sulfone, 2,2-bis[4-(3-aminophenoxy)phenyl]hexafluoropropane, 1,4-bis(3-aminophenoxy) benzene, 4,4′-bis(3-aminophenoxy)-biphenyl, 1,3-bis(3-aminophenoxy)benzene, bis[4-(3-aminophenoxy)phenyl]sulfone, or 2,2-bis(3-aminophenyl)propane.

Further, it is preferable that soluble polyimide containing carboxyl group and/or hydroxyl group is used as the binder polymer (A1) and/or the binder polymer (A2), and it is more preferable that soluble polyimide containing carboxyl group and/or hydroxyl group which soluble polyimide is partially made of polysiloxane diamine represented by formula (1) is used as the binder polymer (A1) and/or the binder polymer (A2),

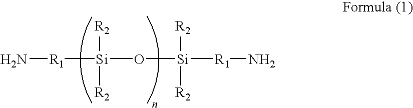

where each R₁ independently represents a hydrocarbon whose carbon number is 1 to 5, and each R₂ independently represents an organic group selected from an alkyl group whose carbon number is 1 to 5 and a phenyl group, and n represents an integer from 1 to 20.

Further, it is preferable that: when a thickness of the first photosensitive layer is regarded as 100, a thickness of the second photosensitive layer is 500 or less.

Another invention of the present invention is a printed wiring board, comprising the aforementioned multi-layer photosensitive dry film resist as an insulating protection layer.

Further, it is preferable that the photosensitive dry film resist which is a part constituting the printed wiring board is such that the second photosensitive layer serves as an outermost layer which is in contact with a circuit face and the first photosensitive layer serves as the other outermost layer.

In order to solve the foregoing problems, a method according to the present invention for producing a printed wiring board, comprising the step of curing the aforementioned photosensitive dry film resist at 180° C. so as to form an insulating protection layer.

### Effects of the Invention

As described above, the multi-layer photosensitive dry film resist according to the present invention comprises at least: a first photosensitive layer which essentially includes a binder polymer (A1), a (meth)acrylic compound (B1), a photoreaction initiator (C1), and a flame retardant (D1); and a second photosensitive layer which essentially includes a binder polymer (A2), a (meth)acrylic compound (B2), and which substantially does not include a flame retardant (D2), wherein: when a weight ratio of the flame retardant (D1) to an entire weight of the first photosensitive layer is defined as a first photosensitive layer flame retardant content and a weight ratio of the flame retardant (D2) to an entire weight of the second photosensitive layer is defined as a second photosensitive layer flame retardant content, the second photosensitive layer flame retardant content is 0 wt % or more and 10 wt % or less, and in case where the first photosensitive layer flame retardant content is 100, the second photosensitive layer flame retardant content is 0 or more and 50 or less. Thus, the photosensitive dry film resist allows favorable water system development and is excellent in flame retardancy, adhesiveness, moisture resistance, and electric reliability. Further, the photosensitive dry film resist has a multi-layer structure, so that the photosensitive dry film resist is excellent also in photosensitivity such as resolution.

Therefore, the present invention is applicable not only to an industry for producing a printed wiring board such as FPC, e.g., a resin industrial field for producing resin material for electronic components, but also to an industrial field of electronic devices using such printed wiring board.

### BRIEF DESCRIPTION OF DRAWINGS

FIG. 1 is a schematic illustrating a comb-shape pattern (line/space=100 μm/100 μm) formed on a flexible copper-clad laminate in a method for evaluating electric reliability of Examples.

FIG. 2 is a schematic illustrating a comb-shape pattern (line/ space=25 μm/25 μm) formed on a flexible copper-clad laminate in a method for evaluating electric reliability of Examples.

### BEST MODE FOR CARRYING OUT THE INVENTION

The present inventors diligently studied the foregoing problems. As a result, they found that: when a photosensitive dry film resist is arranged so as to have a multi-layer structure including a first photosensitive layer containing a flame retardant and a second photosensitive layer containing no or a small amount of flame retardant and these layers are laminated so that the second photosensitive layer is in contact with the side contacting a laminated plate having a circuit thereon, this arrangement results in a photosensitive dry film resist which is excellent in both the flame retardancy and the electric reliability. Also, they found that, amazingly, the resultant photosensitive dry film resist realizes not only the flame retardancy and the electric reliability but also improvement of the photosensitivity unlike a single-layer structure.

As to a photosensitive dry film resist according to the present invention and a printed wiring board using the same, (I) Photosensitive dry film resist, (II) Manufacturing method of photosensitive dry film resist, and (III) Printed wiring board will be described in this order.

### (I) Photosensitive Dry Film Resist

### (I-1) Photosensitive Dry Film Resist

The photosensitive dry film resist according to the present invention is a multi-layer photosensitive dry film resist including at least a first photosensitive layer and a second photosensitive layer.

Note that, in the present specification, the multi-layer structure is a structure including two or more layers. Thus, the multi-layer photosensitive dry film resist according to the present invention may have a two-layer structure including a first photosensitive layer and a second photosensitive layer or may have a structure in which any other layer is further laminated.

The multi-layer photosensitive dry film resist according to the present invention comprises at least: a first photosensitive layer which essentially includes a binder polymer (A1), a (meth)acrylic compound (B1), a photoreaction initiator (C1), and a flame retardant (D1); and a second photosensitive layer which essentially includes a binder polymer (A2), a (meth)acrylic compound (B2), and which substantially does not include a flame retardant (D2), wherein: when a weight ratio of the flame retardant (D1) to an entire weight of the first photosensitive layer is defined as a first photosensitive layer flame retardant content and a weight ratio of the flame retardant (D2) to an entire weight of the second photosensitive layer is defined as a second photosensitive layer flame retardant content, the second photosensitive layer flame retardant content is 0 wt % or more and 10 wt % or less, and in case where the first photosensitive layer flame retardant content is 100, the second photosensitive layer flame retardant content is 0 or more and 50 or less. Note that, it is preferable that the second photosensitive layer essentially includes a photoreaction initiator (C2). Further, in the photosensitive dry film resist, the second photosensitive layer is laminated so as to be in contact with the side contacting a copper-clad laminate having a circuit thereon (this plate is referred to also as “CCL with circuit”). Further, it is preferable that the first photosensitive layer is positioned outermost from the CCL side.

Herein, the phrase “substantially does not include a flame retardant (D2)” means that the flame retardant (D2) is not included at all or a small amount of the flame retardant (D2) is included. Specifically, the amount is such that the foregoing condition is satisfied, that is, the second photosensitive layer flame retardant content is 0 wt % or more and 10 wt % or less, and in case where the the first photosensitive layer flame retardant content is 100, the second photosensitive layer flame retardant content is 0 or more and 50 or less. In other words, the second photosensitive layer flame retardant content is 0 wt % or more and 10 wt % or less and 0 (second photosensitive layer flame retardant content)/(first photosensitive layer flame retardant content) 0.5.

In the multi-layer photosensitive dry film resist of the present invention, the first photosensitive layer flame retardant content is increased to give the flame retardancy and the second photosensitive layer flame retardant content is decreased or the flame retardant is not included in the second photosensitive layer at all so as to improve the moisture resistance and the electric reliability. Further, a residue hardly occurs at the time of alkaline development, so that it is possible to enhance the developing property and the resolution.

This arrangement allows the entire photosensitive dry film resist to have a favorable water system developing property and be excellent in flame retardancy, adhesiveness, moisture resistance, and electric reliability.

The second photosensitive layer flame retardant content may be set to any value as long as the second photosensitive layer flame retardant content is 0 wt % or more and 10 wt % or less, but it is more preferable that the second photosensitive layer flame retardant content is smaller, and it is more preferable that the second photosensitive layer flame retardant content is 5 wt % or less, and it is still more preferable that the second photosensitive layer flame retardant content is 1 wt % or less. If the second photosensitive layer flame retardant content is 10 wt % or less, it is possible to further enhance the resolution, the moisture resistance, and the electric reliability. Further, the second photosensitive layer flame retardant content may be set in any manner as long as (second photosensitive layer flame retardant content)/(first photosensitive layer flame retardant content) is 0 or more and 0.5 or less, but it is more preferable that this ratio is 0.2 or less, and it is still more preferable that the ratio is 0.1 or less, and it is particularly preferable that the ratio is 0.05 or less. When (second photosensitive layer flame retardant content)/(first photosensitive layer flame retardant content) is set to 0.5 or less, it is possible to give the sufficient flame retardancy to the entire photosensitive dry film resist as long as the second photosensitive layer flame retardant content is in the foregoing range.

Note that, in the present invention, the flame retardant content is a weight ratio of the flame retardant which occupies in entire components of each layer constituting the photosensitive dry film resist, and the flame retardant content is calculated in accordance with the following expression. Note that, in case where D2, C2, E1, and E2 do not exist, the calculation is carried out with the weight regarded as 0. Further, E1 and E2 represent all components other than A to D components.

First photosensitive layer Flame retardant content (wt %)=(weight of the flame retardant (D1)÷{(weight of the binder polymer (A1))+(weight of the (meth)acrylic compound (B1))+(weight of the photoreaction initiator (C1))+(weight of the flame retardant (D1))+(other component (E1))×100

Second photosensitive layer flame retardant content (wt %)=(weight of the flame retardant (D2)÷{(weight of the binder polymer (A2))+(weight of the (meth)acrylic compound (B2))+(weight of the photoreaction initiator (C2))+(weight of the flame retardant (D2))+(other component (E2))×100

As described above, the photosensitive dry film resist according to the present invention is a multi-layer photosensitive dry film resist including at least the first photosensitive layer and the second photosensitive layer, wherein the first and second photosensitive layers respectively include the aforementioned components, and a ratio of the binder polymer, the (meth)acrylic compound, the photoreaction initiator, and the flame retardant in each layer is not particularly limited as long as the flame retardant content of each layer is in the aforementioned range.

In the first and second photosensitive layers, each of (i) a weight ratio of the binder polymer (A1) with respect to the entire weight of the first photosensitive layer and (ii) a weight ratio of the binder polymer (A2) with respect to the entire weight of the second photosensitive layer is preferably 10 wt % or more and 90 wt % or less, more preferably 20 wt % or more and 85 wt % or less, still more preferably 25 wt % or more and 80 wt % or less. It is preferable that the ratio is 10 wt % or more since this condition is likely to improve the heat resistance of the first and second photosensitive layers, and it is preferable that the ratio is 90 wt % or less since this allows each photosensitive layer to be press-bonded to the base material at a low temperature.

Further, in the first and second photosensitive layers, it is preferable that the (meth)acrylic compound (B1) and the (meth)acrylic compound (B2) are included so that a ratio of the (meth)acrylic compound (B1) is 1 part by weight or more and 400 parts by weight or less with respect to 100 parts by weight of the binder polymer (A 1) and a ratio the (meth)acrylic compound (B2) is 1 part by weight or more and 400 parts by weight or less with respect to 100 parts by weight of the binder polymer (A2), and it is more preferable that the ratio of each (meth)acrylic compound is 3 parts by weight or more and 300 parts by weight or less. If the (meth)acrylic compound is included within the aforementioned range of its ratio, it is possible to particularly effectively realize the first and second photosensitive layers which are imidized at lower temperature than that of a conventional arrangement.

Further, in the first and second photosensitive layers, the photoreaction initiator (C1) and the photoreaction initiator (C2) are blended so that sensitization effect can be obtained and the blend does not have an unfavorable influence on the development. Specifically, it is preferable to blend the photoreaction initiators (C1) and (C2) so that an amount of the photoreaction initiator (C1) is 0.01 to 50 parts by weight with respect to 100 parts by weight of the binder polymer (A1) and an amount of the photoreaction initiator (C2) is 0.01 to 50 parts by weight with respect to 100 parts by weight of the binder polymer (A2).

Note that, as long as the photoreaction initiator of the first photosensitive layer is included at the foregoing ratio, it is possible to obtain the photosensitive dry film resist having certain resolution and photosensitivity even in case where the second photosensitive layer does not include the photoreaction initiator (C2). Therefore, the scope of the present invention encompasses an arrangement in which the second photosensitive layer substantially does not include the photoreaction initiator (C2). Thus, a ratio of the blended photoreaction initiator (C2) may be 0 to 0.01 parts by weight with respect to 100 parts by weight of the binder polymer (A2).

Further, in the first photosensitive layer, the amount of the flame retardant (D1) is not particularly limited and may be suitably set in accordance with a type of a flame retardant used. The amount of the flame retardant (D1) is preferably 5 to 50 parts by weight, more preferably 10 to 40 parts by weight, when a total amount of the binder polymer (A1) and the (meth)acrylic compound (B1) is 100 parts by weight. When the amount of the flame retardant (D1) is 5 parts by weight or more, it is possible to effectively give the flame retardancy to the photosensitive dry film resist having been cured. Further, if the amount of the flame retardant (D1) is 50 parts by weight or less, it is possible to improve the mechanical property of the photosensitive dry film resist having been cured. Note that, the amount of the flame retardant (D2) in the second photosensitive layer is as described above.

The thickness of the photosensitive dry film resist according to the present invention is not particularly limited, but for example, the thickness is preferably 5 μm or more and 75 μm or less, more preferably 10 μm or more and 60 μm or less. It is not preferable that the thickness of the photosensitive dry film resist is less than 5 μm since this thickness does not allow a conduction wire made of copper or the like to be coated therewith. Further, it is not preferable that the thickness of the photosensitive dry film resist is larger than 75 μm since this thickness causes the photosensitivity to drop.

Further, in case where the thickness of the first photosensitive layer is regarded as 100, the thickness of the second photosensitive layer is preferably 10 to 500, more preferably 20 to 400, still more preferably 50 to 300.

In case where the thickness of the first photosensitive layer is regarded as 100, it is not preferable that the thickness of the second photosensitive layer is larger than 500 since this thickness causes the flame retardancy of the photosensitive dry film resist to drop. Further, in case where the thickness of the first photosensitive layer is regarded as 100, it is not preferable that the thickness of the second photosensitive layer is smaller than 10 since this thickness is likely to cause the electric reliability to drop.

In the photosensitive dry film resist according to the present invention, the second photosensitive layer is laminated so as to be in contact with the side contacting the copper-clad laminate having a circuit thereon (this plate is referred to also as “CCL with circuit”). This makes it possible to improve the resolution, the flame retardancy, the moisture resistance, and the electric reliability of the photosensitive dry film resist. This effect may be based on the following reason. When the concentration of the flame retardant at a portion contacting the copper-clad laminate having a circuit thereon is dropped, it is possible to prevent the moisture resistance of the portion contacting the copper-clad laminate from dropping, so that it is possible to effectively improve the electric reliability.

As described above, the second photosensitive layer is laminated so as to be in contact with the side contacting the copper-laminate plate, so that it is possible to improve the resolution and the photosensitivity. This may be based on the following reason. That is, irradiation of light causes the photoreaction initiator to generate radicals and the like so as to cross-link the (meth)acrylic compound, so that the photosensitivity is exhibited. Herein, if the concentration of the flame retardant is high, this causes the concentration of the generated radicals and the like to drop and causes the cross-linked density (concentration) of the (meth)acrylic compound to drop, so that the photosensitivity drops. Particularly, this tendency is greater as further away (deeper) from the light irradiation side. Therefore, the concentration of the flame retardant on the side contacting the copper-clad laminate on the side further away from the light irradiation side, that is, the concentration of the flame retardant on the side contacting the copper-clad laminate is dropped, thereby improving the resolution and the photosensitivity. Further, the concentration of the flame retardant of the second photosensitive layer contacting the base material is dropped, so that the alkaline solubility of the second photosensitive layer is improved. As a result, a residue hardly occurs at the time of the alkaline development, so that it is possible to enhance the resolution and the photosensitivity. As long as the alkaline solubility of the second photosensitive layer contacting the base material is excellent, such effect can be obtained even if the alkaline solubility of the first photosensitive layer deteriorates. Therefore, by laminating the second photosensitive layer so as to be in contact with the side contacting the copper-clad laminate, it is possible to realize the flame retarancy of the entire photosensitive dry film resist and it is possible to obtain effect based on the excellent alkaline solubility.

Further, in the photosensitive dry film resist according to the present invention, a below-described support film and/or protection film may be further laminated. Note that, the support film is formed on the outside of the first photosensitive layer, or the protection film is formed on the outside of the second photosensitive layer.

The following description will detail the aforementioned components included in the first and second photosensitive layers constituting the multi-layer photosensitive dry film resist according to the present invention.

### (I-2) Binder Polymer

In the present invention, the binder polymer is a polymer component, blended to give a film forming ability, out of photosensitive resin compositions used to form the photosensitive dry film resist. Note that, in the present invention, the polymer component is oligomer whose weight average molecular weight is 5000 or more. Note that, the weight average molecular weight can be measured by size exclusion chromatography (SEC), for example, by HLC8220GPC (product of TOSOH CORPORATION).

The binder polymer used in the present invention is not particularly limited, but it is preferable that the binder polymer is soluble in alkaline aqueous solution or can be swollen in alkaline aqueous solution so as to allow water system development. Thus, it is preferable that the binder polymer includes in its polymer chain acidic functional group such as a carboxyl group, a hydroxyl group, a sulfonic acid group, a phosphoric acid group, and the like. Examples of the binder polymer including acidic functional group include: vinyl polymer containing carboxyl group; polyamide acid; soluble polyimide containing carboxyl group and/or hydroxyl group, and they can be solely used or can be used in combination of two or more kinds.

Note that, in the present invention, the binder polymers (A1) and (A2) may be the same or may be different from each other. Likewise, the first and second photosensitive layers may be the same or may be different from each other in the components B, C, D, and E.

### (I-2-1) Vinyl Polymer Containing Carboxyl Group

The vinyl polymer containing carboxyl group is used as the binder polymer, thereby producing a photosensitive dry film resist which is excellent in plasticity and alkaline solubility. Further, also easy production can be realized, which results in high productivity and low cost.

The vinyl polymer containing carboxyl group can be obtained by copolymerizing a monomer containing carboxyl group with a monomer polymerizable therewith in accordance with a known method.

Examples of the monomer containing carboxyl group include: (meth)acrylic acid, maleic acid, maleic acid monoalkylester, vinyl benzoic acid, cinnamic acid, propiolic acid, fumaric acid, crotonic acid, maleic acid anhydride, phthalic acid anhydride, and the like. Above all, it is preferable to use (meth)acrylic acid in view of the cost and polymerizability. They can be solely used or can be used in combination of two or more kinds.

Examples of the monomer copolymerizable with the foregoing monomer include: (meth)acrylic acid esters, maleic acid diesters, fumaric acid diesters, crotonic acid esters, vinyl esters, maleic acid diesters, (meth)acrylamides, vinyl ethers, vinyl alcohols, styrene, styrene derivative, and the like. Above all, it is preferable to use (meth)acrylic acid ester, styrene, and styrene derivative in view of polymerizability and flexibility. They can be used solely or can be used in combination of two or more kinds.

The vinyl polymer containing carboxyl group which can be obtained from these monomers is not particularly limited, but the vinyl polymer containing carboxyl group preferably includes 5 to 50 mol % of the monomer containing carboxyl group, more preferably includes 15 to 40 mol % of the monomer containing carboxyl group. If the ratio of the monomer containing carboxyl group is less than 5 mol %, the solubility in alkaline aqueous solution is likely to deteriorate. If the ratio of the monomer containing carboxyl group is more than 50 mol %, the resistance against alkaline aqueous solution is likely to deteriorate. Note that, the ratio of the monomer containing carboxyl group refers to a ratio of the monomer carboxyl group with respect to the entire monomers used.

A weight average molecular weight of the vinyl polymer containing carboxyl group is not particularly limited, but the weight average molecular weight is preferably 5000 to 300000, more preferably 10000 to 200000. If the weight average molecular weight is less than 5000, the photosensitive dry film resist is likely to be cloggy, and the film having been cured is likely to deteriorate in its bendability. While, if the weight average molecular weight is more than 300000, the developing property of the resultant photosensitive dry film resist may deteriorate. Note that, the weight average molecular weight can be measured by size exclusion chromatography (SEC), for example, by HLC8220GPC (product of TOSOH CORPORATION).

### (I-2-2) Polyamide Acid

The polyamide acid which is a precursor of polyimide is used as the binder polymer, so that the entire photosensitive dry film resist is excellent in properties such as a water system developing property, flame retardancy, adhesiveness, moisture resistance, electric reliability, solder heat resistance, and the like.

The polyamide acid can be obtained by reacting diamine and acid dianhydride in an organic solvent. For example, diamine is dissolved in an organic solvent or is dispersed in a slurry manner under an inert atmosphere such as argon and nitrogen and the like, thereby obtaining diamine solution. While, acid dianhydride is added to the diamine solution after dissolution in the organic solvent or after dispersion in the slurry manner or in a solid state.

The acid dianhydride and diamine used to synthesize polyamide acid are not particularly limited, but it is preferable to use aromatic acid anhydride and aromatic diamine in view of reactivity, flame retardancy, solubility with respect to the organic solvent, heat resistance, and bendability.

Examples of the aromatic acid anhydride include: aromatic tetracarboxylic acid dianhydride such as pyromellitic acid dianhydride, 3,3′,4,4′-benzophenone tetracarboxylic acid dianhydride, 3,3′,4,4′-biphenylsulfone tetracarboxylic acid dianhydride, 2,2-bis(hydroxyphenyl)propane dibenzoate-3,3′,4,4′-tetracarboxylic acid dianhydride, 2,3′,3,4′-biphenylether tetracarboxylic acid dianhydride, 3,4,3′,4′-biphenylether tetracarboxylic acid dianhydride, biphenyl-3,4,3′,4′-tetracarboxylic acid dianhydride, and 2,2′-hexafluoropropyliden diphthalic acid dianhydride, and the like; aliphatic tetracarboxylic acid dianhydride, having an aromatic ring, such as 1,3 ,3a,4,5,9b-hexahydro-2,5-dioxo-3-furanyl-naptho [1,2-c]furan-1,3-dione, and the like; and the like. These acid dianhydrides can be used solely or can be used in combination of two or more kinds.

Out of the aromatic acid dianhydrides, it is preferable to use at least part of aromatic tetracarboxylic acid dianhydride such as pyromellitic acid dianhydride, 3,3′,4,4′-benzophenone tetracarboxylic acid dianhydride, 3,3′,4,4′-biphenylsulfone tetracarboxylic acid dianhydride, 3,4,3′,4′-biphenylether tetracarboxylic acid dianhydride, biphenyl-3,4,3′,4′-tetracarboxylic acid dianhydride, and 2,2′-hexafluoropropyliden diphthalic acid dianhydride, in view of easiness to synthesize and solubility with respect to alkaline aqueous solution.

Examples of the aromatic diamine include: p-phenylene diamine, m-phenylene diamine, 4,4′-diaminodiphenylmethane, 4,4′-diaminophenylethane, 4,4′-diaminophenylether, 3,4′-diaminophenylether, 3,3′-diaminophenylether, 4,4′-didiaminophenylsulfide, 4,4′-didiaminophenylsulfone, 1,5-diaminonaphthalene, 3,3-dimethyl-4,4′-diaminobiphenyl, 5-amino-1-(4′-aminophenyl)-1,3,3-trimethylindan, 6-mino-1-(4′-aminophenyl)-1,3,3-trimethylindan, 3,4′-diaminodiphenylether, 2,7-diaminofluorene, 2,2-bis(4-aminophenyl)hexafluoropropane, 3,3′-dimethoxy-4,4′-diaminobiphenyl, 4,4′-diamino-2,2′-bis(trifluoromethyl)biphenyl, 2,2-bis[4-(4-aminophenoxy)phenyl]propane, 2,2-bis[4-(4-aminophenoxy)phenyl]hexafluoropropane, 1,4-bis(4-aminophenoxy)benzene, 4,4′-bis(4-aminophenoxy)-biphenyl, 1,3-bis(4-aminophenoxy)benzene, 1,3-bis(3-aminophenoxy)benzene, 9,9-bis(4-aminophenyl)fluorene, 4,4′-(p-phenyleneisopropyliden)bisaniline, 4,4′-(m-phenyleneisopropyliden)bisaniline, 2,2′-bis[4-(4-amino-2-trifluoromethylphenoxy)phenyl]hexa fluoropropane, and 4,4′-bis[4-(4-amino-2-trifluoromethyl)phenoxy]-octafluoro biphenyl, bis[4-(3-aminophenoxy)phenyl]sulfone. The diamines can be used solely or can be used in combination of two or more kinds.

Out of the aromatic diamines, it is preferable to use at least part of 1,3-bis(4-aminophenoxy)benzene, 1,3-bis(3-aminophenoxy)benzene, and bis[4-(3-aminophenoxy)phenyl]sulfone, in view of heat resistance and solubility with respect to alkaline aqueous solution.

It is needless to say that not only the aforementioned aromatic diamines but also other known diamines may be used as part of raw material.

In case of synthesizing polyamide acid by using the diamines and acid dianhydrides, at least one kind of the diamines and at least one kind of the acid dianhydrides are used to carry out reaction. That is, for example, a diamine component and the acid dianhydride are used, and polymerization reaction is carried out in an organic solvent as described above, thereby obtaining polyamide acid.

At this time, if one kind of the diamines and one kind of the acid dianhydrides are substantially equal to each other in terms of moles, this results in polyamide acid including one kind of acid dianhydride component and one kind of diamine component. Further, in case of using two or more kinds of acid dianhydride components and two or more kinds of diamine components, it is possible to intentionally obtain polyamide acid copolymer as long as a molar ratio of an entire amount of plural diamine components and a molar ratio of an entire amount of plural acid dianhydrides are adjusted so as to be substantially equal to each other in terms of moles.

A reaction temperature of the diamine and acid dianhydride (synthesis reaction of polyamide acid) is not particularly limited, but the temperature is preferably −20° C. or higher and 80° C. or lower, more preferably −15° C. or higher and 50° C. or lower. If the temperature exceeds 80° C., polyamide acid may be decomposed. Inversely, if the temperature is lower than −20° C., proceeding of the polymerization reaction may be slow. Further, the reaction time can be set to be any value within a range from 10 minutes to 30 hours.

Further, an organic solvent used in the synthesis reaction of the polyamide acid is not particularly limited as long as an organic polar solvent is used. However, t is advantageous in the production steps to use a solvent which can dissolve the polyamide acid and whose boiling point is as low as possible.

Specifically, examples of the organic solvent used in the synthesis reaction of the polyamide acid include: a formamide solvent such as N,N-dimethylformamide; an acetamide solvent such as N,N-dimethylacetamide; a pyrrolidone solvent such as N-methyl-2-pyrrolidone and N-vinyl-2-pyrrolidone; an ether solvent such as tetrahydrofuran, dioxane, and dioxolane; and the like.

A weight average molecular weight of the polyamide acid is not particularly limited, but the weight average molecular weight is preferably 5000 to 300000, more preferably 10000 to 200000. If the weight average molecular weight is less than 5000, the photosensitive dry film resist is likely to be cloggy, and the film having been cured is likely to deteriorate in its bendability. While, if the weight average molecular weight is more than 300000, the solution viscosity is too high to be easily handled, and the developing property of the resultant photosensitive dry film resist may drop. Note that, the weight average molecular weight can be measured by size exclusion chromatography (SEC), for example, by HLC8220GPC (product of TOSOH CORPORATION).

With the photosensitive resin composition disclosed by Patent Documents 6 to 9 and obtained by mixing polyamide acid with (meth)acrylic compound, it is difficult to suppress warpage caused by mismatch between the cover lay film obtained from the photosensitive resin composition and the base film in terms of a thermal expansion coefficient. Herein, a copper foil pattern is provided on a thin base film of FPC (about 25 μm) directly or via an adhesive, and a cover lay film is formed on the surface so as to protect the conductive surface. Therefore, if mismatch between the base film and the cover lay film in terms of a thermal expansion coefficient results in warpage, this is disadvantage in packaging components and the like.

In this manner, each of the FPC photosensitive dry film resists fails to realize sufficient performance, and the conventional photosensitive dry film resist does not satisfactory realize all the water system developing properties: excellent resolution, flame retardancy, adhesiveness, moisture resistance, electric reliability, and anti-warpage property.

The polyamide acid obtained by using polysiloxane diamine represented by the following formula (1) as at least part of the raw material can improve the flexibility, adhesiveness, bendability. Therefore, by using such polyamide acid, it is possible to produce a photosensitive dry film resist which realizes not only the developing properties such as excellent resolution, flame retardancy, adhesiveness, moisture resistance, and electric reliability, but also anti-warpage property.

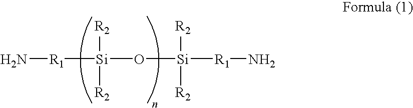

where each R₁ independently represents a hydrocarbon whose carbon number is 1 to 5, and each R₂ independently represents an organic group selected from an alkyl group whose carbon number is 1 to 5 and a phenyl group, and n represents an integer from 1 to 20.

Further, the present inventors found that: polyamide acid made of polysiloxane diamine having a certain structure is further used so as to improve flame retardancy of polyimide itself, thereby realizing a low imidization temperature. Then, they found that: by using such polyamide acid for the two-layer photosensitive dry film resist, it is possible to realize a photosensitive dry film resist which satisfactory realizes all the water system developing properties, i.e., excellent resolution, flame retardancy, adhesiveness, moisture resistance, electric reliability, and anti-warpage property, and a low imidization temperature.

It is extremely preferable to use, as polyamide acid having a favorable balance between flame retardancy and flexibility, polyamide acid including a constitutional unit represented by the following formula (2) and a constitutional unit represented by the following formula (3).

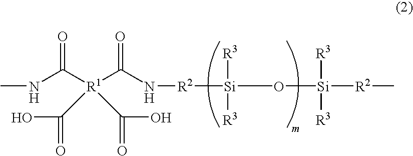

where R¹ represents a tetravalent organic group, each R² independently represents an alkylene group whose carbon number is 2 to 5, and each R³ independently represents a methyl group or a phenyl group, and a content of the phenyl group in R3 is 15% or more and 40% or less, and m is an integer of 4 or more and 20 or less

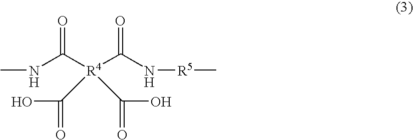

where R⁴ represents a tetravalent organic group, and R⁵ represents a bivalent organic group obtained by excluding two amino groups from aromatic diamine.

As a result, it is possible to obtain polyamide acid which is excellent in flame retardancy, electric reliability, and anti-warpage property. Further, by using the polyamide acid, it is possible to obtain a photosensitive dry film resist which allows water system development and which is excellent in resolution, flame retardancy, adhesiveness, moisture resistance, electric reliability, and anti-warpage property.

In the formula (2), R¹ is not particularly limited as long as R¹ is a tetravalent organic group. However, it is more preferable that R¹ is a tetravalent aromatic group whose carbon number is 6 to 50 and which is selected from a monocyclic aromatic group, a condensation polycyclic aromatic group, and a group obtained by coupling two or more these aromatic groups directly or via a coupling group. A specific example of R¹ is a residual group obtained by excluding two chains each of which is indicative of —CO—O—CO— from below-described acid dianhydride. Note that, R¹ may be the same as or different from other R¹ in each constitutional unit represented by the formula (2).

In the formula (2), each R² independently represents an alkylene group whose carbon number is 2 to 5. Specifically, R² is an ethylene group, a propylene group, a tetramethylene group, or a pentamethylene group.

Further, in formula (2), each R³ independently represents a methyl group or a phenyl group. Note that, the methyl group of R³ may be partially replaced by an ethyl group or a propyl group as long as the methyl group does not have an unfavorable influence on performance of the resultant polyamide acid, the photosensitive dry film resist having the polyamide acid, and the imidized resultant (hereinafter, sometimes referred to as “polyamide acid and the like” in the present specification). Herein, a content of the phenyl group of R³ is preferably 15% or more and 40% or less. If the content of phenyl group of R³ is 15% or more, it is possible to improve the flame retardancy of polyamide acid and the like. In this manner, it is preferable that the content of the phenyl group is 15% or more in view of the flame retardancy of the resultant polyamide acid and the like. However, it is not preferable that the content of the phenyl group is more than 40% since the flexibility and anti-warpage property of the resultant polyamide acid are likely to deteriorate. The content of the phenyl group is more preferably 18% or more and 38% or less, still more preferably 20% or more and 35% or less.

Further, if the content of the phenyl group is within the foregoing range, the photosensitivity, the bendability, and the electric reliability of the resultant polyamide acid and the like are likely to be improved. In this manner, for unknown reasons, it is possible to obtain the polyamide acid and the like having anti-warpage property, excellent flexibility, bendability, electric reliability, photosensitivity, and flame retardancy by setting the content of the phenyl group within the foregoing range.

Further, the flame retardancy is improved, so that the flame retardancy can be realized with a smaller amount of flame retardant than the case of the conventional polyamide acid and the like obtained by using polysiloxane diamine. Therefore, it is possible to obtain polyamide acid and the like which are more excellent in the flame retardancy, moisture resistance, and electric reliability.

Note that, the content of the phenyl group refers to a molar fraction of the phenyl group included in R³ and is represented by the following expression.

Content (%) of the phenyl group=(mol number of the phenyl group of R³)÷(mol number of the phenyl group of R³+mol number of the methyl group of R³)×100

Further, it is preferable that the content of the methyl group of R³ is 60% or more and 85% or less. If the content of the methyl group of R³ is 60% or more, the flexibility and the anti-warpage property of the resultant polyamide acid are improved, so that such content is preferable. Further, if a ratio of the methyl group is 60% or more, the resultant polyamide acid and the like are excellent in the flexibility and anti-warpage property. However, it is not preferable that the ratio of the methyl group is 85% or more since this is likely to cause the flame retardancy of the resultant polyamide acid and the like to deteriorate. The ratio of the methyl group is more preferably 62% or more and 82% or less, still more preferably 65% or more and 80% or less.

Further, it is preferable that m, i.e., a recurring unit of the siloxane bond in the formula (2) is an integer not less than 4 and not more than 20. It is preferable that m is 4 or more since this further improves the flexibility and anti-warapage property of the resultant polyamide acid and the like. Further, if m is 20 or more, the polysiloxane part agglutinates in the resultant polyamide acid and the like, so that the agglutinating domain exceeds a wavelength of visible light and diffusely reflects the light so as to whiten, which may result in deterioration of the photosensibility. Further, if m is more than 20 and a large domain containing only polysiloxane is generated, the flame retardancy may deteriorate. It is more preferable that m is 4 or more and 18 or less, and it is still more preferable that m is 5 or more and 15 or less.

Further, if m is within the foregoing range, the resultant polyamide acid and the like are likely to be excellent in the bendability and the electric reliability. In this manner, if m is within the foregoing range, it is possible to obtain polyamide acid and the like which are less warped and excellent in the flexibility, the bendability, the electric reliability, and the photosensitivity, and which have the flame retardancy.

Further, R⁴ of formula (3) is not particularly limited as long as R⁴ represents a tetravalent organic compound, but it is more preferable that R⁴ is a tetravalent aromatic group whose carbon number is 6 to 50 and which is selected from a monocyclic aromatic group, a condensation polycyclic aromatic group, and a group obtained by coupling two or more these aromatic groups directly or via a coupling group. Specific examples of R⁴ include a residual group obtained by excluding two chains each of which is indicative of —CO—O—CO— from below-described acid dianhydride. Note that, R⁴ may be the same as or different from other R⁴ in each constitutional unit represented by the formula (3). Further, R⁴ may be the same as or different from other R¹ of the formula (2).

Further, R⁵ of the formula (3) is not particularly limited as long as R⁵ represents a bivalent organic group obtained by excluding two amino groups from aromatic diamine. Note that, herein, the aromatic diamine is a compound having two amino groups directly coupled to an aromatic ring. Above all, it is more preferable that R⁵ is a bivalent aromatic group whose carbon number is 6 to 50 and which is selected from a monocyclic aromatic group, a condensation polycyclic aromatic group, and a group obtained by coupling two or more these aromatic groups directly or via a coupling group. Note that, R⁵ may be the same as or different from other R⁵ in each constitutional unit represented by the formula (3).

More preferably, the constitutional unit represented by the formula (3) includes a constitutional unit in which at least one of aromatic rings coupled to the two amino acids of the aromatic diamine in R⁵ of the formula (3) has two bonds at a meta position with respect to a main chain. An example of the recurring unit is as follows: in case where the aromatic diamine is phenylenediamine, a single benzene ring coupled to the two amino groups has two bonds at a meta position with respect to a main chain. That is, in such case, the aromatic diamine is m-phenylenediamine, and R⁵ is bivalent m-phenylene group obtained by exclusing two amino groups from m-phenylenediamine.

Further, in case where the aromatic diamine is diaminodiphenylmethane for example, at least one of two benzene rings coupled to two amino groups has two bonds at a meta position with respect to the main chain. That is, in such case, the aromatic diamine is 3,3′- or 3,4′-diaminodiphenylmethane, and R⁵ is a bivalent group obtained by exclusing two amino groups from 3,3′- or 3,4′-diaminodiphenylmethane.

As a result, it is possible to drop a temperature at which the polyamide acid and the like are imidized. Specifically, it is possible to obtain polyamide acid whose imidization ratio is 95% or more at 180° C. or lower.

The conventional photosensitive polyimide has been studied as a material for a semiconductor, and there is no problem even if an imidization temperature of the semiconductor is high, so that an arrangement for dropping the imidization temperature has not been studied. The conventional photosensitive polyimide is obtained by carrying out exposure and development under the polyamide acid phase and then carrying out imidization generally at 300° C. or higher. If such photosensitive polyimide is used as the FPC photosensitive dry film resist, the FPC is heated at 250° C. or higher. However, it is general that also resin whose heat resistance is lower than that of epoxy resin and the like is used as a component of a rigid print board and a flexible print board. This resin cannot resist against a temperature over 200° C. Thus, if the photosensitive polyimide cured at high temperature over 300° C. is used for the FPC, the high temperature causes oxidization of the copper foil and causes a crystal structure of copper to change, which results in such problem that the strength of the copper foil deteriorates. Therefore, such photosensitive polyimide cannot be used for a rigid print board or a flexible print board.

By using the polyamide acid, it is possible to obtain a photosensitive dry film resist which allows water system development and is excellent in resolution, flame retardancy, adhesiveness, moisture resistance, electric reliability, and anti-warpage property, and whose imidization temperature is low.

Therefore, such photosensitive dry film resist is cured at 180° C. or lower so as to be formed as an insulating protection layer, thereby producing a printed wiring board. This makes it possible to solve the following problem: the high temperature causes oxidization of the copper foil and causes a crystal structure of copper to change, which results in the lower strength of the copper foil. As a result, it is possible to produce a high-performance printed wiring board.

In case where the aromatic ring has two bonds at an ortho position with respect to a main chain, an imide ring generated by the imidization is close to the main chain. As a result, steric hindrance occurs, so that the imidization is hindered. Thus, the imidization temperature is likely to rise.

On the other hand, in case where the aromatic ring has two bonds at a para position with respect to a main chain, steric hindrance does not occur, but the main chain is entirely in a linear state, so that this is less susceptible to thermal vibration. This may result in a higher glass transition temperature (Tg). Further, the main chain is entirely in a linear state, so that agglutinability among molecules increases, which may result in a higher glass transition temperature Tg. That is, water molecules are excluded at the time of imidization, which results in ring closure, so that the volume decreases. However, if the entire molecules do not move, it is impossible to carry out the imidization.

Further, in case where the aromatic ring has two bonds at a meta position with respect to a main chain, this is likely to absorb less light. Thus, in case where such arrangement is adopted to a photosensitive resin, it is possible to obtain the photosensitive resin having high photosensitivity.

Therefore, the constitutional unit represented by formula (3) may include a constitutional unit in which the aromatic ring of R⁵ has two bonds at an ortho or a para position with respect to a main chain to such an extent that this arrangement does not have any influence on rise of the imidization temperature and the glass transition temperature, but it is preferable that a smaller ratio of such constitutional unit is included.

In other words, the constitutional unit represented by the formula (3) more preferably includes a more ratio of the constitutional unit in which the aromatic ring has two bonds at a meta position with respect to a main chain.

For example, in case where {(mol number of amino group at a meta position of aromatic diamine)/(mol number of amino group of entire aromatic diamine used to produce polyamide acid precursor))×100=a content (%) of amino group at the meta position, the content of amino group at the meta position is more preferably 60% or more, still more preferably 80% or more. Note that, the mol number of the amino group of the entire aromatic diamine is obtained by doubling the mol number of the entire aromatic diamine used to produce polyamide acid. For example, in case of using only 3,3′-diphenylether as the aromatic diamine used to produce the polyamide acid precursor, the content of amino group at the meta position is 100%. In case of using only 3,4′-diphenylether, the content of amino group at the meta position is 50%. In case of using only 4,4′-diphenylether, the content of amino group at the meta position is 0%. Further, in case of using only m-phenylenediamine as the aromatic diamine used to produce polyamide acid, the content of amino group at the meta position is 100%. In case of using only p-phenylenediamine or o-phenylenediamine, the content of amino group at the meta position is 0%.

Further, in case where {(mol number of amino group in the para position of aromatic diamine)/(mol number of amino group of entire aromatic diamine used to produce polyamide acid precursor)}×100=a content (%) of the amino group at the para position, the content of amino group at the para position is more preferably 20% or less.

The aromatic diamine having an amino group at a meta position is not particularly limited as long as the aromatic diamine is such diamino compound that the amino group is directly coupled to the aromatic ring and the position of the amino group is 3- or m-. Specific examples thereof include:m-phenylene diamine, 3,3′-diaminodiphenylmethane, 3,3′-diaminodiphenylether, 3,3′-diaminodiphenylsulfide, 3,3′-diaminodiphenylsulfone, 3,3′-diaminobenzanilide, 2,2-bis(3-aminophenyl)hexafluoropropane, 3,3′-diamino-2,2′-bis(trifluoromethyl)biphenyl, 2,2-bis[4-(3-aminophenoxy)phenyl]propane, 2,2-bis[4-(3-aminophenoxy)phenyl]sulfone, 2,2-bis[4-(3-aminophenoxy)phenyl]hexafluoropropane, 1,4-bis(3-aminophenoxy)benzene, 4,4′-bis(3-aminophenoxy)-biphenyl, 1,3-bis(3-aminophenoxy)benzene, bis[4-(3-aminophenoxy)phenyl]sulfone, 2,2-bis(3-aminophenyl)propane, 9,9-bis(3-aminophenyl)fluorene, 4,4′-(m-phenyleneisopropyliden)bisaniline, 4,6-diamino resorcinol, 3,3′-diamino-4,4′-dihydroxybiphenyl, 3,3′-diamino-4,4′-dihydroxydiphenylmethane, 2,2-bis[3-amino-4-hydroxyphenyl]propane, 2,2-bis[3-amino-4-hydroxyphenyl]hexafluoropropane, 3,3′-diamino-4,4′-dihydroxydiphenylether, 3,3′-diamino-4,4′-dihydroxydiphenylsulfone; bis[(hydroxyphenoxy)phenyl]sulfone such as bis[4-(3-amino-4-hydroxyphenoxy)phenyl]sulfone, and the like; diamine compounds such as 3,3′-diamino-4,4′-dihydroxybiphenyl, 2,2′-bis[3-amino-4-hydroxyphenyl]propane, 3,3′-diamino-4,4′-dicarboxybiphenyl, 3,3′-diamino-4,4′-dicarboxydiphenylmethane, 2,2-bis[3-amino-4-carboxyphenyl]propane, 2,2-bis[3-amino-4-carboxyphenyl]hexafluoropropane, 3,3′-diamino-4,4′-dicarboxydiphenylether, 3,3′-diamino-4,4′-dicarboxydiphenylsulfone, 3,5-diamino benzoic acid, and the like. In such case, the constitutional unit represented by the formula (3) is a structure in which two amino groups are excluded from the aromatic diamine of R⁵ of the formula (3).

In order to obtain polyamide acid and the like having particularly high electric reliability, it is more preferable to select a compound having no hydroxyl group or no carboxyl group out of aromatic diamines each of which has the above-exemplified amino group at the meta position.

More preferable examples of the aromatic diamine having amino group at the meta position include m-phenylene diamine, 3,3′-diaminodiphenylmethane, 3,3′-diaminodiphenylether, 3,3′-diaminodiphenylsulfide, 3,3′-diaminodiphenylsulfone, 3,3′-diaminobenzanilide, 2,2-bis(3-aminophenyl)hexafluoropropane, 2,2-bis[4-(3-aminophenoxy)phenyl]propane, 2,2-bis[4-(3-aminophenoxy)phenyl]sulfone, 2,2-bis[4-(3-aminophenoxy)phenyl]hexafluoropropane, 1,4-bis(3-aminophenoxy)benzene, 4,4′-bis(3-aminophenoxy)-biphenyl, 1,3-bis(3-aminophenoxy)benzene, bis[4-(3-aminophenoxy)phenyl]sulfone, or 2,2-bis(3-aminophenyl)propane.

Further, polyamide acid used as the binder polymer includes not only the constitutional unit represented by the formula (2) and the constitutional unit represented by the formula (3) but also a constitutional unit represented by the following formula (4),

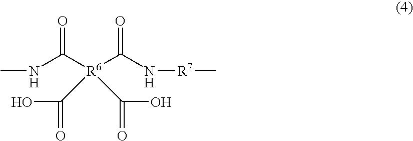

where R⁶ represents a tetravalent organic group and R⁷ has a structure represented by the following formula a, b, c, d, e, f, or g,

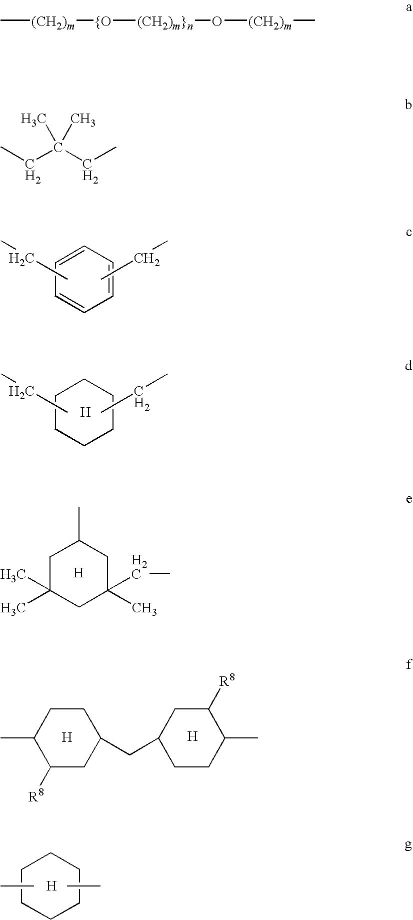

where m of the formula a represents an integer ranging from 1 to 20, n of the formula a represents an integer ranging from 0 to 10, R⁸ of the formula f represents a hydrogen atom, a methyl group, an ethyl group, or a butyl group.

In the formula (4), R⁶ is not particularly limited as long as R⁶ is a tetravalent organic group, but it is more preferable that R⁶ is a tetravalent aromatic group which is selected from a monocyclic aromatic group, a polycyclic aromatic group, and a group obtained by coupling two or more these aromatic groups directly or via a coupling group and whose carbon number is 6 to 50. Specific examples of R⁶ include a residual group obtained by excluding two chains each of which is indicative of —CO—O—CO— from below-described acid dianhydride. Note that, R⁶ may be the same as or different from other R⁶ in each constitutional unit represented by the formula (4).

By further including the constitutional unit represented by the formula (4), improvement of the compatibility with respect to the (meth)acrylic compound is expected.

In the polyamide acid including the constitutional unit represented by the formula (2), the constitutional unit represented by the formula (3), and depending on cases, the constitutional unit represented by the formula (4), a total of (i) a molar fraction of the constitutional unit represented by the formula (2) and (ii) a molar fraction of the constitutional unit represented by the formula (4), with respect to the entire constitutional units of the binder polymer (A) or the entire constitutional units of polyamide acid serving as the binder polymer (A) is preferably 10% or more and less than 90%, more preferably 20% or more and less than 80%, still more preferably 30% or more and less than 70%, particularly preferably 40% or more and less than 60%, where the molar fraction is as follows: ((mol number of the constitutional unit represented by the formula (2))+((mol number of the constitutional unit represented by the formula (4))÷(mol number of the constitutional unit represented by the formula (2)+mol number of the constitutional unit represented by the formula (3)+mol number of the constitutional unit represented by the formula (4))×100. If the total of the molar fraction of the constitutional unit represented by the formula (2) and the molar fraction of the constitutional unit represented by the formula (4) is 10% or more, it is possible to carry out imidization at a temperature lower than that of the conventional imidization temperature of polyamide acid and the like, and it is possible to obtain polyamide acid and the like which are less warped and are excellent in flexibility and bendability.

At this time, a molar fraction of the constitutional unit represented by the formula (2) with respect to the total of (i) the molar fraction of the constitutional unit represented by the formula (2) and (ii) the molar fraction of the constitutional unit represented by the formula (4) is preferably more than 0 and 100% or less, more preferably 10% or more and 100% or less, still more preferably 30% or more and 100% or less, where the molar fraction is as follows: (mol number of the constitutional unit represented by the formula (2))÷(mol number of the constitutional unit represented by the formula (2)+mol number of the constitutional unit represented by the formula (4))×100. This arrangement is preferable since this makes it possible to exhibit high flame retardancy, flexibility, and bendability.

Further, a weight average molecular weight of polyamide acid including at least the constitutional units respectively represented by the formulas (2) and (3), depending on cases, a weight average molecular weight of polyamide acid including not only the constitutional units respectively represented by the formulas (2) and (3) but also the constitutional unit represented by the formula (4) is preferably 2000 or more and 1000000 or less, more preferably 5000 or more and 300000 or less. If the weight average molecular weight of polyamide acid is less than 2000, the molecular weight of the resultant polyimide drops, which is likely to result in lower strength. Such condition is not preferable. If the weight average molecular weight of polyamide acid is more than 1000000, it is likely to take longer time to develop the photosensitive resin. Also such condition is not preferable.

Further, the weight average molecular weight of polyamide acid including at least the constitutional units respectively represented by the formulas (2) and (3), depending on cases, a weight average molecular weight of polyamide acid including not only the constitutional units respectively represented by the formulas (2) and (3) but also the constitutional unit represented by the formula (4) is divided by a number average molecular weight, and the number indicative of weight average molecular weight/number average molecular weight is preferably 2 or more and 10 or less, more preferably 2 or more and 5 or less.

In case where at least any one of the first and second photosensitive layers or more preferably the first photosensitive layer contains the polyamide acid, it is possible to provide a photosensitive dry film resist which is excellent in flame retardancy, moisture resistance, electric reliability, and anti-warpage property and which has a low imidization temperature.

Of course, the binder polymer may contain (i) the polyamide acid including at least the constitutional units respectively represented by the formulas (2) and (3), depending on cases, a weight average molecular weight of polyamide acid including not only the constitutional units respectively represented by the formulas (2) and (3) but also the constitutional unit represented by the formula (4) or (ii) other polyamide acid as long as this does not have an unfavorable influence on the performance of the resultant photosensitive dry film resist.

Further, the polyamide acid may be a mixture of (i) polyamide acid including the constitutional unit represented by the formula (2) and the constitutional unit represented by the formula (3) and (ii) polyamide acid including the constitutional unit represented by the formula (4) and the constitutional unit represented by the formula (3). Also in such case, it is possible to obtain the same effect as in the case of a copolymerized product including the constitutional unit represented by the formula (2), the constitutional unit represented by the formula (3), and the constitutional unit represented by the formula (4).

In the photosensitive dry film resist according to the present invention, it is preferably so arranged that the binder polymer (A) is polyamide acid including the constitutional unit represented by the formula (2), the constitutional unit represented by the formula (3), depending on cases, also the constitutional unit represented by the formula (4), but the binder polymer (A) may include a constitutional unit represented by the following formula (4) and a constitutional unit represented by the following formula (3).

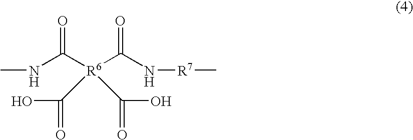

where R⁶ represents a tetravalent organic group and R⁷ has a structure represented by the following formula a, b, c, d, e, f, or g,

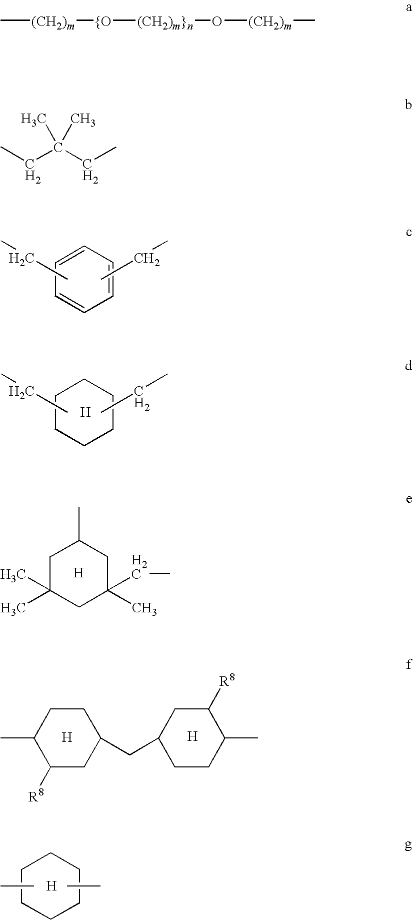

where m of the formula a represents an integer ranging from 1 to 20, n of the formula a represents an integer ranging from 0 to 10, R⁸ of the formula f represents a hydrogen atom, a methyl group, an ethyl group, or a butyl group.

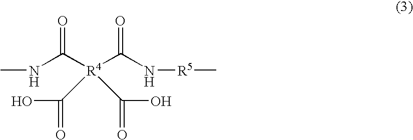

where R⁴ represents a tetravalent organic group, and R⁵ represents a bivalent organic group obtained by excluding two amino groups from aromatic diamine.

Here, the constitutional unit represented by the formula (3) and the constitutional unit represented by the formula (4) are the same as in the case of the polyamide acid including the constitutional unit represented by the formula (2), the constitutional unit represented by the formula (3), depending on cases, also the constitutional unit represented by the formula (4). Thus, descriptions thereof are omitted here.

In the polyamide acid including the constitutional unit represented by the formula (3) and the constitutional unit represented by the formula (4), a molar fraction of the constitutional unit represented by the formula (4) with respect to the entire constitutional units of polyamide acid is preferably 10% or more and less than 90%, more preferably 20% or more and less than 80%, still more preferably 30% or more and less than 70%, particularly preferably 40% or more and less than 60%, where the molar fraction is (mol number of the constitutional unit represented by the formula (4))÷(mol number of the constitutional unit represented by the formula (3)+mol number of the constitutional unit represented by the formula (4))×100. If the molar fraction of the constitutional unit represented by the formula (4) is 10% or more, it is possible to carry out imidization at temperature lower than the conventional imidization temperature of polyamide acid and the like, and it is possible to obtain polyamide acid and the like which are less warped and are excellent in flexibility and bendability.

Further, a weight average molecular weight of polyamide acid including at least the constitutional units respectively represented by the formulas (3) and (4) is preferably 2000 or more and 1000000 or less, more preferably 5000 or more and 300000 or less. If the weight average molecular weight of polyamide acid is less than 2000, the molecular weight of the resultant polyimide drops, which is likely to result in lower strength. Such condition is not preferable. If the weight average molecular weight of polyamide acid is more than 1000000, it is likely to take longer time to develop the photosensitive resin. Also such condition is not preferable.

Further, the weight average molecular weight of polyamide acid including the constitutional unit represented by the formula (3) and the constitutional unit represented by the formula (4) is divided by a number average molecular weight, and the number indicative of weight average molecular weight/number average molecular weight is preferably 2 or more and 10 or less, more preferably 2 or more and 5 or less.

In case where at least any one of the first and second photosensitive layers or more preferably each of the first and second photosensitive layers contains the polyamide acid including the constitutional unit represented by the formula (3) and the constitutional unit represented by the formula (4), it is possible to provide a photosensitive dry film resist which is excellent in flame retardancy, moisture resistance, electric reliability, and anti-warpage property and which has a low imidization temperature.

Note that, at least any one of the first and second photosensitive layers may contain other polyamide acid as long as this does not have an unfavorable influence on the performance of the resultant photosensitive dry film resist.

As the polyamide acid used as the binder polymer of the second photosensitive layer, it is preferable to use polyamide acid used for the first photosensitive layer, but it is possible to use other polyamide acid.

As the polyamide acid used as the binder polymer of the second photosensitive layer, it is possible to use polyamide acid including the constitutional unit represented by the formula (2), the constitutional unit represented by the formula (3), depending on cases, the constitutional unit represented by the formula (4), and it is possible to use polyamide acid including the constitutional unit represented by the formula (3) and the constitutional unit represented by the formula (4). Besides, it is also possible to favorably use polyamide acid including the constitutional unit represented by the formula (3) for example.

A production method of the polyamide acid used in the present invention is not particularly limited as long as the polyamide acid has the foregoing structure. However, an example of the production method is as follows: The polyamide acid including the constitutional unit represented by the formula (2) and the constitutional unit represented by the formula (3) can be produced by reacting acid dianhydride, aromatic diamine, and polysiloxane diamine represented by the following formula (5) in an organic polar solvent.

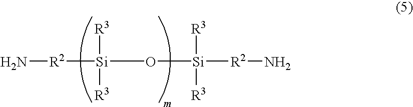

where each R² independently represents an alkylene group whose carbon number is 2 to 5, each R³ independently represents a methyl group or a phenyl group, and a content of a phenyl group of R³ is 15% or more and 40% or less, and m is an integer not less than 4 and not more than 20.

Further, polyamide acid including the constitutional unit represented by the formula (2), the constitutional unit represented by the formula (3), and the constitutional unit represented by the formula (4) can be produced, for example, by reacting acid dianhydride, aromatic diamine, polysiloxane diamine represented by the foregoing formula (5), and a′, b′, c′, d′, e′, f′, or g′ of the following formula group (6) in an organic polar solvent,

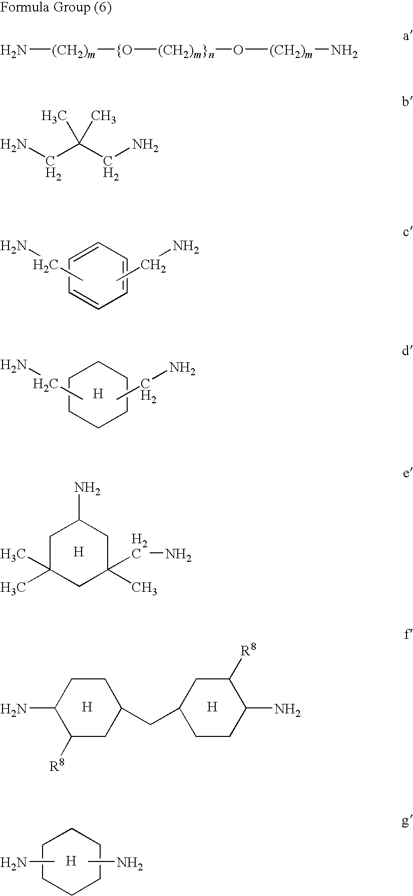

where m of the formula a′ is an integer from 1 to 20, and n of the formula a′ is an integer from 0 to 10, and R⁸ of the formula f′ represents a hydrogen group, a methyl group, an ethyl group, or a butyl group.

Further, polyamide acid including the constitutional unit represented by the formula (3) and the constitutional unit represented by the formula (4) can be produced, for example, by reacting acid dianhydride, aromatic diamine, and a′, b′, c′, d′, e′, f′, or g′ of the formula group (6) in an organic polar solvent.

Note that, in case of using a′, b′, c′, d′, e′, f′, or g′ of the formula group (6), they may be used solely or may be used in combination of two or more kinds.

Further, polyamide acid including the constitutional unit represented by the formula (4) can be produced, for example, by reacting acid dianhydride and aromatic diamine in an organic polar solvent.

In the formula (5), each R2 independently represents an alkylene group whose carbon number is 2 to 5, and specific examples thereof include an ethylene group, a propylene group, a tetramethylene group, or a pentamethylene group.

Further, in the formula (5), each R³ independently represents a methyl group or a phenyl group. Here, a content of the phenyl group and a content of the methyl group of R³ are the same as in the case of R³ of the above-described formula (2), so that descriptions thereof are omitted herein.

Note that, the methyl group of R³ of the formula (5) may be partially replaced by an ethyl group or a propyl group as long as this does not have an unfavorable influence on the performance of the resultant photosensitive resin composition.

Further, also the recurring unit number m of the siloxane bond of the formula (5) is the same as in m of the above-described formula (2), so that descriptions thereof are omitted.

The acid dianhydride is not particularly limited and any acid dianhydride can be used. Note that, a residual group obtained by excluding two chains each of which is indicative of —CO—O—CO— from the acid dianhydride is a favorable example of R¹ of the formula (2) and R⁴ and R⁶. Specific examples of the acid dianhydride include: aromatic tetracarboxylic acid dianhydride such as 3,3′,4,4′-benzophenone tetracarboxylic acid dianhydride, 3,3′,4,4′-biphenylsulfone tetracarboxylic acid dianhydride, 3,3′,4,4′-biphenylether tetracarboxylic acid dianhydride, 2,2′-hexafluoropropyliden diphthalic acid dianhydride, 2,2-bis(4-hydroxyphenyl)propane dibenzoate-3,3′,4,4′-tetracarboxylic acid dianhydride, pyromellitic acid dianhydride, 1,4,5,8-naphthalene tetracarboxylic acid dianhydride, 2,3,6,7-naphthalene tetracarboxylic acid dianhydride, 3,3′,4,4′-dimethyldiphenylsilane tetracarboxylic acid dianhydride, 3,3′,4,4′-tetraphenylsilane tetracarboxylic acid dianhydride, 1,2,3,4-furan tetracarboxylic acid dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis(3,4-dicarboxyphenoxy)diphenylpropane dianhydride, 3,3′,4,4′-perfluoroisopropyliden diphthalic acid dianhydride, 3,3′,4,4′-biphenyltetracarboxylic acid dianhydride, bis(phthalic acid)phenylphosphinoxide dianhydride, p-phenylene-bis(triphenyl phthalic acid)dianhydride, m-phenylene-bis(triphenyl phthalic acid)dianhydride, bis(triphenyl phthalic acid)-4,4′-diphenylether dianhydride, and bis(triphenyl phthalic acid)-4,4′-diphenylmethane dianhydride; and aliphatic or alicylic tetracarboxylic acid dianhydride such as 1,2,3,4-cyclobutane tetracarboxylic acid dianhydride, 1,3-dimethyl-1,2,3,4-cyclobutane tetracarboxylic acid, butane tetracarboxylic acid dianhydride, 1,2,3,4-cyclopentane tetracarboxylic acid dianhydride, 2,3,5-tricarboxycyclopentyl acetic acid dianhydride, 3,5,6-tricarboxynorbornane-2-acetic acid dianhydride, 2,3,4,5-tetrahydrofuran tetracarboxylic acid dianhydride, 5-(2,5-dioxotetrahydrofural)-3-methyl-3-cyclohexene-1,2-dicarboxylic acid dianhydride, and bicyclo[2,2,2]-octo-7-ene-2,3,5,6-tetracarboxylic acid dianhydride; and the like. These tetracarboxylic acid dianhydrides may be used solely or may be used in combination of two or more kinds.

Above all, as the acid dianhydride, it is more preferable to use aromatic tetracarboxylic acid dianhydride in view of excellent flame retardancy of the resultant polyimide.

Further, in order to obtain polyimide whose solubility with respect to an organic solvent is high, it is more preferable to include, as the acid dianhydride, at least one of 3,3′,4,4′-biphenylsulfone tetracarboxylic acid dianhydride, 2,2′-hexafluoropropyliden diphthaliac acid dianhydride, 2,3,3′,4′-bipheny tetracarboxylic acid dianhydride, 4,4-(4,4′-isopropylidendiphenoxy)bisphthalic acid anhydride, 2,2-bis(4-hydroxyphenyl)propandibenzoate-3,3′,4,4′-tetracarboxylic acid dianhydride, 3,3′,4,4′-biphenylether tetracarboxylic acid dianhydride, 3,3′,4,4′-tetraphenylsilane tetracarboxylic acid dianhydride, or 1,2-ethanedibenzoate-3,3′,4,4′-tetracarboxylic acid dianhydride.

Further, in view of industrially low cost, it is preferable to use 3,3′,4,4′-benzophenone tetracarboxylic acid dianhydride, 3,3′,4,4′-biphenylsulfone tetracarboxylic acid dianhydride, 3,3′,4,4′-biphenylether tetracarboxylic acid dianhydride, 2,2′-hexafluoropropyliden diphthalic acid dianhydride, 2,2-bis(4-hydroxyphenyl)propandibenzoate-3,3′,4,4′-tetracarboxylic acid dianhydride, and pyromellitic acid dianhydride.

Further, the aromatic diamine is not particularly limited, and any aromatic diamine can be used. Such aromatic diamine is not particularly limited, but examples thereof include: aromatic diamine such as p-phenylene diamine, m-phenylene diamine, 4,4′-diamino diphenylmethane, 4,4′-diaminodiphenylethane, 4,4′-diaminodiphenylether, 3,4′-diaminodiphenylether, 3,3′-diaminodiphenylether, 4,4′-diaminodiphenylsulfide, 4,4′-diaminodiphenylsulfone, 1,5-diaminonaphthalene, 3,3-dimethyl-4,4′-diaminobiphenyl, 5-amino-1-(4′-aminophenyl)-1,3,3-trimethylindan, 6-amino-1-(4′-aminophenyl)-1,3,3-trimethylindan, 4,4′-diaminobenzanilide, 3,5-diamino-3′-trifluoromethyl benzanilide, 3,5-diamino-4′-trifluoromethyl benzanilide, 3,4′-diaminodiphenylether, 2,7-diaminofluorene, 2,2-bis(4-aminophenyl)hexafluoropropane, 3,3′-dimethoxy-4,4′-diaminobiphenyl, 4,4′-diamino-2,2′-bis(trifluoromethyl)biphenyl, 2,2-bis[4-(4-aminophenoxy)phenyl]propane, 2,2-bis[4-(4-aminophenoxy)phenyl]hexafluoropropane, 1,4-bis(4-aminophenoxy)benzene, 4,4′-bis(4-aminophenoxy)-biphenyl, 4,4′-bis(3-aminophenoxy)-biphenyl, 1,3′-bis(4-aminophenoxy)benzene, 1,3-bis(3-aminophenoxy)benzene, 9,9-bis(4-aminophenyl)fluorene, 4,4′-(p-phenyleneisopropyliden)bisaniline, 4,4′-(m-phenyleneisopropyliden)bisaniline, 2,2′-bis[4-(4-amino-2-trifluoromethylphenoxy)phenyl]hexafluoropropane, and 4,4′-bis[4-(4-amino-2-trifluoromethyl)phenoxy]-octafluorobiphenyl; aromatic diamine having (i) two amino groups coupled to an aromatic and (ii) a hetero atom other than a nitrogen atom of each amino group such as diaminotetraphenylthiophene; diamino resorcinols such as 4,6-diamino resorcinol; hydroxybiphenyl compounds such as 3,3′-diamino-4,4′-dihydroxybiphenyl, 4,4′-diamino-3,3′-dihydroxybiphenyl, 4,4′-diamino-2,2′-dihydroxybiphenyl, and 4,4′-diamino-2,2′,5,5′-tetrahydroxybiphenyl; hydroxy diphenylmethanes or hydroxy diphenylalkanes such as 3,3′-diamino-4,4′-dihydroxydiphenylmethane, 2,2-bis[3-amino-4-hydroxyphenyl]propane, 2,2-bis[4-amino-3-hydroxyphenyl]propane, 2,2-bis[3-amino-4-hydroxyphenyl]hexafluoropropane, and 4,4′-diamino-2,2′,5,5′-tetrahydroxydiphenylmethane; hydroxydiphenylether compounds such as 3,3′-diamino-4,4′-hydroxydiphenylether, 4,4′-diamino-3,3′-dihydroxydiphenylether, 4,4′-diamino-2,2′-dihydroxydiphenylether, and 4,4′-diamino-2,2′,5,5′-tetrahydroxydiphenylether; diphenylsulfone compounds such as 3,3′-diamino-4,4′-dihydroxydiphenylsulfone, 4,4′-diamino-3,3′-dihydroxydiphenylsulfone, 4,4′-diamino-2,2′-dihydroxydiphenylsulfone, and 4,4′-diamino-2,2′,5,5′-tetrahydroxydiphenylsulfone; bis[(hydroxyphenoxy)phenyl]alkane compounds such as 2,2-bis[4-(4-amino-3-hydroxyphenoxy)phenyl]propane; bis[(hydroxyphenoxy)phenyl]sulfone compounds such as bis[4-(4-amino-3-hydroxyphenoxy)phenyl]sulfone and bis[4-(3-amino-4-hydroxyphenoxy)phenyl]sulfone; diamino phenols such as 2,4-diaminophenol; bis(hydoxyphenoxy)biphenyl compounds such as 3,3′-diamino-4,4′-dihydroxybiphenyl, 4,4′-diamino-3,3′-dihydroxydiphenylmethane, 4,4′-diamino-2,2-dihydroxydiphenylmethane, 2,2′-bis[3-amino-4-hydroxyphenyl]propane, and 4,4′-bis(4-amino-3-hydoxyphenoxy)biphenyl; diamino phthalic acids such as 2,5-diamino terephthalic acid; carboxy biphenyl compounds such as 3,3′-diamino-4,4′-dicarboxybiphenyl, 4,4′-diamino-3,3′-dicarboxybiphenyl, 4,4′-diamino-2,2′-dicarboxybiphenyl, and 4,4′-diamino-2,2′,5,5′-tetracarboxybiphenyl; carboxy diphenylalkanes such as 3,3′-diamino-4,4′-dicarboxydiphenylmethane, 2,2-bis[3-amino-4-carboxyphenyl]propane, 2,2-bis[4-amino-3-carboxyphenyl]propane, 2,2-bis[3-amino-4-carboxyphenyl]hexafluoropropane, and 4,4′-diamino-2,2′,5,5′-tetracarboxydiphenylmethane; carboxydiphenylether compounds such as 3,3′-diamino-4,4′-dicarboxydiphenylether, 4,4′-diamino-3,3′-dicarboxydiphenylether, 4,4′-diamino-2,2′-dicarboxydiphenylether, and 4,4′-diamino-2,2′,5,5′-tetracarboxydiphenylether; diphenylsulfone compounds such as 3,3′-diamino-4,4′-dicarboxydiphenylsulfone, 4,4′-diamino-3,3′-dicarboxydiphenylsulfone, 4,4′-diamino-2,2′-dicarboxydiphenylsulfone, and 4,4′-diamino-2,2′,5,5′-tetracarboxydiphenylsulfone; bis[(carboxyphenoxy)phenyl]alkane compounds such as 2,2-bis[4-(4-amino-3-carboxyphenoxy)phenyl]propane; bis[(carboxyphenoxy)phenyl]sulfone compounds such as 2,2-bis[4-(4-amino-3-carboxyphenoxy)phenyl]sulfone; diamino benzoic acids such as 3,5-diamino benzoic acid; and the like. These aromatic diamines may be used solely or may be used in combination of two or more kinds.

Above all, as described, the aromatic diamine is more preferably such that at least one of aromatic rings coupled to the two amino groups of the aromatic diamine has two bonds at a meta position with respect to a main chain, and the aromatic diamine more preferably has an amino group at a meta position as exemplified above. This makes it possible to lower an imidization temperature of the polyamide acid precursor and the like. Further, also aromatic diamine having an amino group at a meta position may be used solely or may be used in combination of two or more kinds.

An order in which the acid anhydride, the aromatic diamine, and polysiloxane diamine or diamine of the formula group (6) are reacted in the organic polar solvent is not particularly limited. The acid anhydride, the aromatic diamine, and polysiloxane diamine or diamine of the formula group (6) may be reacted at the same time, or reaction may be carried out by adding aromatic diamine after initiation of reaction of the acid dianhydride and polysiloxane diamine or diamine of the formula group (6), or reaction may be carried out by adding polysiloxane or diamine of the formula group (6) after reaction of the acid dianhydride and aromatic diamine.

Above all, it is more preferable to carry out reaction by adding aromatic diamine after initiation of reaction of acid dianhydride and polysiloxane diamine or diamine of the formula group (6).

In such case, the acid dianhydride is first reacted with polysiloxane diamine or diamine of the formula group (6) in an organic polar solvent. For example, polysiloxane diamine or diamine of the formula group (6) or solution thereof is added to solution or suspended solution made of acid dianhydride and organic polar solvent. Subsequently, aromatic diamine is added, thereby obtaining polyimide precursor (polyamide acid) used in the present invention.

Further, an order in which the acid dianhydride, aromatic diamine, polysiloxane diamine, and diamine of the formula group (6) are reacted in the organic polar solvent is not particularly limited, and the acid dianhydride, aromatic diamine, polysiloxane diamine, and diamine of the formula group (6) may be reacted at the same time. Further, it may be so arranged that reaction of acid dianhydride and polysiloxane diamine is initiated and then diamine of the formula group (6) is reacted therewith and subsequently aromatic diamine is added. Further, it may be so arranged that reaction of acid dianhydride and aromatic diamine is initiated and then polysiloxane diamine is reacted therewith and subsequently diamine of the formula group (6) is added.

The organic polar solvent is not particularly limited, but examples thereof include dimethylsulfoxide, N,N′-dimethylformamide, N,N′-diethylformamide, N,N′-dimethylacetamide, N,N-diethylacetamide, N-methylpyrrolidone, hexamethylphosphotriamide, dioxolane, tetrahydrofuran, 1,4-dioxane, acetnitryl, and the like. These organic polar solvents may be used solely or may be used in combination of two or more kinds. At this time, the reaction of acid dianhydride with polysiloxane diamine and/or diamine of the formula group (6) is carried out in the organic polar solvent preferably at −20° C. or higher and 80° C. or lower, more preferably at −15° C. or higher and 50° C. or lower. If the reaction temperature is set to −20° C. or higher, it is possible to react acid dianhydride with polysiloxane diamine and/or diamine of the formula group (6). Further, a reaction duration in reacting acid dianhydride with polysiloxane diamine and/or diamine of the formula group (6) is not particularly limited, but the reaction duration is preferably 1 to 12 hours.

At this time, a mol number of the acid dianhydride to be reacted is preferably more than a mol number of polysiloxane diamine and/or diamine of the formula group (6). This makes it possible to obtain polyimide precursor (polyamide acid) oligomer of acid dianhydride end.

Subsequently, a reaction temperature in carrying out reaction by adding aromatic diamine thereto is preferably −20° C. or higher and 80° C. or lower, more preferably -15 or higher and 50° C. or lower. By setting the reaction temperature within such temperature range, it is possible to favorably carry out copolymerization with aromatic diamine. Further, a reaction duration in carrying out reaction by adding aromatic diamine is not particularly limited, but the reaction duration is preferably 0.5 to 24 hours for example.

When a molar ratio of the aromatic diamine exceeds 90 mol % with respect to the entire diamine, its imidization temperature is likely to rise, so that the molar ratio is preferably 90 mol % or less, and more preferably 80 mol % or less.

In case where a temperature of 5 g/l of N-methylpyrrolidone is 30° C., a logarithmic viscosity of polyamide acid of the present invention is preferably 0.2 to 4.0, more preferably 0.3 to 2.0.

(1-2-3) Soluble Polyimide having Carboxyl Group and/or Hydroxyl Group

In view of flame retardancy and heat resistance, it is preferable to use, as the binder polymer, soluble polyimide having carboxyl group and/or hydroxyl group. Further, the soluble polyimide has been imidized, so that the soluble polyimide allows a temperature in hot cure to be set low and allows a hot cure duration to be set short. This results in high productivity.

The soluble polyimide is not particularly limited as long as the polyimide can be dissolved in an organic solvent. However, in the present invention, the polyimide preferably has solubility of 1.0 g in 100 g of the organic solvent at 20° C. The solubility is more preferably 5.0 g or more at 20° C. and still more preferably 10 g or more at 20° C. If the solubility in 100 g of the organic solvent is less than 1.0 g at 20° C., it is likely to be difficult to form a photosensitive dry film resist having a desired thickness. The organic solvent is not particularly limited, but examples thereof include: formamide solvents such as N,N-dimethylformamide and N,N-diethylformamide; ether solvents such as 1,4-dioxane, 1,3-dioxolane, and tetrahydrofuran; and the like.

A weight average molecular weight of the soluble polyimide having carboxyl group and/or hydroxyl group is not particularly limited, the weight average molecular weight is preferably 5000 to 300000, more preferably 10000 to 200000. If the weight average molecular weight is less than 5000, the photosensitive dry film resist produced by using the photosensitive resin composition of the present invention is likely to be cloggy, so that the film having been cured is likely to deteriorate in bendability. On the other hand, if the weight average molecular weight is more than 200000, a solution viscocity of the soluble polyimide having carboxyl group and/or hydroxyl group is too high, so that it is likely to be difficult to handle the soluble polyimide, and the resultant photosensitive dry film resist may have insufficient developing property. Note that, the weight average molecular weight can be measured by size exclusion chromatography (SEC), for example, by HLC8220GPC (product of TOSOH CORPORATION).

Further, a weight average molecular weight of each carboxyl group and/or each hydroxyl group of the soluble polyimide having carboxyl group and/or hydroxyl group (hereinafter, this weight average molecular weight is referred to as “acid equivalence”) is preferably 7000 or less, more preferably 5000 or less, most preferably 3000 or less. If the acid equivalence exceeds 7000, it is likely to be difficult to carry out water system development of the photosensitive dry film resist produced by using the photosensitive resin composition of the present invention. Note that, the acid equivalence of the soluble polyimide can be obtained by calculation based on a composition of the soluble polyimide having carboxyl group and/or hydroxyl group.

### <Production Method of Polyimide>

In order to explain a production method of the soluble polyimide having carboxyl group and/or hydroxyl group, the following will detail a method for synthesizing polyamide acid and a method for imidizing polyamide acid by carrying out dehydration ring closure.

### <Synthesis of Polyamide Acid>

The soluble polyimide having carboxyl group and/or hydroxyl group can be obtained from polyamide acid serving as a precursor thereof. The polyamide acid can be obtained by reacting diamine and acid dianhydride in an organic solvent. Specifically, in an inert gas atmosphere such as argon, nitrogen, and the like, diamine is dissolved in an organic solvent or is dispersed in a slurry manner so as to prepare a diamine solution. While, the acid dianhydride is dissolved in an organic solvent or is dispersed in a slurry manner. Thereafter or in a solid state, the resultant is added to the diamine solution.

The diamine used to synthesize polyamide acid serving as a precursor of the soluble polyimide of the present invention which soluble polyimide has carboxyl group and/or hydroxyl group is not particularly limited. However, in view of the water system developing property, it is preferable to use diamine, having one or more carboxyl groups and/or one or more hydroxyl groups in its molecule, as at least a part of the raw material. Further, in view of heat resistance and anti-chemical property, it is preferable to use aromatic diamine, having one or more aromatic rings in its molecule, as at least a part of the raw material. Particularly, if aromatic diamine having one or more carboxyl groups and/or one or more hydroxyl groups in its molecule is used as a part of the raw material, this is particularly preferable since it is possible to give the resultant photosensitive dry film resist the heat resistance and the water system developing property.

The aromatic diamine having carboxyl group and/or hydroxyl group is not particularly limited, but it is preferable to use, as a part of the raw material of the soluble polyimide, aromatic diamine represented by the following formula (7),

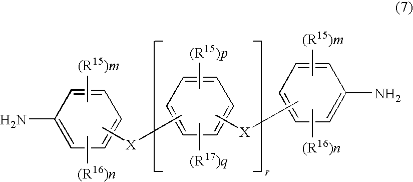

where R¹⁵ may be the same as or different from other R¹⁵ and represents a carboxyl group or a hydroxyl group, R¹⁶ may be the same as or different from other R¹⁶ and R¹⁷ may be the same as or different from other R¹⁷ and each of R¹⁶ and R¹⁷ represents a hydrogen atom, an alkyl group whose carbon number is 1 to 9, an alkoxy group whose carbon number is 2 to 10, or —COOR¹⁸ (R¹⁸ represents an alkyl group whose carbon number is 1 to 9), X may be the same or different from other X and represents —O—, —S—, —SO₂—, —C(CH₃)₂—, —CH₂—, —C(CH₃)(C₂H₅)—, or —C(CF₃)₂—, and m is an integer not less than 1 and n is an integer not less than 0 so that m+n=4, and p is an integer not less than 1 and q is an integer not less than 0 so that p+q=4, and r is an integer from 0 to 10.

The aromatic diamine having carboxyl group is not particularly limited, but examples thereof include: diamino benzoic acid such as 3,5-diamino benzoic acid; carboxy biphenyl compounds such as 3,3′-diamino-4,4′-dicarboxybiphenyl, 4,4′-diamino-2,2′,5,5′-tetracarboxybiphenyl; carboxydiphenyl alkanes such as 4,4′-diamino-3,3′-dicarboxydiphenylmethane and 3,3′-diamino-4,4′-dicarboxydiphenylmethane; carboxy diphenylether compounds such as 4,4′-diamino-2,2′,5,5′-tetracarboxydiphenylether; diphenylsulfone compounds such as 3,3′-diamino-4,4′-dicarboxydiphenylsulfone; bis(caroxyphenoxy)biphenyl compounds such as 2,2-bis[4-(4-amino-3-carboxyphenoxy)phenyl]propane; bis[(carboxyphenoxy)phenyl]sulfone compounds such as 2,2-bis[4-(4-amino-3-carboxyphenoxy)phenyl]sulfone; and the like.

Above all, a part of a constitutional formula of particularly preferable aromatic diamine having carboxyl group is as follows.

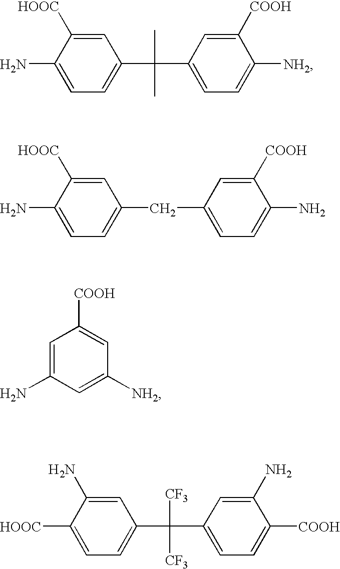

Next, the aromatic diamine having hydroxyl group is not particularly limited, but examples thereof include: compounds such as 2,2′-diaminobisphenol A, 2,2′-bis(3-amino-4-hydroxyphenyl)hexafluoropropane, bis(2-hydroxy-3-amino-5-methylphenyl)methane, 2,6-di[(2-hydroxy-3-amino-5-methylphenyl)methyl]-4-methylphenol, 2,6-di[(2-hydroxy-3-amino-5-methyphenyl)methyl]-4-hydroxybenzoic acid propyl, and the like.

Above all, a part of a constitutional formula of particularly preferable aromatic diamine having hydroxyl group is as follows.

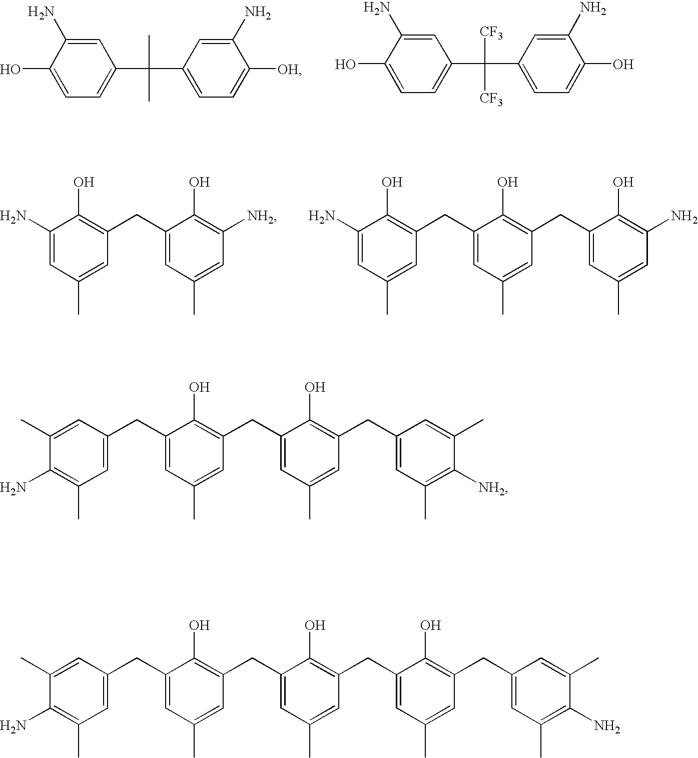

If these diamines are used as part of the raw material, the acid equivalence of the resultant soluble polyimide having carboxyl group and/or hydroxyl group is lowered, which results in improvement of the water system developing property.

Note that, it is needless to say that, in addition to the diamine having carboxyl group and/or hydroxyl group, other known diamine may be used at the same time as a part of the raw material of the soluble polyimide. Examples of other known diamine include compounds such as bis[4-(3-aminophenoxy)phenyl]sulfone, [bis(4-amino-3-carboxy)phenyl]methane, polysiloxane diamine represented by the formula (1), and the like. Particularly, it is preferable to use polysiloxane diamine represented by the formula (1) since this polysiloxane diamine can improve flexibility, adhesiveness, and bendability. The diamines can be used solely or can be used in combination of two or more kinds.

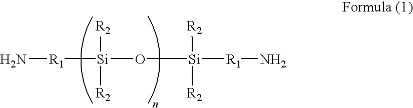

where each R₁ independently represents a hydrocarbon whose carbon number is 1 to 5, and each R₂ independently represents an organic group selected from an alkyl group whose carbon number is 1 to 5 and a phenyl group, and n is an integer from 1 to 20.

While, acid dianhydride used to synthesize polyamide acid is not particularly limited. However, in view of improvement of heat resistance, it is preferable to use acid dianhydride having 1 to 4 aromatic ring(s) or alicyclic acid dianhydride. Further, in order to obtain a polyimide resin whose solubility with respect to an organic solvent is high, it is preferable to use at least part of acid dianhydride having two or more aromatic rings, and it is more preferable to use at least part of acid dianhydride having four or more aromatic rings.

Examples of the acid dianhydride include: aliphatic or alicyclic tetracarboxylic acid dianhydride such as butane tetracarboxylic acid dianhydride and 1,2,3,4-cyclobutane tetracarboxylic acid dianhydride; aromatic tetracarboxylic acid dianhydride such as pyromellitic acid dianhydride, 3,3′,4,4′-benzophenone tetracarboxylic acid dianhydride, 3,3′,4,4′-biphenylsulfone tetracarboxylic acid dianhydride, 2,2-bis(hydroxyphenyl)propanedibenzoate-3,3′,4,4′-tetracarboxylic acid dianhydride, 2,3′,3,4′-biphenylether tetracarboxylic acid dianhydride, 3,4,3′,4′-biphenylether tetracarboxylic acid dianhydride, and biphenyl-3,4,3′,4′-tetracarboxylic acid dianhydride; and aliphatic tetracarboxylic acid dianhydride having aromatic ring, such as 1,3,3a,4,5,9b-hexahydro-2,5-dioxo-3-furanyl-naptho[1,2-c]furan-1,3-dione, and the like. The acid dianhydrides may be used solely or used in combination of two or more kinds.

Out of the acid dianhydrides, in view of easiness to synthesize and solubility of the resultant polyimide with respect to an organic solvent, it is preferable to use at least part of acid dianhydride having two or more aromatic rings, such as 2,2-bis(hydroxyphenyl)propane dibenzoate-3,3′,4,4′-tetracarboxylic acid dianhydride, 2,3′,3,4′-biphenylether tetracarboxylic acid dianhydride, 3,4,3′,4′-biphenylether tetracarboxylic acid dianhydride, and biphenyl-3,4,3′,4′-tetracarboxylic acid dianhydride.

In case of synthesizing polyamide acid by using the diamine and acid dianhydride, at least one kind of the diamine and at least one kind of the acid dianhydride are used to carry out reaction. That is, for example, a diamine component at least partially containing diamine having carboxyl group and/or hydroxyl group and the acid dianhydride are used so as to carry out polymerization reaction in an organic solvent as described above, thereby obtaining polyamide acid having one or more carboxyl groups and/or one or more hydroxyl groups in its molecule.

At this time, if one kind of diamine and one kind of acid dianhydride are substantially equal to each other in terms of mol, this results in polyamide acid containing one kind of acid dianhydride component and one kind of diamine component. Further, in case of using two or more kinds of acid dianhydride components and two or more kinds of diamine components, it is possible to intentionally obtain polyamide acid copolymer as long as a molar ratio of an entire amount of plural diamine components and a molar ratio of an entire amount of plural diamine components are substantially equal to each other.

A temperature at which the diamine and the acid dianhydride are reacted (synthesis reaction of polyamide acid) is not particularly limited, but the reaction temperature is preferably −20° C. or higher and 80° C. or lower, and more preferably −15° C. or higher and 50° C. or lower. If the reaction temperature exceeds 80° C., polyamide acid may be decomposed. Adversely, if the reaction temperature is −20° C. or lower, the polymerization reaction may proceed more slowly. Further, a reaction duration may be arbitrarily set within a range of 10 minutes to 30 hours.

Further, the organic solvent used to carry out the synthesis reaction of polyamide acid is not particularly limited as long as the organic solvent is an organic polar solvent. However, as the reaction of the diamine and the acid dianhydride proceeds, polyamide acid is generated, which results in rise of the viscosity of the reaction solution. Further, as described later, removal of the organic solvent and imidization can be carried out at the same time by heating the polyamide acid solution, obtained by synthesizing polyamide acid, under reduced pressure. Thus, as the organic solvent, it is advantageous to select an organic solvent, which can dissolve polyamide acid and whose boiling point is as low as possible, in view of production steps.

Specific examples of the organic solvent used to carry out the synthesis reaction of polyamide acid include: a formamide solvent such as N,N-dimethylformamide; an acetamide solvent such as

N,N-dimethylacetamide; a pyrrolidone solvent such as N-methyl-2-pyrrolidone and N-vinyl-2-pyrrolidone; an ether solvent such as tetrahydrofuran, dioxane, and dioxolane; and the like.

### <Imidization of Polyamide Acid>

Next, the following describes a method for imidizing the polyamide acid by using the polyamide acid for polyimide. The polyamide acid is imidized by carrying out dehydration ring closure of the polyamide acid. The dehydration ring closure can be carried out by (i) an azeotropy process using azeotropic solvent, (ii) a thermal process, or (iii) a chemical process.

In the azeotropy process using the azeotropic solvent, a solvent which is azeotropic with water such as toluene and xylene is added to the polyamide acid solution, and a temperature thereof is raised at 170 to 200° C., and reaction is carried out for one to five hours while positively excluding, from the system, water generated by dehydration ring closure. After the reaction, precipitation is caused in an alcohol solvent such as methanol, and the resultant of the precipitation is rinsed with an alcohol solvent as necessary and then is dried, thereby obtaining a polyimide resin.

The dehydration ring closure based on the thermal process is carried out by heating the polyamide acid solution. Alternatively, the polyamide acid solution is made to flow in a spreading manner or is applied to a film-shape support such as a glass plate, a metal plate, a PET (polyethylene terephthalate), and the like, and then the film-shape support is heated at a temperature ranging from 80° C. to 300° C. Further, the polyamide acid solution is poured directly into a container subjected to a releasing treatment such as coating with fluororesin, and the polyamide acid solution is heated so as to be dried under reduced pressure, thereby carrying out dehydration ring closure of polyamide acid. The dehydration ring closure of polyamide acid based on such thermal process makes it possible to obtain polyimide.

Note that, a heating duration in each treatment varies depending on an amount of the polyamide acid solution to be subjected to the dehydration ring closure and a heating temperature, but it is general that the heating treatment is preferably carried out in one minute to five hours after the treatment temperature reaches the maximum temperature.

While, in the dehydration ring closure based on the chemical process, as necessary, tertiary amine whose amount corresponds to a catalyst amount is added as catalyst, as well as a dehydrating agent, to the polyamide acid solution, and the resultant mixture is heated. Note that, this heating treatment is based on the thermal process. This makes it possible to obtain polyimide.

As the dehydrating agent of the chemical process, it is general to use acid anhydride such as acetic anhydride, propionic anhydride, and the like. Further, as the tertiary amine, it is possible to use pyridine, isoquinoline, triethylamine, trimethylamine, imidazole, picoline, and the like.

Note that, in case where the soluble polyimide of the present invention has hydroxyl group, the hydroxyl group may react with acid anhydride added as the dehydrating agent, so that it is preferable that an amount of the acid anhydride is stoichiometrically minimum required in the imidization.

### (I-3) (Meth)acrylic Compound

Next, the (meth)acrylic compound serving as the component (B) is described as follows. The photosensitive resin composition includes the component (B), so that it is possible not only to give a favorable curing property but also to give flowability at the time of heat lamination by lowering viscoelasticity in heating the resultant photosensitive dry film resist. That is, heat lamination at relatively low temperature can be realized, so that it is possible to fill dents of the circuit.

In the present invention, (meth)acrylic compound is a compound selected from a group made up of (meth)acryl compound, epoxy(meth)acrylate, polyester(meth)acrylate, urethane(meth)acrylate, and imide(meth)acrylate. Note that, in the present invention, (meth)acryl refers to acryl compound and/or methacryl compound.

The (meth)acrylic compounds may be used solely or may be used in combination of two or more kinds. A total amount of (meth)acrylic compound included in the photosensitive resin composition of the present invention preferably ranges from 1 to 400 parts by weight, more preferably from 3 to 300 parts by weight, still more preferably from 1 to 200 parts by weight, particularly preferably from 1 to 100 parts by weight, with respect to 100 parts by weight of the binder polymer serving as the component (A).

In case of using more than 200 parts by weight of (meth)acrylic compound as the component (B) with respect to 100 parts by weight of the binder polymer serving as the component (A), the resultant photosensitive dry film resist is likely to be cloggy.

The component (B) of photosensitive resin composition of the present invention is not particularly limited, but it is preferable to use multifunctional (meth)acryl compound having at least two carbon-carbon double bonds in order to improve cross-linked density based on light irradiation. Further, it is preferable to use a compound having at least one aromatic ring and/or at least one heterocycle in its molecule in order to give heat resistance to the resultant photosensitive dry film resist.

The (meth)acrylic compound having at least one aromatic ring and/or at least one heterocicle in its molecule and having at least two carbon-carbon double bonds is not particularly limited, but examples thereof include: bisphenol A EO denaturalized di(meth)acrylate such as ARONIX M-210 and ARONIX M-211B (products of TOAGOSEI CO., LTD.), NK ester A-BPE-4, NK ester A-BPE-10-, and NK ester A-BPE-30; bisphenol F EO denaturalized (n=2 to 20) di(meth)acrylate such as ARONIX M-208 (product of TOAGOSEI CO., LTD.); bisphenol A PO denaturalized (n=2 to 20) di(meth)acrylate such as denacol acrylate DA-250 (product of Nagase Chemical Industries Co., Ltd.); and the like. Further, as the (meth)acrylic compound having no aromatic ring, for example, it is possible to use: isocyanuric acid EO denaturalized diacrylate such as ARONIX M-215; and isocyanuric acid EO denaturalized triacrylate such as ARONIX M-315 (product of TOAGOSEI CO., LTD.) and the like. Note that, the “EO denaturalized” means that there is an ethylene oxide denaturalized part, and the “PO denaturalized” means that there is a propylene oxide denaturalized part.

Further, in order to control the developing property, it is preferable to use (meth)acryl compound having alcohol hydroxyl group. The (meth)acryl compound having alcohol hydroxyl group has excellent compatibility with base polymer.

Examples of the (meth)acryl compound having alcohol hydroxyl group include pentaerythritol tri(meth)acrylate, V#2308, V#2323 (products of Osaka Organic Chemical Industry Ltd.), and the like.

Further, by using (meth)acrylic compound having at least one epoxy group and at least one (meth)acryl group in its molecule, it is possible to improve hydrolysis resistance of the resultant photosensitive dry film resist and its bonding property with respect to the copper foil.

The (meth)acrylic compound having at least one epoxy group and at least one (meth)acryl group in its molecule is not particularly limited, but examples thereof include: glycidyl compound such as glycidyl methacrylate; NK-oligo EA-1010, NK-oligo EA-6310 (products of SHIN-NAKAMURA CHEMICAL CO., LTD.), and the like.

Further, it is preferable to use epoxy(meth)acrylate having at least two hydroxyl groups in its molecule. By using such epoxy (meth)acrylate, it is possible to improve the solubility of the resultant photosensitive dry film resist with respect to the water system developer, thereby reducing the time taken to complete the development.

The epoxy (meth)acrylate having at least two hydroxyl groups in its molecule is not particularly limited, but examples thereof include: bisphenol A type epoxy acrylate such as LIPDXY SP-2600 (product of Showa Highpolymer Co., Ltd.), NK oligo EA-1020 and NK oligo EA-6340 (products of SHIN-NAKAMURA CHEMICAL CO., LTD.), KARAYAD R-280 and KARAYAD R-190 (products of Nippon Kayaku Co., Ltd.), and Ebercryl 600 and Ebercryl 3700 (products of DAICEL-UCB Company LTD.); denaturalized bisphenol A type epoxy acrylate such as KRM 7856, Ebercryl 3604, Ebercryl 3702, Ebercryl 3703, and Ebercryl 3708 (all of which are products of DAICEL-UCB Company LTD.), and LR 9019 (BASF); aliphatic epoxy acrylate such as LR 8765 (BASF); phenolnovolak epoxy acrylate such as NK oligo EA-6320 and NK oligo EA-6340. (products of SHIN-NAKAMURA CHEMICAL CO., LTD.); denaturalized 1,6-hexanediol diacrylate such as KARAYAD R-167 and MAX-2104 (products of Nippon Kayaku Co., Ltd.), and denacol acrylate DA-212 (product of Nagase Chemical Industries Co., Ltd.); denaturalized phthalate diacrylate such as denacol acrylate DA-721 (product of Nagase Chemical Industries Co., Ltd.); cresol novolak epoxy acrylate such as NK oligo EA-1020 (product of SHIN-NAKAMURA CHEMICAL CO., LTD.); and the like.

By using polyester (meth)acrylate, it is possible to give the flexibility to the resultant photosensitive resin film. The polyester (meth)acrylate is not particularly limited, but examples thereof include ARONIX M-5300, ARONIX M-6100, and ARONIX M-7100 (all of which are products of TOAGOSEI CO., LTD.), and the like.

By using urethane(meth)acrylate, it is possible to give the flexibility to the resultant photosensitive resin film. The urethane(meth)acrylate is not particularly limited, but examples thereof include ARONIX M-1100 and ARONIX M-1310 (products of TOAGOSEI CO., LTD.), KARAYAD UX-4101 (product of Nippon Kayaku Co., Ltd.), and the like.

By using imide(meth)acrylate, it is possible to improve the adhesiveness of the base material (polyimide film, copper foil, and the like) with which the resultant photosensitive resin film is combined. The imide(meth)acrylate is not particularly limited, but examples thereof include ARONIX TO-1534, ARONIX TO-1429, and ARONIX TO-1428 (products of TOAGOSEI CO., LTD.).

Further examples of the (meth)acrylic compound include bisphenol F EO denaturalized (n=2 to 50) diacrylate, bisphenol A EO denaturalized (n=2 to 50) diacrylate, bisphenol S EO denaturalized (n=2 to 50) diacrylate, 1,6-hexandiol diacrylate, neopentylglycol diacrylate, ethyleneglycol diacrylate, pentaerythritol diacrylate, trimethylolpropane triacrylate, pentaerythritol triacrylate, dipentaerythritol hexaacrylate, tetramethylol propane tetraacrylate, tetraethyleneglycol diacrylate; 1,6-hexanediol dimethacrylate, neopentylglycol dimethacrylate, ethyleneglycol dimethacrylate, pentaerythritol dimethacrylate, trimethylol propane trimethacrylate, pentaerythritol trimethacrylate, dipentaerythritol hexamethacrylate, tetramethylol propane tetramethacrylate, tetraethyleneglycol dimethacrylate, methoxydiethyleneglycol methacrylate, methoxypolyethyleneglycol methacrylate, β-metachroyl oxyethyl hydrogen phthalate, β-metachroyl oxyethyl hydrogen succinate, 3-chloro-2-hydroxypropyl methacrylate, steallyl methacrylate, phenoxyethyl acrylate, phenoxydiethyleneglycol acrylate, phenoxypolyethyleneglycol acrylate, β-acryloyloxtethyl hydrogen succinate, lauryl acrylate, ethyleneglycol dimethacrylate, diethyleneglycol dimethacrylate, triethyleneglycol dimethacrylate, polyethyleneglycol dimethacrylate, 1,3-buthyleneglycol dimethacrylate, 1,6-hexanediol dimethacrylate, neopentylglycol dimethacrylate, polypropyleneglycol dimethacrylate, 2-hydroxy-1,3dimethachroxypropane, 2,2-bis[4-(methachroxyethoxy)phenyl]propane, 2,2-bis[4-(methachroxy diethoxy)phenyl]propane, 2,2-bis[4-(methachroxy polyethoxy)phenyl]propane, polyethyleneglycol dichrylate, tripropyleneglycol diacrylate, polypropyleneglycol diacrylate, 2,2-bis[4-(acryloxy diethoxy)phenyl]propane, 2,2-bis[4-(acryloxy polyethoxy)phenyl]propane, 2-hydroxy-1-acryloxy3-methachloxy propane, trimethylol propane trimethacrylate, tetramethylol methane triacrylate, tetramethyrol methane tetraacrylate, methoxy dipropyleneglycol methacrylate, methoxytriethyleneglycol acrylate, nonylphenoxypolyethyleneglycol acrylate, nonylphenoxypolypropyleneglycol acrylate, 1-acryloyloxypropyl-2-phthalate, isosteallyl acrylate, polyoxyethylenealkylether acrylate, nonylphenoxyethyleneglycol acrylate, polypropyleneglycol dimethacrylate, 1,4-butanediol dimethacrylate, 3-methyl-1,5-pentanediol dimethacrylate, 1,6-mexanediol dimethacrylate, 1,9-nonanediol methacrylate, 2,4-diethyl-1,5-pentanediol dimethacrylate, 1,4-cyclohexanedimethanol dimethacrylate, dipropyleneglycol diacrylate, tricyclodecanedimethanol diacrylate, 2,2-bis[4-(acryloxy polyethoxy)phenyl]propane, 2,2-bis[4-(acryloxy polypropoxy)phenyl]propane, 2,4-diethyl-1,5-pentanediol diacrylate, ethoxylated tothymethylolpropane triacrylate, propoxylated tothymethylolpropane triacrylate, isocyanuric acid tri(ethaneacrylate), pentathritol tetraacrylate, ethoxylated pentathritol tetraacrylate, propoxylated pentathritol tetraacrylate, ditrimethylolpropane tetraacrylate, dipentaerythritol polyacrylate, isocyanuric acid triallyl, glycidyl methacrylate, glycidyl allylether, 1,3,5-triacryloylhexahydro-s-triazine, triallyl1,3,5-benzenecarboxylate, triallyl amine, triallyl citrate, triallyl phosphate, allobarbital, diallyl amine, diallyl dimethyl silane, diallyl disulfide, diallyl ether, zallylcyallate, diallyl isophthalate, diallyl telephtalate, 1,3-diallyloxy-2-propanol, diallyl sulfide diallyl maleate, 4,4′-isopropyliden diphenol dimethacrylate, 4,4′-isopropyliden diphenol diacrylate, and the like. In order to improve the cross-linked density, it is particularly preferable to use a bifunctional or further multifunctional monomer.

As the (meth)acrylic compound, it is possible to use: vinyl compound such as styrene, divinyl benzene, vinyl-4-t-butylbenzoate, vinyl-n-butylether, vinyl isobutylether, vinyl-n-butylate, vinyl-n-caprolate, and vinyl-n-caprylate; and allyl compound such as isocyanuric acid triallyl and phthalic acid diallylether.

Note that, the (meth)acrylic compounds may be used solely or may be used in combination of plural kinds.

### (I-4) Photoreaction Initiator

In case where the photosensitive dry film resist obtained by adding the photoreaction initiator is exposed, it is possible to promote the cross-linking reaction or the polymerization reaction in an exposed area. On this account, it is possible to sufficiently differentiate the exposed area from an unexposed area in terms of the solubility of the photosensitive dry film resist with respect to the water system developer. As a result, it is possible to favorably develop a pattern on the photosensitive dry film resist.

Examples of the photoreaction initiator include a radical generation agent, a photocation generation agent, a photobase generation agent, a photoacid generation agent, and the like.

The radical generation agent is a generic term of compounds each of which generates radicals in response to light irradiation. The radical generation agent used in the present invention is not particularly limited as long as the compound generates radicals in response to light irradiation, but it is preferable to use a compound which generates radicals in response to irradiation of light whose wavelength is 250 to 450 nm.

Specific examples of the radical generation agent are an acylphosphine oxide compound represented by the following formula (8) and an acylphosphine oxide compound represented by the following formula (9).

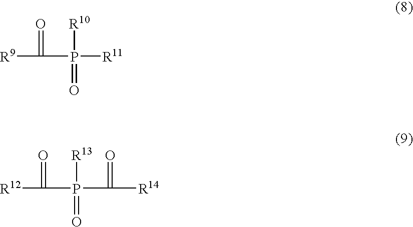

where each of R⁹, R₁₀, R₁₁, R₁₂, R¹³, and R¹⁴ of the formulas (8) and (9) represents C₆H₅—, C₆H₄(CH₃)—, C₆H₂(CH₃)₃—, (CH₃)₃C—, C₆H₃Cl₂—, a methoxy group, or an ethoxy group.

The radical generated from each of the compounds reacts with a reaction group (a vinyl group, an acryloyl group, a methacryloyl group, an acryl group, and the like) having two bonds, and promotes cross-linking.

The acylphosphine oxide compound represented by the foregoing formula (8) generates two radicals, and the acylphosphine oxide compound represented by the foregoing formula (9) generates four radicals through a cleavage. Thus, in the present invention, it is more preferable to use the acylphosphine oxide compound represented by the foregoing formula (9).

More specifically, it is preferable to use as the radical generation agent a compound which generates radicals by light whose wavelength is 250 to 450 nm, for example, by light whose wavelength is long as a g-line. Examples thereof include: ketone compounds such as 2,2-dimethoxy-1,2-diphenylethane-1-one and 2-hydroxy-2-methyl-1-phenyl-propane-1-one; phosphin oxide compounds such as bis(2,4,6-trimethyl benzoyl)-phenylphosphin oxide and bis(2,6-dimethoxy benzoyl)-2,4,4-trimethyl-penthylphosphin oxide; titanocen compounds such as bis(-2,4-cyclopentadien-1-yl)-bis(2,6-difluoro-3-(1H-pyrrole-1-yl)-phenyl)titanium; and the like. Above all, it is particularly preferable to use the phosphin oxide compound or the titanocen compound.

Further, examples of the photocation generation agent include diphenyl iodonium saline such as diphenyl iodonium salt of dimethoxy anthraquinone sulphonic acid; triphenyl sulphonium saline; pyrylinium saline; triphenyl onium saline; diazonium saline; and the like. Note that, it is preferable that not only the foregoing saline but also an alicyclic epoxy or vinyl ether compound having a high cation-curing property is mixed.

Further, examples of the photobase generation agent include: a benzylalcohol-urethane compound obtained by reacting nitro benzylalcohol or dinitro benzylalcohol with isocyanate; a phenylalcohol-urethane compound obtained by reacting nitro-1-phenylethylalcohol or dinitro-1-phenylethylalcohol with isocyanate; a propanol-urethane compound obtained by reacting dimethoxy-2-phenyl-2-propanol with isocyanate; and the like.

Further, examples of the photoacid generation agent include: a compound which allows generation of sulfonic acid such as iodonium salt, sulfonium salt, and onium salt; a compound which allows generation of carboxylic acid such as naphthoquinone diazide; and the like. Alternatively, it is preferable to use compounds such as diazonium salt and bis(trichloromethyl)triazine because each of these compounds allows generation of a sulfone group in response to irradiation of light.

Further, in the photosensitive dry film resist according to the present invention, a combination of peroxide and a sensitizer may be used as the photoreaction initiator. Such arrangement allows the photosensitive dry film resist to achieve the practical photosensitivity.

The peroxide is not particularly limited, and various kinds of peroxide can be used. Specific examples of the peroxide include ketone peroxides, peroxy ketals, hydroperoxides, dialkyl peroxides, diacyl peroxides, peroxy esters, peroxy dicarbonates, and the like. It is particularly preferable to use 3,3′,4,4′-tetra(t-butylperoxycarbonyl)benzophenone.

Further, the sensitizer is not particularly limited, but favorable examples thereof include Michler's ketone, bis-4,4′-diethylamino benzophenone, benzophenone, camphor quinone, benzyl, 4,4′-dimethylaminobenzyl, 3,5-bis(diethylamino benzylidene)-N-methyl-4-pipelidone, 3,5-bis(dimethylamino benzylidene)-N-methyl-4-pipelidone, 3,5-bis(diethylamino benzylidene)-N-ethyl-4-pipelidone, 3,3′-carbonylbis(7-diethylamino)coumarin, riboflavintetrabutylate, 2-methyl-1-[4-(methylthio)phenyl]-2-morpholinopropane-1-one, 2,4-dimethylthioxanthene, 2,4-diethylthioxanthene, 2,4-diisopropylthioxanthene, 3,5-dimethylthioxanthene, 3,5-diisopropylthioxanthene, 1-phenyl-2-(ethoxycarbonyl)oxyiminopropane-1-one, benzoin ether, benzoinisopropylether, benzanthrone, 5-nitroacenaphthene, 2-nitrofluorene, anthrone, 1,2-benzanthraquinone, 1-phenyl-5-mercapto-1H-tetrazole, thioxanthene-9-one, 10-thioxanthenone, 3-acetylindole, 2,6-di(p-dimethylaminobenzal)-4-carboxycyclohexanone, 2,6-di(p-dimethylaminobenzal)-4-hydroxycyclohexanone, 2,6-di(p-diethylaminobenzal)-4-carboxycyclohexanone, 2,6-di(p-diethylaminobenzal)-4-hydroxycyclohexanone, 4,6-dimethyl-7-ethylaminocoumarin, 7-diethylamino-4-methylcoumarin, 7-diethylamino-3-(1-methylbenzoimidazolyl)coumarin, 3-(2-benzoimidazolyl)-7-diethylaminocoumarin, 3-(2-benzothiazolyl)-7-diethylaminocoumarin, 2-(p-dimethylaminostyryl)benzoxazole, 2-(p-dimethylaminostilyl)quinoline, 4-(p-dimethylaminostilyl)quinoline, 2-(p-dimethylaminostilyl)zenzothiazole, 2-(p-dimethylaminostilyl)-3,3-dimethyl-3H-indole, and the like.

The sensitizer is blended to such extent that the sensitization effect can be obtained and the blend does not have an unfavorable influence on the developing property. Specifically, with respect to 100 parts by weight of each of the binder polymer (A1) and the binder polymer (A2), an amount of the sensitizer blended preferably ranges from 0.01 to 50 parts by weight, more preferably from 0.1 to 20 parts by weight. Note that, as the sensitizer, one kind of a compound may be used, or a mixture of two or more kinds may be used. Further, with respect to 100 parts by weight of the sensitizer, an amount of the peroxide blended preferably ranges from 1 to 200 parts by weight, more preferably from 1 to 150 parts by weight.

Further, as the combination of the photoreaction initiator and the sensitizer, it is particularly preferable to adopt a combination of (i) peroxide such as bis(2,4,6-trimethyl benzoyl)phenylphosphinoxide and (ii) 3,3′,4,4′-tetra(t-butylperoxycarbonyl)benzophenone.

The photoreaction initiators can be used solely or can be used in combination of two or more kinds.

It is preferable that the photosensitive dry film resist according to the present invention includes 0.01 to 50 parts by weight of the photoreaction initiator with respect to 100 parts by weight of each of the binder polymer (A1) and the binder polymer (A2).

Further, with respect to 100 parts by weight of a total of the binder polymer serving as the component (A) and the (meth)acrylic compound serving as the component (B), the amount of the photoreaction initiator preferably ranges from 0.001 to 10 parts by weight, more preferably from 0.01 to 10 parts by weight. If the amount of the photoreaction initiator and/or the sensitizer is less than 0.001 part by weight, it is impossible to obtain sufficient sensitivity. If the amount of the photoreaction initiator and/or the sensitizer exceeds 10 parts by weight, light is more likely to be absorbed by the surface of the photosensitive dry film resist, so that internal photo-curing may be insufficient.

Note that, it may be so arranged that the second photosensitive layer does substantially not include the photoreaction initiator (C2) as described above, and a ratio of the photoreaction initiator (C2) may be 0 to 0.01 part by weight with respect to 100 parts by weight of the binder polymer (A2). Further, with respect to 100 parts by weight of a total of the binder polymer serving as the component (A) and the (meth)acrylic compound serving as the component (B), the amount of the photoreaction initiator may be 0 to 0.001 parts by weight.

Further, the photoreaction initiator (C1) for the first photosensitive layer and the photoreaction initiator (C2) for the second photosensitive layer may be the same as each other or may be different from each other.

Further, in order to achieve practical photosensitivity, the photoreaction initiator may further include a photopolymerization assistant. The photopolymerization assistant is not particularly limited, but examples thereof include 4-diethylaminoethylbenzoate, 4-dimethylaminoethylbenzoate, 4-diethylaminopropylbenzoate, 4-dimethylaminopropylbenzoate, 4-dimethylaminoisoamylebenzoate, N-phenylglycine, N-methyl-N-phenylglycine, N-(4-cyanophenyl)glycine, 4-dimethylaminobenzonitrile, ethyleneglycoldithioglycolate, ethyleneglycol di(3-mercaptopropionate), trimethylolpropanethioglycolate, trimethylolpropane tri(3-mercaptopropionate), pentaerythritoltetrathioglycolate, pentaerythritol tetra(3-mercaptopropionate), trimethylolethanetrithioglycolate, trimethylolpropanetrithioglycolate, trimethylolethane tri(3-mercaptopropionate), dipentaerythritolhexa(3-mercaptopropionate), thioglycolic acid, α-mercapto propionic acid, t-butylperoxybenzoate, t-butylperoxymethoxybenzoate, t-butylperoxynitrobenzoate, t-butylperoxyethylbenzoate, phenylisopropylperoxybenzoate, di t-butyldiperoxyisophthalate, tri t-butyltriperoxytrimellitate, tri t-butyltriperoxytrimesitate, tetra t-butyltetraperoxypyromellitate, 2,5-dimethyl-2,5-di(benzoylperoxy)hexane, 3,3′,4,4′-tetra(t-butylperoxycarbonyl)benzophenone, 3,3′,4,4′-tetra(t-amylperoxycarbonyl)benzophenone, 3,3′,4,4′-tetra(t-hexylperoxycarbonyl)benzophenone, 2,6-di(p-azidobenzal)-4-hydroxycyclohexanone, 2,6-di(p-azidobenzal)-4-carboxycyclohexanone, 2,6-di(p-azidobenzal)-4-methoxycyclohexanone, 2,6-di(p-azidobenzal)-4-hydroxymethylcyclohexanone, 3,5-di(p-azidobenzal)-1-methyl-4-piperidone, 3,5-di(p-azidobenzal)-4-piperidone, 3,5-di(p-azibenzal)-N-acetyl-4-piperidone, 3,5-di(p-azidobenzal)-N-methoxycarbonyl-4-piperidone, 2,6-di(p-azidobenzal)-4-hydroxycyclohexanone, 2,6-di(m-azidobenzal)-4-carboxycyclohexanone, 2,6-di(m-azidobenzal)-4-methoxycyclohexanone, 2,6-di(m-azidobenzal)-4-hydroxymethylcyclohexanone, 3,5-di(m-azidobenzal)-N-methyl-4-piperidone, 3,5-di(m-azidobenzal)-4-piperidone, 3,5-di(m-azidobenzal)-N-acetyl-4-piperidone, 3,5-di(m-azidobenzal)-N-methoxycarbonyl-4-piperidone, 2,6-di(p-azidecinnamyliden)-4-hydroxycyclohexanone, 2,6-di(p-azidecinnamyliden)-4-carboxycyclohexanone, 2,6-di(p-azidecinnamyliden)-4-cyclohexanone, 3,5-di(p-azidecinnamyliden)-N-methyl-4-piperidone, 4,4′-diazidochalcone, 3,3′-diazidochalcone, 3,4′-diazidochalcone, 4,3′-diazidochalcone, 1,3-diphenyl-1,2,3-propanetrione-2-(o-acetyl)oxime, 1,3-diphenyl-1,2,3-propanetrione-2-(o-n-propylcarbonyl)oxime, 1,3-diphenyl-1,2,3-propanetrione-2-(o-methoxycarbonyl)oxime, 1,3-diphenyl-1,2,3-propanetrione-2-(o-ethoxycarbonyl)oxime, 1,3-diphenyl-1,2,3-propanetrione-2-(o-benzoyl)oxime, 1,3-diphenyl-1,2,3-propanetrione-2-(o-phenyloxycarbonyl)oxime, 1,3-bis(p-methylphenyl)-1,2,3-propanetrione-2-(o-benzoyl)oxime, 1,3-bis(p-methoxyphenyl)-1,2,3-propanetrione-2-(o-ethoxycarbonyl)oxime, 1-(p-methoxyphenyl)-3-(p-nitrophenyl)-1,2,3-propanetrione-2-(o-phenyloxycarbonyl)oxime, and the like. Further, as another assistant, it is possible to use trialkylamines such as triethylamine, tributylamine, triethernolamine, and the like.

Note that, as the photopolymerization assistant, one kind of a compound may be used, or a combination of two or more kinds may be used.

The photopolymerization assistant is blended to such extent that photosensitive effect can be obtained and the blend does not have an unfavorable influence on the developing property. Specifically, with respect to 100 parts by weight of each of the binder polymer (A1) and the binder polymer (A2), an amount of the photopolymerization assistant blended is preferably 0.01 to 50 parts by weight, more preferably 0.1 to 20 parts by weight.

### (I-5) Flame Retardant

In the present specification, the “flame retardant” is a substance which is added to or reacted with a burnable substance such as plastic, wood, or fiber so that the burnable substance hardly burns.

The flame retardancy is not particularly limited, but examples thereof include: phosphorous flame retardant such as (i) a phosphazene compound having a phosphorous-nitrogen double bond, (ii) phosphorus ester, (iii) condensed phosphorus ester, (iv) phosphine oxide, and (v) phosphine; a silicone compound in which a content of aromatic ring is high; and the like. Theses flame retardants may be solely or may be used in combination of two or more kinds. Note that, the phosphorus flame retardant in the present invention refers to a compound containing phosphorous, e.g., phosphorus ester, condensed phosphorus ester, phosphine oxide, phosphine, and phosphazene compound.

The flame retardant used in the present invention is not particularly limited. However, in view of the compatibility with the photosensitive resin composition and the flame retardancy, it is more preferable to use a flame retardant containing phosphorous (hereinafter, this flame retardant is referred to as “phosphorus flame retardant”), and it is preferable to use condensed phosphorus ester and phosphazene compound phosphorus flame retardant.

In case of using the phosphorus flame retardant as a flame retardant, an amount of phosphorous contained in the phosphorus flame retardant is preferably 5.0 wt % or more, more preferably 7.0 wt % or more, with respect to 100 wt % of the phosphorus flame retardant. By using the phosphorus flame retardant, it is possible to effectively give the flame retardancy.

Examples of the phosphorus flame retardant include phosphorus compound such as phosphazene, phosphine, phosphine oxide, phosphorus ester (including condensed phosphorus ester), and phosphite. Particularly, in view of the compatibility with the binder polymer, the (meth)acrylic compound, and the photoreaction initiator, it is possible to favorably use phosphazene, condensed phosphorus ester, and the like.

In view of such property that flame retardancy can be given and hydrolysis resistance can be realized, specific examples of the phosphorus flame retardant include phosphorus ester such as SPE-100 (Otsuka Chemicals Inc.), SPH-100 (Otsuka Chemicals Inc.), TPP (triphenyl phosphate) (DAIHACHI CHEMICAL INDUSTRY CO., LTD.), TCP (tricresyl phosphate) (DAIHACHI CHEMICAL INDUSTRY CO., LTD.), TXP (trixylenyl phosphate) (DAIHACHI CHEMICAL INDUSTRY CO., LTD.), CDP (cresyl diphenyl phosphate) (DAIHACHI CHEMICAL INDUSTRY CO., LTD.), and PX-110 (cresyl 2,6-xylenylphosphate) (DAIHACHI CHEMICAL INDUSTRY CO., LTD.); and non-halogen condensed phosphorus ester such as CR-733S (resocynol diphosphate) (DAIHACHI CHEMICAL INDUSTRY CO., LTD.), CR-741 (DAIHACHI CHEMICAL INDUSTRY CO., LTD.), CR-747 (DAIHACHI CHEMICAL INDUSTRY CO., LTD.), and PX-200 (DAIHACHI CHEMICAL INDUSTRY CO., LTD.).

However, if a large amount of the flame retardant is added, not only the electric reliability but also the alkaline solubility drops, so that a residue may be likely to occur. Note that, the residue is likely to occur on an interface with respect to a highly interactive base material.

In the multi-layer structure photosensitive dry film resist of the present invention, it is assumed that: when a second photosensitive layer flame retardant content is 0 wt % or more and 10 wt % or less and a first photosensitive layer flame retardant content is 100, the second photosensitive layer flame retardant content is 0 or more and 50 or less. The first photosensitive layer flame retardant content is increased so as to give the flame retardancy and the second photosensitive layer flame retardant content is decreased or no flame retardant is included in the second photosensitive layer, thereby further improving the moisture resistance and the electric reliability. Further, the second photosensitive layer which is in contact with the base material has excellent alkaline solubility, so that a residue is less likely to occur at the time of alkali development, thereby further improving the developing property and the resolution. Note that, if the second photosensitive layer which is in contact with the base material has the excellent alkaline solubility, a residue is less likely to occur even if the first photosensitive layer has low alkaline solubility.

The second photosensitive layer flame retardant content may be set to any value as long as the content is 0 wt % or more and 10 wt % or less. However, the less content is more preferable. The content is preferably 0 wt % or more and 5 wt % or less, more preferably 0 wt % or more and 1 wt % or less. If the second photosensitive layer flame retardant content exceeds 10 wt %, the electric reliability and the alkali developing property may deteriorate.

Further, in the multi-layer structure photosensitive dry film resist according to the present invention, when the first photosensitive layer flame retardant content is defined as 100, the second photosensitive layer flame retardant content is preferably 0 or more and 50 or less, more preferably 0 or more and 20 or less, still more preferably 0 or more and 10 or less. If the second photosensitive layer flame retardant content exceeds 50 with respect to 100, i.e., the first photosensitive layer flame retardant content, an amount of flame retardant included in the entire photosensitive dry film resist is small when the second photosensitive layer flame retardant content is within the foregoing range, so that it may be impossible to give sufficient flame retardancy. Such condition is not preferable.

Further, the first photosensitive layer flame retardant content is preferably 1 wt % or more and 50 wt % or less, more preferably 5 wt % or more and 40 wt % or less, still more preferably 10 wt % or more and 40 wt % or less, most preferably 10 wt % or more and 30 wt % or less. If the first photosensitive layer flame retardant content is less than 1 wt %, it may be impossible to obtain sufficient flame retardant effect. If the first photosensitive layer flame retardant content exceeds 50 wt %, this may have an unfavorable influence on properties of the cured product. Such condition is not preferable.

Further, in the present invention, in case where the flame retardant (D2) is included in the second photosensitive layer, the flame retardant (D1) of the first photosensitive layer and the flame retardant of the second photosensitive layer (D2) may be the same with or may be different from each other.

### (I-6) Other Component

The photosensitive resin composition of the present invention may include not only the binder polymer (A), the (meth)acrylic compound (B), the photoreaction initiator (C), and the flame retardant (D), but also other component (E) as required. Examples of other component include an epoxy resin, a curing accelerator and/or curing agent, polymerization inhibitor, an adhesive improver, a bulking agent, a preservation/stabilization agent, an ion scavenger, and the like.

That is, the first photosensitive layer of the photosensitive dry film resist according to the present invention essentially includes the binder polymer (A1), the (meth)acrylic compound (B1), the photoreaction initiator (C1), and the flame retardant (D1), but may further include other component.

Further, the second photosensitive layer of the photosensitive dry film resist according to the present invention essentially includes the binder polymer (A2), the (meth)acrylic compound (B2), and preferably the photoreaction initiator (C2), but may further include other component.

### <Epoxy Resin>

By using an epoxy resin, it is possible to improve the bonding property of the resultant photosensitive dry film resist with respect to copper foil, polyimide film, and the like.

The epoxy resin is not particularly limited, but examples thereof include: bisphenol A type epoxy resins such as Epikote 828, 834, 1001, 1002, 1003, 1004, 1005, 1007, 1010, and 1100L (products of Japan Epoxy Resins Co., Ltd.); o-cresolnovolak type epoxy resins such as ESCN-220L, 220F, 220H, 220HH, and 180H65 (commercial names: product of Japan Epoxy Resins Co., Ltd.); trishydroxyphenylmethane type epoxy resins such as EPPN-502H (product of Nippon Kayaku Co., Ltd.); naphthalenearalkylnovolak type epoxy resins such as ESN-375; novolak type epoxy resins such as ESN-185 (product of Nippon Steel Chemical Group); biphenol type epoxy resins such as YX4000H (commercial name) and the like.

In addition, it is possible to use bisphenol A glycidyl ether type epoxy resin, bisphenol F glycidyl ether type epoxy resin, novolak glycidyl ether type epoxy resin, glycidyl ester type epoxy resin, glycidyl amine type epoxy resin, cyclic aliphatic epoxy resin, aromatic epoxy resin, halogenated epoxy resin, and the like.

The epoxy resins may be used solely or may be used in combination of two or more kinds. Note that, with respect to 100 parts by weight of the binder polymer serving as the component (A), an amount of the epoxy resin is preferably 1 to 100 parts by weight, more preferably 0 to 50 parts by weight, particularly preferably 1 to 30 parts by weight. If the amount of the epoxy resin exceeds 30 parts by weight with respect to 100 parts by weight of the binder polymer (A), this may lower the bendability.

<Curing Accelerator and/or Curing Agent>

In case of using the epoxy resin as a material for the photosensitive resin composition, a curing accelerator and/or curing agent may be added to the photosensitive resin composition in order to effectively cure the resultant photosensitive dry film resin. The curing accelerator and/or curing agent are not particularly limited. However, it is possible to use imidazole compounds, acid anhydrides, tertiary amines, hydrazines, aromatic amines, phenols, triphenylphosphines, organic peroxides, and the like. One kind of these curing accelerators and/or curing agents may be used, or these curing accelerators and/or curing agents may be used in combination of two or more kinds.

With respect to 100 parts by weight of the binder polymer serving as the component (A), an amount of the curing accelerator and/or curing agent is preferably 0.1 to 20 parts by weight, more preferably 0.5 to 20 parts by weight, particularly preferably 0.5 to 15 parts by weight. If the amount of the curing accelerator and/or curing agent is less than 0.1 part by weight with respect to 100 parts by weight of the binder polymer (A), the epoxy resin is not sufficiently cured. If the amount of the curing accelerator and/or curing agent exceeds 20 parts by weight, this may lower the heat resistance.

### <Polymerization Inhibitor, Stabilizer, Antioxidant>

It is preferable to add, to the photosensitive resin composition of the present invention, at least one kind of polymer additive, selected from a group made up of a polymerization inhibitor, a stabilizer, and an antioxidant, in order to prevent a photopolymerizable/thermopolymerizable functional group such as vinyl group, an acryl group, a methacryl group, and the like included in the binder polymer (A) and/or the (meth)acrylic compound (B) from cross-linking during storage of the photosensitive resin composition and the photosensitive dry film resist.

The polymerization inhibitor is not particularly limited as long as general polymerization inhibitor or general polymerization suppressant is used. The stabilizer is not particularly limited as long as a generally known thermal stabilizer or a generally known photo stabilizer is used. The antioxidant is not particularly limited as long as a general antioxidant or a general radical scavenger is used.

Each of the polymerization inhibitor, the stabilizer, and the antioxidant is not necessarily used as an individual compound, but a single compound may be used as both the polymerization inhibitor and the antioxidant.

The polymer additive selected from the group made up of the polymerization inhibitor, the stabilizer, and the antioxidant of the present invention is not particularly limited as long as a general polymerization inhibitor, a general polymerization suppressant, a general thermal stabilizer, a general photo stabilizer, a general antioxidant, or a general radical scavenger is used. However, examples thereof include: hydroquinone compounds such as hydroquinone, methylhydroquinone, 2,5-di-t-butylhydroquinone, t-butylhydroquinone, 2,5-bis(1,1,3,3-tetramethylbutyl)hydroquinone (product of Wako Pure Chemical Industries, Ltd.: commercial name is DOHQ), and 2,5-bis(1,1-dimethylbutyl)hydroquinone (product of Wako Pure Chemical Industries, Ltd.: commercial name is DHHQ); benzoquinone compounds such as p-benzoquinone, methyl-p-benzoquinone, t-butylbenzoquinone, and 2,5-diphenyl-p-benzoquinone; hindered phenol compounds such as pentaerythritoltetrakis [3-(3,5-di-t-butyl-4-hydroxyphenyl)propionate] (product of Ciba Specialty Chemicals: commercial name is IRGANOX 1010), N,N′-hexane-1,6-diylbis[3-(3,5-di-t-butyl-4-hydroxyphenyl)propione amide] (product of Ciba Specialty Chemicals: commercial name is IRGANOX 1098), 1,3,5-tris(3,5-di-t-butyl-4-hydroxybenzyl)-1,3,5-triazine-2,4,6(1H, 3H, 5H)-trione (product of Ciba Specialty Chemicals: commercial name is IRGANOX 3114), and hydroxyphenolbenzotriazole (product of Asahi Denka Kogyo K.K.: commercial name is ADEKA AO-20); benzotriazole compound such as 2-(2 H-benzotriazole-2-yl)-p-; cresol (product of Ciba Specialty Chemicals: commercial name is TINUVIN P); nitrosamine compounds such as N-nitrosophenylhydroxylamine (product of Wako Pure Chemical Industries, Ltd.: commercial name is Q-1300) and N-nitrosophenylhydroxylamine aluminum salt (product of Wako Pure Chemical Industries, Ltd.: commercial name is Q-1301); organic sulfur compounds such as phenothiazine, dithiobenzoylsulfide, and dibenzyltetrasulfide; hindered amine compounds such as bis(1,2,2,6,6-pentamethyl-4-piperidyl)[{3,5-bis(1,1-dimethylethyl)-4-hydroxyphenyl}]methyl]butyl malonate (product of Ciba Specialty Chemicals: commercial name is IRGANOX 144); aromatic amines such as p-phenylenediamine (popular name is paramine) and N,N-diphenyl-p-phenylenediamine; phosphorus compounds such as tris(2,4-di-t-butylphenyl)phosphite (product of Ciba Specialty Chemicals: commercial name is IRGANOX 168) and tetrakis(2,4-di-t-butylphenyl)[1,1-biphenyl]-4,4′-diylbisphotphonate (product of Ciba Specialty Chemicals: commercial name is IRGANOX P-EPQ); and the like.

Particularly, it is preferable to use the hydroquinone compound, the hindered phenol compound, the nitrosoamine compound, and the aromatic amine. By using these compounds, it is possible to prevent the photopolymerizable/thermopolymerizable functional group from cross-linking. Thus, it is possible to prevent the viscosity of the organic solvent solution of the photosensitive resin composition from rising during storage of the photosensitive resin composition, so that it is possible not only to more stably reserve the photosensitive dry film resist but also to prevent deterioration of resin due to its oxidization prevention effect. As a result, it is possible to improve long-term heat resistance and hydrolysis resistance of the cured photosensitive dry film resist made of the photosensitive resin composition.

With respect to 100 parts by weight of a total of the binder polymer serving as the component (A) and the (meth)acrylic compound serving as the component (B), an amount of the polymerization inhibitor used therein is preferably 0.00001 to 5 parts by weight, more preferably 0.0001 to 1 part by weight. If the amount of the photoreaction initiator and/or sensitizer is less than 0.00001 part by weight, the stability at the time of reservation may deteriorate. In the amount of the photoreaction initiator and/or sensitizer exceeds 5 parts by weight, sensitivity with respect to an activated energy line is likely to drop.

### <Adhesive Improver>

In order to improve the adhesiveness with respect to the base material such as polyimide film, metal, and the like, a known so-called adhesive improver may be added. In the present invention, it is preferable to add the adhesive improver to the second photosensitive layer serving as a surface to which the base material is bonded.

The adhesive improver is not particularly limited, but examples thereof include benzimidazole, benzoxazole, benzthiazole, triazole, silane coupling agent, and the like.

### (II) Production Method of Photosensitive Dry Film Resist

Subsequently, the following describes a production method of a photosensitive dry film resist taking a two-layer photosensitive dry film resist as an example. However, it is needless to say that the multi-layer photosensitive dry film resist of the present invention is not limited to the photosensitive dry film resist obtained by the following production method.

The two-layer photosensitive dry film resist of the present invention is obtained by forming the first photosensitive layer on the support film and then forming the second photosensitive layer on the first photosensitive layer. Note that, in case of producing a photosensitive dry film resist having two or more layers, for example, the first photosensitive layer is formed on the support film, and then one or more layers are formed on and above the first photosensitive layer, and the second photosensitive layer is formed on an uppermost layer.

The following describes (II-1) Preparation of photosensitive resin composition and (II-2) Production of photosensitive dry film resist, in this order.

### (II-1) Preparation of Photosensitive Resin Composition

First, a first photosensitive layer resin composition constituting the first photosensitive layer and a second photosensitive layer resin composition constituting the second photosensitive layer are prepared.

The first photosensitive layer resin composition is obtained by mixing the binder polymer (A1), the (meth)acrylic compound (B1), the photoreaction initiator (C1), the flame retardant (D1), and as necessary, other component (E1) at a certain ratio, and a solution obtained by evenly dissolving the first photosensitive layer resin composition in an organic solvent is referred to as an organic solvent solution (hereinafter, this solution is referred to also as “first photosensitive layer organic solvent solution” in the present specification).

The second photosensitive layer resin composition is obtained by mixing the binder polymer (A2), the (meth)acrylic compound (B2), preferably the photoreaction initiator (C2), and other component (E2) at a certain ratio, and a solution obtained by evenly dissolving the second photosensitive layer resin composition in an organic solvent is referred to as an organic solvent solution (hereinafter, this solution is referred to also as “second photosensitive layer organic solvent solution” in the present specification).

The organic solvent is not particularly limited as long as the organic solvent can dissolve components included in the first photosensitive layer resin composition and the second photosensitive layer resin composition. Examples of the organic solvent include: ether solvent such as dioxolane, dioxane, and tetrahydrofuran; ketone solvent such as acetone and methylethylketone; alcohol solvent such as methyl alcohol and ethyl alcohol; and the like. These organic solvents may be used solely or may be used in combination of two or more kinds. Note that, in the subsequent steps, the organic solvent is removed, so that it is advantageous in view of production steps to select an organic solvent which dissolves components included in the first photosensitive layer resin composition and the second photosensitive layer resin composition and whose boiling point is as low as possible.

### (II-2) Production of Photosensitive Dry Film Resist

Subsequently, the organic solvent solution constituting the first photosensitive layer resin composition is evenly applied to the support film, and then the resultant film is heated and/or hot air is blown to the resultant film. This allows the organic solvent to be removed, thereby obtaining a film-shaped first photosensitive layer resin composition, i.e., the first photosensitive layer. The first photosensitive layer formed is in a half-cured state (B stage) of the photosensitive resin composition. Therefore, the first photosensitive layer has suitable flowability in carrying out a heat-press treatment such as heat lamination, so that a pattern circuit of a printed wiring board can be favorably embedded therein. Further, an exposure treatment, a heat-press treatment, and a heat-cure treatment are carried out after embedding the pattern circuit, thereby entirely curing the first photosensitive layer.

A temperature at which the first photosensitive layer resin composition is heated and/or hot air is blown to the first photosensitive layer resin composition so as to dry the organic solvent solution constituting the first photosensitive layer resin composition may be set to be any value as long as the temperature does not cause a curing group, such as a (meth)acryl group and an epoxy group, included in the first photosensitive layer resin composition to react. Specifically, the temperature is preferably 150° C. or lower, particularly preferably 120° C. or lower. Further, it is more preferable to set a drying duration to be shorter as long as the organic solvent can be removed.

A material for the support film is not particularly limited, but it is possible to use various kinds of commercial films such as a polyethyleneterephthalate (PET) film, a polyphenylenesulfide film, and a polyimide film, and the like. Out of the support films, the PET film is favorably used since the PET film has certain heat resistance and can be obtained at relatively low price. Note that, the support film has a surface which is in contact with the photosensitive dry film resist, and the surface may be treated so as to improve the adhesiveness and the peeling property.

The multi-layer photosensitive dry film resist of the present invention can be obtained by forming the second photosensitive layer on a surface of the first photosensitive layer in case where the multi-layer structure is a two-layer structure for example. At this time, when the thickness of the first photosensitive layer is defined as 100, the thickness of the second photosensitive layer is preferably 10 to 500, more preferably 20 to 400, still more preferably 50 to 300. When the thickness of the first photosensitive layer is defined as 100, it is not preferable that the thickness of the second photosensitive layer is more than 500 since such thickness drops the flame retardancy of the photosensitive dry film resist. Further, when the thickness of the first photosensitive layer is defined as 100, it is not preferable that the thickness of the second photosensitive layer is smaller than 10 since such thickness is likely to drop the electric reliability.

In forming the second photosensitive layer on a surface of the first photosensitive layer, it is possible to adopt the following two processes, i.e., (1) a direct application process and (2) a transcription process. In (1) the direct application process, the organic solvent solution constituting the second photosensitive layer resin composition is applied to the surface of the first photosensitive layer and the thus applied organic solvent solution is dried so as to form the second photosensitive layer. In (2) the transcription process, a protection film is obtained by applying the organic solvent solution constituting the second photosensitive layer resin composition and drying the thus applied organic solvent solution, and a solution application surface of the protection film is bonded to the first photosensitive layer, and then the protection film is peeled so as to transcribe the second photosensitive layer onto the surface of the first photosensitive layer.

In case of the process (1), the first photosensitive layer is formed on the support film, and then the organic solvent solution constituting the second photosensitive layer resin composition is evenly applied to the surface of the first photosensitive layer with an application tool such as a gravure mesh, and then the organic solvent solution is heated and/or hot air is blown to the organic solvent solution so as to remove the solvent and dry the resultant. This makes it possible to obtain a dry film resist having a “support film/first photosensitive layer/second photosensitive layer” structure in which the second photosensitive layer is formed on the first photosensitive layer. Thereafter, a protection film may be additionally laminated on the second photosensitive layer. The protection film will be described later.

Next, in case of the process (2), the organic solvent solution of the second photosensitive layer resin composition is evenly applied to a protection film such as a PE film with an application tool such as a gravure mesh, and then the organic solvent solution is heated and/or hot air is blown to the organic solvent solution so as to remove the solvent and dry the resultant. The thus obtained protection film having the second photosensitive layer (“protection film/second photosensitive layer”) is bonded to the first photosensitive layer having the support film (“first photosensitive layer/support film”) so that the second photosensitive layer serves as a contact surface with respect to the first photosensitive layer. Note that, this bond can be carried out by roll lamination at 20° C. to 70° C. Thereafter, the protection film is peeled, thereby using the resultant as a photosensitive dry film resist having a “support film/first photosensitive layer/second photosensitive layer” structure.

It is preferable to additionally laminate the protection film on the resultant photosensitive dry film resist. This makes it possible to prevent dirt and dust in air from adhering to the photosensitive dry film resist and to prevent the quality of photosensitive dry film resist from deteriorating under a dried condition.

It is preferable to laminate the protection film on the surface of the second photosensitive layer of the photosensitive dry film resist at 10° C. to 50° C. Note that, if the temperature at the time of lamination is higher than 50° C., this results in thermal expansion of the protection film, so that the protection film after the lamination may have a wrinkle or may be curled. Note that, the protection film is peeled at the time of practical use, it is preferable that the contact surface between the protection film and the photosensitive dry film resist has suitable adhesiveness at the time of preservation and is excellent in the peeling property.

A material for the protection film is not particularly limited, but examples thereof include a polyethylene film (PE film), a polyethylene vinyl alcohol film (EVA film), a “copolymer film of polyethylene and ethylene vinyl alcohol” (hereinafter, referred to as “(PE+EVA) copolymer film”), a “combination of PE film and (PE+EVA) copolymer film”, or a “film obtained by simultaneously extruding (PE+EVA) copolymer and polyethylene” (a film whose one surface is a PE film and other surface is a (PE+EVA) copolymer film).

The PE film has such advantage that its price is low and its surface has an excellent sliding property. Further, the (PE+EVA) copolymer film has suitable adhesiveness and peeling property with respect to the photosensitive dry film resist. By using the protection film, it is possible to improve its surface sliding property in case where a sheet having three layers, i.e., the protection film, the photosensitive dry film resist, and the support film, is wound in a roll manner.

### (III) Printed Wiring Board

The multi-layer photosensitive dry film resist according to the present invention can be formed as an insulating protection layer on a printed wiring board. Thus, the scope of the present invention includes a printed wiring board obtained by forming the photosensitive dry film resist according to the present invention as an insulating protection layer.

In such a printed wiring board, the photosensitive dry film resist is laminated so that the second photosensitive layer is in contact with a copper-clad laminate having a circuit thereon. Thus, in case where the photosensitive dry film resist has a two-layer structure including the first photosensitive layer and the second photosensitive layer, the printed wiring board is such that the second photosensitive layer is in contact with the copper-clad laminate having a circuit thereon and the first photosensitive layer is positioned outside.

According to the arrangement, it is possible to provide a printed wiring board which is excellent in flame retardancy, moisture resistance, and electric reliability.

The following describes a technique for producing a printed wiring board, in which the multi-layer photosensitive dry film resist according to the present invention is formed as an insulating protection layer, taking as an example a case of producing a printed wiring board in which a two-layer photosensitive dry film resist is formed as an insulating protection layer. The following describes an example where a CCL having a circuit pattern thereon (hereinafter, referred to also as “CCL with circuit”) is used as the printed wiring board, but the same technique is applicable also to formation of an interlayer insulation layer in case of forming a multi-layer printed wiring board.

First, the protection film is peeled from a sheet including the protection film, the photosensitive dry film resist, and the support film. Hereinafter, a product obtained by peeling the protection film from the sheet is referred to as “photosensitive dry film resist with support film”. Further, the photosensitive dry film resist with support film covers the CCL with circuit so that the second photosensitive layer side of the photosensitive dry film resist and the circuit portion of the CCL are opposite to each other, and the CCL is bonded to the photosensitive dry film resist by heat press. The bonding based on the heat press is not particularly limited as long as a heat press treatment, a lamination treatment (heat lamination treatment), a heat roll lamination treatment, or the like is carried out as the foregoing heat press.

In case of carrying out the heat lamination treatment or the heat roll lamination treatment (hereinafter, referred to as “lamination treatment”) so as to bond the CCL to the photosensitive dry film resist, a treatment temperature is not lower than a lower limit temperature which allows the lamination treatment (hereinafter, this temperature is referred to as “press-bondable temperature”). Specifically, the press-bondable temperature is preferably 50 to 150° C., more preferably 60 to 120° C., particularly preferably 80 to 120° C.

If the treatment temperature exceeds 150° C., a cross-linking reaction of a photosensitive reaction group included in the photosensitive dry film resist occurs at the time of the lamination treatment, so that curing of the photosensitive dry film resist may proceed. While, if the treatment temperature is lower than 50° C., the flowability of the photosensitive dry film resist is low, so that it is difficult to embed the pattern circuit. Further, the CCL with copper circuit and the base film of the CCL with copper circuit may be less sufficiently bonded to each other.

The heat press allows the photosensitive dry film resist to be laminated on the CCL with circuit and further allows the support film to be laminated, thereby obtaining a sample including these members in this manner. Subsequently, pattern exposure and development are carried out with respect to the thus obtained sample. In carrying out the pattern exposure and the development, a photo mask pattern is placed on the support film of the sample so as to carry out exposure via the photo mask. Thereafter, the support film is peeled and development is carried out, thereby forming a hole (via hole) corresponding to the photo mask pattern.

Note that, the support film is peeled after the exposure, but it may be so arranged that the support film is peeled after bonding the photosensitive dry film resist with support film onto the CCL with circuit, that is, before carrying out the exposure. In view of protection of the photosensitive dry film resist, it is preferable to peel the support film after completion of the exposure.

As a light source used in the exposure, it is preferable to use a light source which effectively irradiates light whose wavelength is 250 to 450 nm. This is because the photoreaction initiator included in the photosensitive dry film resist generally functions in response to light whose wavelength is 450 nm or less.

Further, as a developer used in the development, it is possible to use a basic solution in which a basic compound is dissolved. A solvent in which the basic compound is dissblved is not particularly limited as long as the solvent can dissolve the basic compound. However, in view of environmental problem, it is particularly preferable to use water.

Examples of the basic compound include: hydroxide or carbonate of alkali metal or alkali earth metal such as sodium hydroxide, potassium hydroxide, sodium carbonate, and sodium hydrogen carbonate; organic amine compound such as tetramethyl ammonium hydroxide; and the like. The basic compounds may be used solely or may be used in combination of two or more kinds.

A concentration of the basic compound included in the basic solution is preferably 0.1 wt % to 10 wt %. However, in view of alkali-proof property of the photosensitive dry film resist, the concentration is more preferably 0.1 wt % to 5 wt %.

Note that, the development process is not particularly limited, but examples thereof include: a method in which a development sample is placed in a basic solution and then the mixture is stirred; a method in which a developer is sprayed onto a development sample; and a similar method.

In the present invention, it is possible to particularly adopt a development process in which a sodium carbonate aqueous solution whose temperature had been adjusted to 40° C. and whose concentration is 1 wt % or a sodium hydrate aqueous solution whose concentration is 1 wt % is used as the developer and a spray developing device is used to carry out the development. Herein, the spray developing device is not particularly limited as long as the spray developing device sprays the developer.

Here, a developing duration taken to complete patterning of the photosensitive dry film resist may be arbitrarily set as long as the patterning can be completed within the developing duration, but the developing duration is preferably 180 seconds or shorter, more preferably 90 seconds or shorter, most preferably 60 seconds or shorter. If the developing duration exceeds 180 seconds, the productivity is likely to drop.

Here, as a criterion for setting the developing duration, it is possible to adopt measurement of a duration taken to complete dissolution of the photosensitive dry film resist in a B stage (half-cured state). Specifically, a sample obtained by bonding the photosensitive dry film resist onto a glossy surface of the copper foil is subjected to a spray-development process under such condition that the sample is unexposed and a sodium carbonate aqueous solution whose concentration is 1 wt % (liquid temperature is 40° C.) or a sodium hydrate aqueous solution whose concentration is 1 wt % (liquid temperature is 40° C.) is used as the developer with a spray pressure of 0.85 MPa. It is preferable that the spray-development process allows the photosensitive dry film resist to be dissolved and removed in 180 seconds or shorter duration. If it takes over 180 seconds to dissolve and remove the photosensitive dry film resist, the workability is likely to drop.

After carrying out the exposure and development processes as described above, heat cure is carried out with respect to the photosensitive dry film resist, thereby completely curing the photosensitive dry film resist. As a result, the cured photosensitive dry film resist becomes an insulating protection film of the printed wiring board.

Further, in case of forming a multi-layer printed wiring board, the protection layer of the printed wiring board is used as an interlayer insulation layer, and the interlayer insulation layer is subjected to sputtering or dipping or is bonded to a copper foil, and then a pattern circuit is formed thereon, and the photosensitive dry film resist is laminated thereon. This makes it possible to produce a multi-layer printed wiring board.

Note that, the present embodiment described the case where the photosensitive dry film resist is used as the insulating protection layer or the interlayer insulation layer of the printed wiring board, but the photosensitive dry film resist can be used as a purpose of use other than the foregoing purpose of use.

Note that, it is needless to say that the scope of the present invention includes the following invention.

The included invention is a two-layer photosensitive dry film resist in which a first photosensitive layer includes a binder polymer (A), a (meth)acrylic compound (B), a photoreaction initiator (C), and a flame retardant (D), and a second photosensitive layer includes a binder polymer (A), a (meth)acrylic compound (B), and preferably a photoreaction initiator (C), and does not include a flame retardant (D).

In the two-layer photosensitive dry film resist, it is preferable that the flame retardant included in the first photosensitive layer is a phosphorus compound. Further, it is preferable that the binder polymer serving as the component (A) is a vinyl polymer containing carboxyl group. Further, it is preferable that the binder polymer serving as the component (A) is polyamide acid, and it is more preferable that the binder polymer is polyamide acid partially made of polysiloxane diamine represented by the following formula (1),

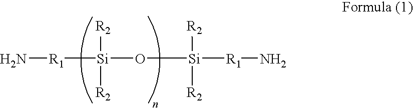

where each R₁ independently represents a hydrocarbon whose carbon number is 1 to 5, and each R₂ independently represents an organic group selected from an alkyl group whose carbon number is 1 to 5 and a phenyl group, and n represents an integer from 1 to 20.

Further, it is preferable that the binder polymer serving as the component (A) is soluble polyimide including carboxyl group and/or hydroxyl group partially made of polysiloxane diamine represented by the following formula (1).

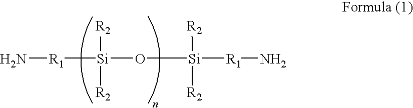

where each R₁ independently represents a hydrocarbon whose carbon number is 1 to 5, and each R₂ independently represents an organic group selected from an alkyl group whose carbon number is 1 to 5 and a phenyl group, and n represents an integer from 1 to 20.

In case where the thickness of the first photosensitive layer is defined as 100, it is preferable that the thickness of the second photosensitive layer is 500 or less. Further, it is preferable to apply an organic solvent solution constituting the second photosensitive layer onto the first photosensitive layer and dry the organic solvent solution so as to form the second photosensitive layer. Further, it is preferable that the organic solvent solution constituting the second photosensitive layer is applied onto a surface of the protection film and the organic solvent solution is dried and the solution-applied surface of the resultant protection film is bonded to the first photosensitive layer and then the protection film is peeled so as to transcribe the second photosensitive layer onto the first photosensitive layer.

Another invention of the present invention is a printed wiring board in which the two-layer photosensitive dry film resist is used as an insulating protection film.

Further another invention of the present invention is a method for producing a two-layer photosensitive dry film resist which method includes the steps of: applying an organic solvent solution constituting a second photosensitive layer onto a surface of a first photosensitive layer: and drying the organic solvent solution, so as to form the second photosensitive layer, the first photosensitive layer including a binder polymer (A), a (meth)acrylic compound (B), a photoreaction initiator (C), and a flame retardant (D), and the second photosensitive layer including a binder polymer (A), a (meth)acrylic compound (B), and preferably a photoreaction initiator (C), not including a flame retardant (D).

A still further another invention of the present invention is a method for producing a two-layer photosensitive dry film resist which method includes the steps of: applying an organic solvent solution constituting a second photosensitive layer onto a surface of a protection film and drying the organic solvent solution; bonding a solution-applied surface of the protection film to a first photosensitive layer; and peeling the protection film so as to transcribe the second photosensitive layer onto the first photosensitive layer, the first photosensitive layer including a binder polymer (A), a (meth)acrylic compound (B), a photoreaction initiator (C), and a flame retardant (D), and the second photosensitive layer including a binder polymer (A), a (meth)acrylic compound (B), and preferably a photoreaction initiator (C), not including a flame retardant (D).

### Examples

The following description will further detail the present invention in accordance with Examples and Comparative Examples, but the present invention is not limited to them. Preparation of photosensitive resin compositions, specific production of photosensitive dry film resists, and evaluation of properties thereof were carried out as follows. Further, binder polymers used in the following Examples and Comparative Examples were produced in accordance with methods of Synthesis Examples 1 to 10.

### <Preparation of Photosensitive Resin Composition>

As to a first photosensitive layer resin composition, an organic solvent solution constituting the first photosensitive layer resin composition was produced as follows: a binder polymer (A1), a (meth)acrylic compound (B1), a photoreaction initiator (C1), and a flame retardant (D1), and as necessary, other component (E1), were mixed with a predetermined ratio thereof, and dioxolane was added thereto so that its solid content weight % (Sc) was 40%, and dioxolane was evenly dissolved, so as to obtain the solution. Likewise, as to a second photosensitive layer resin composition, an organic solvent solution constituting the second photosensitive layer resin composition was produced as follows: a binder polymer (A2), a (meth)acrylic compound (B2), preferably a photoreaction initiator (C2), and as necessary, other component (E2), were mixed with a predetermined ratio thereof, and dioxolane was added thereto so that its solid content weight % (Sc) was 30%, and dioxolane was evenly dissolved, so as to obtain the solution. Here, the solid content weight is a total weight of the components (A), (B), (C), (D), and (E), which are materials other than the organic solvent. In case of the first photosensitive layer resin composition for example, the solid content weight is a total weight of the components (A 1), (B1), (C1), (D1), and (E1), and also a weight of liquid material other than the organic solvent is included as a weight of a solid content.

### <Production of Photosensitive Dry Film>

The organic solvent solution constituting the first photosensitive layer resin composition was applied to the support film so that the thickness of the dried resultant (the thickness of the photosensitive dry film resist) was 20 μm. As the support film, a PET film (Lumirror produced by TORAY Co., Ltd: its thickness was 25 μm) was used. Thereafter, the applied layer on the support film was dried at 100° C. for ten minutes, thereby removing the organic solvent. In this manner, a sheet constituted of the first photosensitive layer/PET film was obtained. Note that, the first photosensitive layer was in the B stage state.

Next, a second photosensitive layer was formed on a surface of the first photosensitive layer. The second photosensitive layer was formed in accordance with the following two processes, i.e., a direct application process and a transcription process.

### 1) Direct Application Process

In case of the direct application process, an organic solvent solution constituting the second photosensitive layer resin composition was applied to the surface of the first photosensitive layer produced in the foregoing manner so that the thickness of the dried resultant was 5 μm, and the organic solvent was dried at 100° C. for 5 minutes, thereby removing the organic solvent.

A “film produced by a method in which (EVA+PE) copolymer and polyethylene are simultaneously extruded” (protect (#6221F) film produced by Sekisui Chemical Co., Ltd. (thickness was 50 μm)) was laminated, as a protection film, on the support film/photosensitive dry film resist produced in the foregoing manner, at a roll temperature of 40° C. and a nip pressure of 50000 Pa·m so that its (EVA+PE) copolymer film surface was in contact with the photosensitive dry film surface.

### 2) Transcription Process

The organic solvent solution constituting the second photosensitive layer resin composition was applied onto a PPS film (Torerina #3000 produced by TORAY Co., Ltd: its thickness was 25 μm) so that the thickness of the dried resultant was 5 μm, and the organic solvent was dried at 100° C. for 5 minutes, thereby removing the organic solvent.

The protection film having the second photosensitive layer which had been produced in this manner was laminated at a roll temperature of 45° C. and a nip pressure of 50000 Pa·m so that its second photosensitive layer side was in contact with the first photosensitive dry film surface. The PPS film was first peeled in using the photosensitive dry film resist.

Note that, the photosensitive dry film resist produced by the direct application process or the transcription process was in the B stage state.

### <Evaluation of Properties of Photosensitive Dry Film Resist>

The following properties of the photosensitive dry film resist produced in the foregoing manner were evaluated. Specifically, (i) alkaline solubility, (ii) developing property, (iii) resolution, (iv) adhesiveness, (v) flame retardancy, (vi) electric reliability, (vii) solder heat resistance, (viii) tucking property in the B stage state, and (iv) warpage, were evaluated.

### (i) Alkaline Solubility

First, an electrolysis copper foil (produced by MITSUI MINING & SMELTING Co., LTD.: thickness was 38 μm) was subjected to soft etching with 10 wt % sulfate aqueous solution for one minute (the soft etching was a step of removing an antirust from the surface of the copper foil), and the resultant was rinsed with water, and the surface was rinsed with ethanol and acetone, and then was dried. After peeling the protection film of the photosensitive dry film resist, the photosensitive dry film resist was laminated onto a glossy surface of the electrolysis copper foil (having been subjected to the soft etching) at 100° C. and 75000 Pa·m. Subsequently, after the PET film was peeled, a spray developing device (ES-655D, an etching machine produced by Sunhayato Corporation) was used to develop the sample in 1 wt % of sodium carbonate aqueous solution (liquid temperature was 40° C.) with its developing duration of 30 to 180 seconds. After being developed, the developed sample was rinsed with distilled water so as to remove the developer, and was dried. A shortest developing duration required in completely removing the photosensitive dry film resist from the glossy surface of the copper foil to which the photosensitive dry film resist had been bonded was defined as an alkali dissolution duration in the B stage state. When the alkali dissolution duration in 1 wt % of sodium carbonate aqueous solution (liquid temperature was 40° C.) exceeded 180 seconds, the same operation was carried out except that the developer was changed to 1 wt % of sodium hydrate aqueous solution (liquid temperature was 40° C.), thereby measuring an alkali dissolution duration.

When the alkali dissolution duration of the photosensitive dry film resist in the B stage state was 60 seconds or shorter in either 1 wt % of sodium carbonate aqueous solution (liquid temperature was 40° C.) or 1 wt % of sodium carbonate aqueous solution (liquid temperature was 40° C.), such photosensitive dry film resist was regarded as “proper”, and when the alkali dissolution duration exceeded 180 seconds, such photosensitive dry film resist was regarded as “improper”.

### (ii) Developing Property

First, an electrolysis copper foil (produced by MITSUI MINING & SMELTING Co., LTD.: thickness was 38 μm) was subjected to soft etching (step of removing an antirust from a surface of the copper foil) with 10 wt % of sulfate aqueous solution, and the resultant was rinsed with water, and then its surface was rinsed with ethanol and acetone, and was dried. After peeling a protection film of the photosensitive dry film resist, the photosensitive dry film resist was laminated on a glossy surface of the electrolysis copper foil (having been subjected to the soft etching) at 100° C. and 75000 Pa·m. A mask pattern having a fine square of 100×100 μm and a fine square of 200×200 μm was placed on a PET film of the laminate, and the photosensitive dry film resist was exposed to light of wavelength 405 nm with a dose of only 300 mJ/cm². After the sample PET film was peeled, a spray developing device (ES-655D produced by Sunhayato Corporation) was used to develop the laminate in 1 wt % of sodium hydrate aqueous solution (liquid temperature was 40° C.) or 1 wt % of sodium carbonate aqueous solution (liquid temperature was 40° C.). Note that, in the alkaline solubility test, a sodium carbonate aqueous solution was used as the developer under such condition that the photosensitive dry film resist was dissolved in the sodium carbonate aqueous solution, and a sodium hydrate aqueous solution was used as the developer under such condition that the photosensitive dry film resist was dissolved in the sodium hydrate aqueous solution. A pattern formed by the development was subsequently rinsed with distilled water so as to remove the developer, and then the resultant was dried. When the resultant was observed through an optical microscope and it was found that at least a square of 200×200 μm was developed without any residue, such photosensitive dry film resist was regarded as “proper”.

(iii) Resolution

Under the same condition as in the foregoing development, the photosensitive dry film resist was laminated on the glossy surface of the electrolysis copper foil. Each of mask patterns, whose lines/spaces were 40/40 μm to 200/200 μm with each increment being 10 μm, was placed on a PET film of the laminate, and the photosensitive dry film resist was exposed to light of wavelength 405 nm with a dose of only 300 mJ/cm². After the sample PET film was peeled, a spray developing device (ES-655D produced by Sunhayato Corporation) was used to carry out spray development in 1 wt % of sodium hydrate aqueous solution (liquid temperature was 40° C.) or 1 wt % of sodium carbonate aqueous solution (liquid temperature was 40° C.), and a minimum line width which allowed an unexposed portion to be removed was measured, and the measured width was regarded as “resolution”. As the resolution has a smaller value, this is more preferable. Note that, in the alkaline solubility test, a sodium carbonate aqueous solution was used as the developer under such condition that the photosensitive dry film resist was dissolved in the sodium carbonate aqueous solution, and a sodium hydrate aqueous solution was used as the developer under such condition that the photosensitive dry film resist was dissolved in the sodium hydrate aqueous solution.

### (iv) Adhesiveness

After the protection film of the photosensitive dry film resist was peeled, the photosensitive dry film resist was laminated onto a polyimide film whose thickness was 25 μm (NPI produced by Kaneka Corp.) at 100° C. and 75000 Pa·m. Next, the photosensitive dry film resist was exposed to light of wavelength 405 nm with a dose of only 600 mJ/cm², and the support film was peeled, and the resultant was heat-cured by an oven of 180° C. for two hours.

The thus produced “polyimide film/photosensitive dry film resist” laminate sample was subjected to a cross-cut peel test in accordance with IPC TM650 2.4.28.1. When the laminate sample was free from any exfoliation, this sample was regarded as “proper”.

### (v) Flame Retardancy

After the protection film of the photosensitive dry film resist was peeled, the photosensitive dry film resist was laminated onto each side of a polyimide film whose thickness was 50 μm (NPI produced by Kaneka Corp.) at 100° C. and 75000 Pa·m. Next, each side was exposed to light of wavelength 405 nm with a dose of only 600 mJ/cm², and the support film (PET) was peeled from each side, and the resultant was heat-cured by an oven of 180° C. for two hours.

The thus produced “photosensitive dry film resist/polyimide film/photosensitive dry film resist” laminate sample was subjected to a test in accordance with UL94 thin material vertical firing test (VTM-0).

### (vi) Electric Reliability

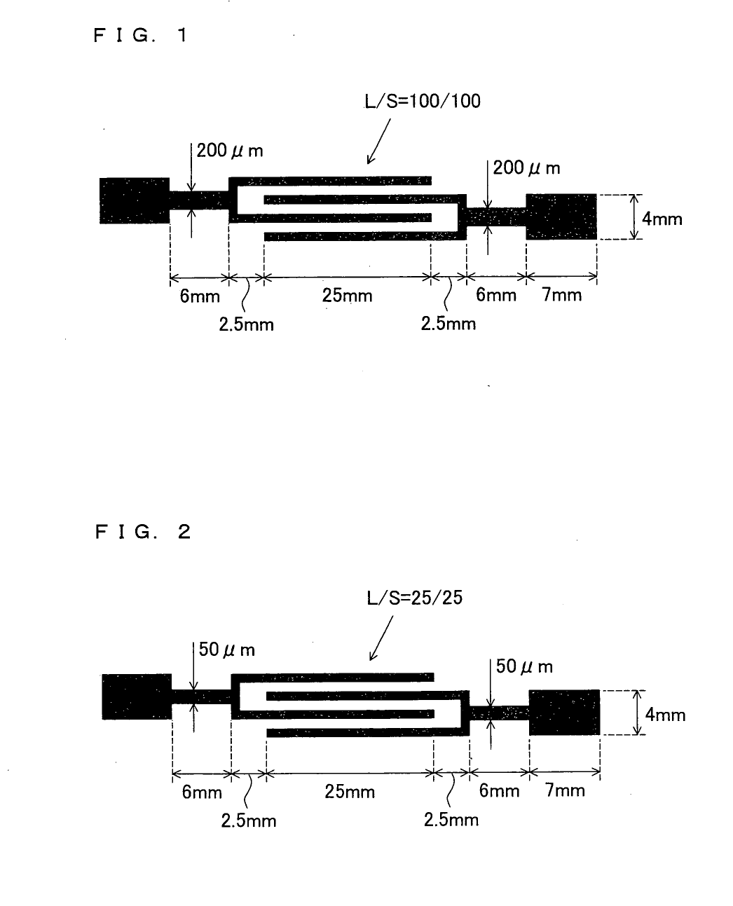

A copper foil surface of a polyimide film having a copper foil (Espanex (commercial name) produced by Nippon Steel Chemical Co., Ltd.: the thickness of the polyimide film was 25 μm and the thickness of the copper foil was 18 μm) and a resist film (SUNFORT produced by Asahi KASEI Corporation) were used to form comb-shaped patterns which are respectively shown in FIG. 1 and FIG. 2 and respectively having line/space=100/100 μm and line/space=25/25 μm. In this manner, each CCL having circuit was obtained. The photosensitive dry film resist from which the protection film had been peeled was placed so as to coat each comb-shaped pattern of the CCL having circuit, and the photosensitive dry film resist was laminated at 100° C. and 75000 Pa·m. The photosensitive dry film resist surface of the resultant sample was exposed to light of wavelength 405 nm with a dose of only 300 mJ/cm², and then the PTE film was peeled, and the resultant was cured at 180° C. for two hours.

The sample was placed in a thermo-hygrostat (PLATINOUS PR-2K (commercial name) produced by ESPEC CORP.) whose temperature was 85° C. and whose relative humidity was 85%, and a voltage of 60V was kept applied across terminals of the comb-shaped pattern, and a line insulation resistance was measured in every 30 minute.

As to the insulation resistance, it was regarded as being proper if the insulation resistance was at least 1.0×10⁸Ω or more under such condition that the comb-shaped pattern was such that line/space=100/100 μm and an application duration was 500 hours. It was regarded as being improper if short circuit occurred within 500 hours. If an insulation resistance of 1.0×10⁸Ω or more was kept when the comb-shaped pattern was such that line/space=25/25 μm, its electric reliability was regarded as being more preferable.

(vii) Solder Heat Resistance

A copper foil (electrolysis copper foil produced by MITSUI MINING 86 SMELTING Co., LTD.: thickness was 38 μm) was cut into a square of 5×5 cm, and the cut copper foil was subjected to soft etching with 10 wt % of sulfate aqueous solution for one minute and was rinsed with water, and the resultant was rinsed with ethanol and acetone and was dried. Next, a protection film of a photosensitive dry film resist having been cut into a square of 4×4 cm was peeled, and the cut photosensitive dry film resist was placed on a glossy surface of the electrolysis copper foil (having been subjected to the soft etching) so as to be laminated at 100° C. and 75000 Pa·m. A photosensitive dry film resist surface of the resultant sample was exposed to light of wavelength 405 nm with a dose of only 300 mJ/cm², and then the resultant was cured at 180° C. for two hours. After the sample was adjusted into <1> a normal state (temperature of 20° C./relative humidity of 40% for 24 hours) and <2> a moisture absorption state (temperature of 40° C./relative humidity of 85% for 48 hours), the sample was placed in a melted solder whose temperature was 260° C. or higher for 30 seconds, and there was measured a maximum temperature which did not allow any swollenness and exfoliation of an interface between the copper foil and the photosensitive dry film resist. The solder heat resistance of at least 260° C. or higher was regarded as being proper.

(viii) Tucking Property of B Stage State

After the protection film of the photosensitive dry film resist was peeled, whether or not there was any tuck was checked by touching the photosensitive dry film resist. When the photosensitive dry film resist was free from any tuck or was slightly tucked, this was regarded as being proper. When the photosensitive dry film resist was greatly tucked, this was regarded as being improper.

### (iv) Warpage

A photosensitive dry film resist having been produced as in the measurement of the adhesiveness was placed on a polyimide film, APICAL 25NPI (produced by Kaneka Corp.), so as to be laminated at 110° C. and 20000 Pa·m. Subsequently, the resultant was exposed to light of wavelength 400 nm with a dose of only 300 mJ/cm², and then the PET film was peeled, and the resultant was cured at 180° C. for two hours, thereby obtaining a laminate. The laminate was cut into a square of 5×5 cm as a test sample. The test sample was left at a temperature of 23° C. and a relative humidity of 65% for 24 hours. Thereafter, the test sample was placed on a flat table with its photosensitive dry film resist surface facing upward, and a warping portion's maximum height from the table was measured by a ruler as warpage (mm). When the warpage is 5 mm or less, this was regarded as being proper.

### <Synthesis of Binder Polymer>

Raw materials of the binder polymer are as follows. 3,3′,4,4′-benzophenontetracarboxylic acid dianhydride (hereinafter, referred to also as “BTDA”), 3,3′,4,4′-biphenylethertetracarboxylic acid dianhydride (hereinafter, referred to also as “ODPA”), pyromellitic acid dianhydride, 3,3,3′,4′-biphenyltetracarboxylic acid dianhydride (hereinafter, referred to also as “s-BPDA”), 3,3′,4,4′-biphenylsulphonetetracarboxylic acid dianhydride, and 3,3′,4,4′-biphenylethertetracarboxylic acid dianhydride were used as acid dianhydride, and 1,3-bis(3-aminophenoxy)benzene, 2,2-bis(3-aminophenyl)propane, 3,3′-diaminodiphenylether, and 2,2-bis[4-(4-aminophenoxy)phenyl]propane were used as aromatic diamine. As solvent, N-methyl pyrrolidone (hereinafter, referred to also as “NMP”), N,N′-dimethyl formamide (hereinafter, referred to also as “DMF”), and dioxolane were used.

A weight average molecular weight of the resultant binder polymer was calculated with a size exclusion chromatography in accordance with conversion based on polyethyleneoxide by using HLC8220GPC produced by TOSOH CORPORATION.

### Synthesis Example 1

### Polyamide Acid

Into a 2000 ml separable flask provided with a stirring device, 29.23 g (100 mmol) of 1,3-bis(3-aminophenoxy) benzene was placed and was added to 58.46 g of dimethyl formamide in a dissolved manner, and the mixture was stirred for one hour at room temperature. Subsequently, 31.02 g (100 mmol) of 3,3′,4,4′-biphenylethertetracarboxylic acid dianhydride was added, and the mixture was stirred for three hours, thereby obtaining polyamide acid. A weight average molecular weight of polyamide acid was 100000.

### Synthesis Example 2

### Polyamide Acid

Into a 2000 ml separable flask provided with a stirring device, 31.02 g (100 mmol) of 3,3′,4,4′-biphenylethertetracarboxylic acid dianhydride and 102.7 g of dimethyl formamide were placed, and 59.68 g (40 mmol: molecular weight was 1492) of polysiloxane diamine X-22-9409S (product of Shin-Etsu Chemical Industry Co. Ltd.) was added to 59.68 g of dimethyl formamide in a dissolved manner, and the mixture was stirred at a room temperature for one hour. Subsequently, 17.54 g (60 mmol) of 1,3-bis(3-aminophenoxy)benzene was added, and the mixture was stirred for three hours, thereby obtaining polyamide acid. A weight average molecular weight of polyamide acid was 80000.

### Synthesis Example 3

### Polyamide Acid

Into a 3 L separable flask provided with a stirring device, a reflex condenser, a dropping funnel, and a tube for introducing nitrogen gas, 87.3 g (400 mmol) of pyromellitic acid dianhydride and 496 g of N-methyl pyrrolidone were placed in a nitrogen atmosphere, and an internal temperature thereof was raised to 50° C. while stirring the mixture. At this temperature, 92.6 g (100 mmol: molecular weight was 926) of polysiloxane diamine BY16-853U (product of Dow Corning Toray Silicone Co., Ltd: represented by the formula (5) where R²=propylene group, and m is about 10, a content of phenyl group was 0%) was gradually dropped from the dropping funnel for two hours. After completion of the dropping, the mixture was kept stirred for one hour at this temperature. Thereafter, a reaction temperature was lowered to 30° C. or lower, and 87.7 g (300 mmol) of 1,3-bis(3-aminophenoxy)benzene was added, and then the mixture was kept stirred for 20 hours in an nitrogen atmosphere, thereby obtaining polyamide acid. A weight average molecular weight of polyamide acid was 120000.

### Synthesis Example 4

### Soluble Polyimide Having Carboxyl Group and/or Hydroxyl Group

Into a 500 ml separable flask provided with a stirring device, 17.3 g (30 mmol) of (2,2-bis(hydroxyphenyl)propanedibenzoate)-3,3′,4,4′-tetracarboxylic acid dianhydride and 30 g of dimethyl formamide were placed and was stirred by the stirring device so as to be dissolved. Next, 5.15 g (18 mmol) of [bis(4-amino-3-carboxy)phenyl]methane was dissolved in 9 g of dimethyl formamide, and the mixture was added to the solution of (2,2-bis(hydroxyphenyl)propanedibenzoate)-3,3′,4,4′-tetracarboxylic acid dianhydride, and the resultant mixture was roughly stirred. After the solution became even, 7.47 g (9 mmol) of polysiloxane diamine KF-8010 (product of Shin-Etsu Chemical Industry Co. Ltd.) was added, and the resultant mixture was roughly stirred. After the solution became even, lastly, 1.29 g (3 mmol) of bis[4-(3-aminophenoxy)phenyl]sulfone was added and the resultant mixture was roughly stirred for one hour. The polyamide acid solution obtained in this manner was poured into a tray coated with fluororesin and was dried under a reduced pressure for two hours in a vacuum oven at 200° C. and 660 Pa, thereby obtaining 26.40 g of polyimide having carboxyl group. A weight average molecular weight of polyamide acid was 37000.

### Synthesis Example 5

### Polyamide Acid

Into a 2000 ml separable flask provided with a stirring device, 31.02 g (100 mmol) of ODPA and 102.7 g of dioxolane were placed, and 59.68 g (40 mmol: represented by formula (5) where R²=propylene group, and m is about 12, and a content of phenyl group was 25%, and a molecular weight was 1492) of polysiloxane diamine X-22-9409S (product of Shin-Etsu Chemical Industry Co. Ltd.) was added to 59.68 g of dioxolane in a dissolved manner, and the mixture was stirred at a room temperature for one hour. Subsequently, 17.54 g (60 mmol) of 1,3-bis(3-aminophenoxy)benzene was added, and the mixture was stirred for three hours, thereby obtaining polyamide acid.

A molecular weight of the resultant polyamide acid was measured. As a result, a weight average molecular weight thereof was 80000, and a number average molecular weight thereof was 32000, and a weight average molecular weight/number average molecular weight was 2.5. Tg of the resultant obtained by polyimidizing the polyamide acid was 90° C.

### Synthesis Example 6

### Polyamide Acid

Into a 2000 ml separable flask provided with a stirring device, 32.22 g (100 mmol) of BTDA and 112.5 g of DMF were placed, and 80.88 g (30 mmol: represented by the formula (5) where R²=propylene group, and m is about 20, and a content of phenyl group was 40%, and a molecular weight was 2696) of polysiloxane diamine was added to 80.88 g of DMF in a dissolved manner, and the mixture was stirred at a room temperature for two hours. Subsequently, 15.83 g (70 mmol) of 2,2-bis(3-aminophenyl)propane was added, and the mixture was stirred for three hours, thereby obtaining polyamide acid.

A molecular weight of the resultant polyamide acid was measured. As a result, a weight average molecular weight thereof was 60000, and a number average molecular weight thereof was 25000, and a weight average molecular weight/number average molecular weight was 2.4. Tg of the resultant obtained by polyimidizing the polyamide acid was 100° C.

### Synthesis Example 7

### Polyamide Acid

Into a 500 ml separable flask provided with a stirring device, 35.82 g (100 mmol) of 3,3′,4,4′-biphenylsulfonetetracarboxylic acid dianhydride and 83.0 g of DMF were placed, and 5.93 g (40 mmol) of 1,2-bis(2-aminoethoxy)ethane was added to 5.93 g of DMF in a dissolved manner, and the mixture was stirred at a room temperature for two hours. Subsequently, 17.54 g (60 mmol) of 1,3-bis(3-aminophenoxy)benzene was added, and the mixture was stirred for three hours, thereby obtaining polyamide acid.

A molecular weight of the resultant polyamide acid was measured. As a result, a weight average molecular weight thereof was 85000, and a number average molecular weight thereof was 30000, and a weight average molecular weight/number average molecular weight was 2.8. Tg of the resultant obtained by polyimidizing the polyamide acid was 130° C.

### Synthesis Example 8

### Polyamide Acid

Into a 500 ml separable flask provided with a stirring device, 29.42 g (100 mmol) of s-BPDA and 73.2 g of DMF were placed, and 28.15 g (50 mmol: represented by the formula (5) where R²=propylene group, and m is about 4, and a content of phenyl group was 15%, and a molecular weight was 563) of polysiloxane diamine was added to 28.15 g of DMF in a dissolved manner, and the mixture was stirred at a room temperature for two hours. Subsequently, 10.01 g (50 mmol) of 3,3′-diaminodiphenyl ether was added, and the mixture was stirred for three hours, thereby obtaining polyamide acid.

A molecular weight of the resultant polyamide acid was measured. As a result, a weight average molecular weight thereof was 85000, and a number average molecular weight thereof was 30000, and a weight average molecular weight/number average molecular weight was 2.8. Tg of the resultant obtained by polyimidizing the polyamide acid was 85° C.

### Synthesis Example 9

### Polyamide Acid

Into a 2000 ml separable flask provided with a stirring device, 31.02 g (100 mmol) of ODPA and 94.3 g of dioxolane were placed, and 42.92 g (40 mmol: represented by the formula (5) where R²=propylene group, and m is about 20, and a content of phenyl group was 15%, and a molecular weight was 1073) of polysiloxane diamine was added to 42.92 g of dioxolane in a dissolved manner, and the mixture was stirred at a room temperature for one hour. Subsequently, 17.54 g (60 mmol) of 1,3-bis(3-aminophenoxy)benzene was added, and the mixture was stirred for three hours, thereby obtaining polyamide acid.

A molecular weight of the resultant polyamide acid was measured. As a result, a weight average molecular weight thereof was 85000, and a number average molecular weight thereof was 30000, and a weight average molecular weight/number average molecular weight was 2.8. Tg of the resultant obtained by polyimidizing the polyamide acid was 80° C.

### Synthesis Example 10

### Polyamide Acid

Into a 2000 ml separable flask provided with a stirring device, 31.02 g (100 mmol) of ODPA and 106.2 g of dioxolane were placed, and 59.68 g (40 mmol: represented by the formula (5) where R²=propylene group, and m is about 12, and a content of phenyl group was 25%, and a molecular weight was 1492) of polysiloxane diamine X-22-9409S (product of Shin-Etsu Chemical Industry Co. Ltd.) was added to 59.68 g of dioxolane in a dissolved manner, and the mixture was stirred at a room temperature for one hour. Subsequently, 11.69 g (40 mmol) of 1,3-bis(3-aminophenoxy)benzene was added, and the mixture was stirred for one hour. Then, 8.21 g (20 mmol) of 2,2-bis[4-(4-aminophenoxy)phenyl]propane was added, and the mixture was stirred for three hours, thereby obtaining polyamide acid.

A molecular weight of the resultant polyamide acid was measured. As a result, a weight average molecular weight thereof was 90000, and a number average molecular weight thereof was 33000, and a weight average molecular weight/number average molecular weight was 2.7. Tg of the resultant obtained by polyimidizing the polyamide acid was 120° C.

### Example 1

### <Production of Photosensitive Dry Film Resist>

The following components were mixed, and dioxolane was added and evenly dissolved so that its solid content wt % (Sc)=40%, thereby producing an organic solvent solution constituting the first photosensitive layer and an organic solvent solution constituting the second photosensitive ,layer.

### <Organic Solvent Solution Constituting First Photosensitive Layer>

### Binder Polymer (A1)

Vinyl polymer containing carboxyl group (ACA320 (commercial name) produced by Daiseru-Cytec Company Ltd.: weight average molecular weight was 25000) . . . 100 parts by weight

### (Meth)acrylic Compound (B1)

Bisphenol A EO denaturalized di(meth)acrylate (EB150 (commercial name) produced by Daiseru-Cytec Company Ltd.) . . . 20 parts by weight

Bisphenol A EO denaturalized di(meth)acrylate (FA321M (commercial name) produced by Hitachi Chemical Co., Ltd.) . . . 20 parts by weight

### Photoreaction Initiator (C1)

Bis (2,4,6-trimethylbenzoyl)phenylphosphineoxide (IRGACURE 819 produced by Ciba Specialty Chemicals) . . . 1 part by weight

### Flame Fetardant (D1)

Resorcinol bis(di 2,6-xylenyl)phosphate (PX-200 (commercial name) produced by DAIHACHI CHEMICAL INDUSTRY CO., LTD) . . . 30 parts by weight

### <Organic Solvent Solution Constituting Second Photosensitive Layer>

### Binder Polymer (A2)

Vinyl polymer containing carboxyl group (ACA320 (commercial name) produced by Daiseru-Cytec Company Ltd.: weight average molecular weight was 25000) . . . 100 parts by weight

### (Meth)acrylic Compound (B2)

Pentaerythtolacrylate (M305 (commercial name) produced by TOAGOSEI CO., LTD.) . . . 40 parts by weight

### Photoreaction Initiator (C2)

Bis(2,4,6-trimethylbenzoyl)phenylphosphineoxide (IRGACURE 819 produced by Ciba Specialty Chemicals) . . . 1 part by weight

The organic solvent solution constituting the photosensitive resin composition arranged in the foregoing manner was prepared, and the transcription process was carried out so as to produce a photosensitive dry film resist which is in the B stage state and whose first photosensitive layer had the thickness of 20μ and second photosensitive layer had the thickness of 5μ.

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 70 μm
Adhesiveness: proper
Flame retardant: Proper
Electric reliability: Proper (line/space=100/100 μm: 1.7×10⁸Ω, line/space=25/25 μm: 4.5×10⁶Ω)
Solder heat resistance: 260° C. This is regarded as being proper.
Tucking property in the B stage state: Free from any tuck.
This is regarded as being proper.
Warpage: 4 mm. This is regarded as being proper.

### Example 2

### <Production of Photosensitive Dry Film Resist>

The following components were mixed, and dioxolane was added and evenly dissolved so that its solid content wt % (Sc)=40%, thereby producing an organic solvent solution constituting the first photosensitive layer and an organic solvent solution constituting the second photosensitive layer.

### <Organic Solvent Solution Constituting First Photosensitive Layer>

### Binder Polymer (A1)

Polyamide acid synthesized in Synthesis Example 1 (in a solid phase) . . . 100 parts by weight

### (Meth)acrylic Compound (B1)

Bisphenol A EO denaturalized di(meth)acrylate (EB150 (commercial name) produced by Daiseru-Cytec Company Ltd.) . . . 10 parts by weight

Bisphenol A EO denaturalized di(meth)acrylate (FA321M (commercial name) produced by Hitachi Chemical Co., Ltd.) . . . 40 parts by weight

### Photoreaction Initiator (C1)

Bis(2,4,6-trimethylbenzoyl)phenylphosphineoxide (IRGACURE 819 produced by Ciba Specialty Chemicals) . . . 2 parts by weight

### Flame Retardant (D1)

Bisphenol A bis (diphenyl) phosphate (CR-741 (commercial name) produced by DAIHACHI CHEMICAL INDUSTRY CO., LTD) . . . 15 parts by weight

### <Organic Solvent Solution Constituting Second Photosensitive Layer>

### Binder Polymer (A2)

Polyamide acid synthesized in Synthesis Example 1 (in a solid phase) . . . 100 parts by weight

### (Meth)acrylic Compound (B2)

Bisphenol A EO denaturalized di(meth)acrylate (FA321M (commercial name) produced by Hitachi Chemical Co., Ltd.) . . . 40 parts by weight

### Photoreaction Initiator (C2)

Bis(2,4,6-trimethylbenzoyl)phenylphosphineoxide (IRGACURE 819 produced by Ciba Specialty Chemicals) . . . 1 part by weight

The organic solvent solution constituting the photosensitive resin composition arranged in the foregoing manner was prepared, and the direct application process was carried out so as to produce a photosensitive dry film resist which is in the B stage state and whose first photosensitive layer had the thickness of 20μ and second photosensitive layer had the thickness of 5μ.

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 70 μm
Adhesiveness: Proper
Flame retardant: Proper
Electric reliability: Proper (line/space=100/100 μm: 5.4×10¹¹Ω, line/space=25/25 μm: 3.7×10⁸Ω)
Solder heat resistance: 290° C. This is regarded as being proper.
Tucking property in the B stage state: Free from any tuck.
This is regarded as being proper.
Warpage: In a cylindrical manner. This is regarded as being improper.

### Example 3

### <Production of Photosensitive Dry Film Resist>

The following components were mixed, and dioxolane was added and evenly dissolved so that its solid content wt % (Sc)=40%, thereby producing an organic solvent solution constituting the first photosensitive layer and an organic solvent solution constituting the second photosensitive layer.

### <Organic Solvent Solution Constituting First Photosensitive Layer>

### Binder Polymer (A1)

Polyamide acid synthesized in Synthesis Example 2 (in a solid phase) . . . 100 parts by weight

### (Meth)acrylic Compound (B1)

Bisphenol A EO denaturalized di(meth)acrylate (EB150 (commercial name) produced by Daiseru-Cytec Company Ltd.) . . . 20 parts by weight

Bisphenol A EO denaturalized di(meth)acrylate (FA321M (commercial name) produced by Hitachi Chemical Co., Ltd.) . . . 30 parts by weight

### Photoreaction Initiator (C1)

Bis(2,4,6-trimethylbenzoyl)phenylphosphineoxide (IRGACURE 819 produced by Ciba Specialty Chemicals) . . . 2 parts by weight

### Flame Retardant (D1)

Phosphazene compound (SPH-100 (commercial name) produced by Otsuka Chemicals Inc.) . . . 20 parts by weight

### <Organic Solvent Solution Constituting Second Photosensitive Layer>

### Binder Polymer (A2)

Polyamide acid synthesized in Synthesis Example 2 (in a solid phase) . . . 100 parts by weight

### (Meth)acrylic Compound (B2)

Bisphenol A EO denaturalized di(meth)acrylate (EB150 (commercial name) produced by Daiseru-Cytec Company Ltd.) . . . 10 parts by weight

Bisphenol A EO denaturalized di(meth)acrylate (FA321M (commercial name) produced by Hitachi Chemical Co., Ltd.) . . . 20 parts by weight

### Photoreaction Initiator (C2)

Bis(2,4,6-trimethylbenzoyl)phenylphosphineoxide (IRGACURE 819 produced by Ciba Specialty Chemicals) . . . 1 part by weight

The organic solvent solution constituting the photosensitive resin composition arranged in the foregoing manner was prepared, and the direct application process was carried out so as to produce a photosensitive dry film resist which is in the B stage state and whose first photosensitive layer had the thickness of 20μ and second photosensitive layer had the thickness of 5μ.

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 50 μm
Adhesiveness: Proper
Flame retardant: Proper
Electric reliability: Proper (line/space=100/100 μm: 5.6×10¹¹Ω, line/space=25/25 μm: 5.4×10⁸Ω)
Solder heat resistance: 290° C. This is regarded as being proper.
Tucking property in the B stage state: Free from any tuck.
This is regarded as being proper.
Warpage: 1 mm or less. This is regarded as being proper.

### Example 4

### <Production of Photosensitive Dry Film Resist>

The following components were mixed, and dioxolane was added and evenly dissolved so that its solid content wt % (Sc)=40%, thereby producing an organic solvent solution constituting the first photosensitive layer and an organic solvent solution constituting the second photosensitive layer.

### <Organic Solvent Solution Constituting First Photosensitive Layer>

### Binder Polymer (A1)

Soluble polyimide having carboxyl group which soluble polyimide had been synthesized in Synthesis Example 4 . . . 100 parts by weight

### (Meth)acrylic Compound (B1)

Denaturalized bisphenol A type epoxyacrylate (Ebercryl 3708 (commercial name) produced by Daiseru-Cytec Company Ltd.) . . . 50 parts by weight

### Photoreaction Initiator (C1)

Bis(2,4,6-trimethylbenzoyl)phenylphosphineoxide (IRGACURE 819 produced by Ciba Specialty Chemicals) . . . 2 parts by weight

### Flame Retardant (D1)

Phosphazene compound (SPE-100 (commercial name) produced by Otsuka Chemicals Inc.) . . . 15 parts by weight

### <Organic Solvent Solution Constituting Second Photosensitive Layer>

### Binder Polymer (A2)

Soluble polyimide having carboxyl group which soluble polyimide had been synthesized in Synthesis Example 4 . . . 100 parts by weight

### (Meth)acrylic Compound (B2)

Denaturalized bisphenol A type epoxyacrylate (Ebercryl 3708 (commercial name) produced by Daiseru-Cytec Company Ltd.) . . . 50 parts by weight

### Photoreaction Initiator (C2)

Bis(2,4,6-trimethylbenzoyl)phenylphosphineoxide (IRGACURE 819 produced by Ciba Specialty Chemicals) . . . 2 parts by weight

### Other Component (E2)

Epoxy Resin

Bisphenol A type epoxy resin (Epikote 828 (commercial name) produced by Japan Epoxy Resins Co., Ltd.) . . . 10 parts by weight

Curing Agent

4,4′-diaminodiphenylmethane (DDM): 1 part by weight

The organic solvent solution constituting the photosensitive resin composition arranged in the foregoing manner was prepared, and the direct application process was carried out so as to produce a photosensitive dry film resist which is in the B stage state and whose first photosensitive layer had the thickness of 20μ and second photosensitive layer had the thickness of 5μ.

### <Results of Property Evaluation>

The results of property evaluation carried out with respect to the resultant photosensitive dry film resist are as follows.
Alkaline solubility: The photosensitive dry film resist was not dissolved in 1 wt % of sodium carbonate aqueous solution even in 180 seconds. The photosensitive dry film resist was dissolved in sodium hydrate aqueous solution in 30 seconds.
Developing property: A square hole of 100 μm×100 μm and a square hole of 200 μm×200 μm were developed without any residue. This is regarded as being proper.
Resolution: 90 μm
Adhesiveness: Proper
Flame retardant: Proper
Electric reliability: Proper (line/space=100/100 μm: 5.7×10⁸Ω, line/space=25/25 μm: 3.4×10⁶Ω)
Solder heat resistance: 300° C. This is regarded as being proper.
Tucking property in the B stage state: Free from any tuck.
This is regarded as being proper.
Warpage: 3 mm. This is regarded as being proper.

### Example 5

The following components were mixed, and dioxolane was added and evenly dissolved so that its solid content wt % (Sc)=40%, thereby producing an organic solvent solution constituting the first photosensitive layer and an organic solvent solution constituting the second photosensitive layer. The direct application process was carried out so as to produce a photosensitive dry film resist which is in the B stage state and whose first photosensitive layer had the thickness of 20 μm and second photosensitive layer had the thickness of 5 μm.

### <Organic Solvent Solution Constituting First Photosensitive Layer>

### Binder Polymer (A1)

Polyamide acid synthesized in Synthesis Example 5 (in a solid phase) . . . 100 parts by weight

### (Meth)acrylic Compound (B1)

Bisphenol A EO denaturalized di(meth)acrylate (EB150 (commercial name) produced by Daiseru-Cytec Company Ltd.) . . . 10 parts by weight

Bisphenol A EO denaturalized di(meth)acrylate (FA321M (commercial name) produced by Hitachi Chemical Co., Ltd.) . . . 40 parts by weight

### Photoreaction Initiator (C1)

Bis(2,4,6-trimethylbenzoyl)phenylphosphineoxide (IRGACURE 819 produced by Ciba Specialty Chemicals) . . . 2 parts by weight

### Flame Retardant (D1)

Bisphenol A bis (diphenyl) phosphate (CR-741 (commercial name) produced by DAIHACHI CHEMICAL INDUSTRY CO., LTD) . . . 15 parts by weight

### <Organic Solvent Solution Constituting Second Photosensitive Layer>

### Binder Polymer (A2)

Polyamide acid synthesized in Synthesis Example 5 (in a solid phase) . . . 100 parts by weight

### (Meth)acrylic Compound (B2)

Bisphenol A EO denaturalized di(meth)acrylate (FA321M (commercial name) produced by Hitachi Chemical Co., Ltd.) . . . 40 parts by weight

### Photoreaction Initiator (C2)

Bis(2,4,6-trimethylbenzoyl)phenylphosphineoxide (IRGACURE 819 produced by Ciba Specialty Chemicals) . . . 1 part by weight

### <Results of Property Evaluation>

The results of property evaluation carried out with respect to the resultant photosensitive dry film resist are as follows.
Developing property: A square hole of 100 μm×100 μm and a square hole of 200 μm×200 μm were developed without any residue. This is regarded as being proper.
Alkaline solubility: The photosensitive dry film resist was dissolved in 1 wt % of sodium carbonate aqueous solution in 30 seconds.
Resolution: 70 ₁1M
Adhesiveness: Proper
Flame retardant: Proper
Electric reliability: Proper (line/space=100/100 μm: 5.4×10¹¹Ω, line/space=25/25 μm: 5.7×10⁸Ω)
Solder heat resistance: 290° C. This is regarded as being proper.
Tucking property in the B stage state: Free from any tuck.
This is regarded as being proper.
Warpage: 1 mm or less. This is regarded as being proper.

### Example 6

The following components were mixed, and dioxolane was added and evenly dissolved so that its solid content wt % (Sc)=40%, thereby producing an organic solvent solution constituting the first photosensitive layer and an organic solvent solution constituting the second photosensitive layer. The direct application process was carried out so as to produce a photosensitive dry film resist which is in the B stage state and whose first photosensitive layer had the thickness of 20 μm and second photosensitive layer had the thickness of 5 μm.

### <Organic Solvent Solution Constituting First Photosensitive Layer>

### Binder Polymer (A1)

Polyamide acid synthesized in Synthesis Example 6 (in a solid phase) . . . 100 parts by weight

### (Meth)acrylic Compound (B1)

Bisphenol A EO denaturalized di(meth)acrylate (EB150 (commercial name) produced by Daiseru-Cytec Company Ltd.) . . . 20 parts by weight

Bisphenol A EO denaturalized di(meth)acrylate (FA321M (commercial name) produced by Hitachi Chemical Co., Ltd.) . . . 30 parts by weight

### Photoreaction Initiator (C1)

Bis(2,4,6-trimethylbenzoyl)phenylphosphineoxide (IRGACURE 819 produced by Ciba Specialty Chemicals) . . . 2 parts by weight

### Flame Retardant (D1)

Phosphazene compound (SPH-100 (commercial name) produced by Otsuka Chemicals Inc.) . . . 20 parts by weight

### <Organic Solvent Solution Constituting Second Photosensitive Layer>

### Binder Polymer (A2)

Polyamide acid synthesized in Synthesis Example 6 (in a solid phase) . . . 100 parts by weight

### (Meth)acrylic Compound (B2)

Bisphenol A EO denaturalized di(meth)acrylate (EB150 (commercial name) produced by Daiseru-Cytec Company Ltd.) . . . 10 parts by weight

Bisphenol A EO denaturalized di(meth)acrylate (FA321M (commercial name) produced by Hitachi Chemical Co., Ltd.) . . . 20 parts by weight

### Photoreaction Initiator (C2)

Bis(2,4,6-trimethylbenzoyl)phenylphosphineoxide (IRGACURE 819 produced by Ciba Specialty Chemicals) . . . 1 part by weight

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 50 μm
Adhesiveness: Proper
Flame retardant: Proper
Electric reliability: Proper (line/space=100/100 μm: 5.0×10¹¹Ω, line/space=25/25 μm: 4.4×10⁸Ω)
Solder heat resistance: 290° C. This is regarded as being proper.
Tucking property in the B stage state: Free from any tuck.
This is regarded as being proper.
Warpage: 1 mm or less. This is regarded as being proper.

### Example 7

The same operation as in Example 5 was carried out except that polyamide acid synthesized in Synthesis Example 7 was used as the component (A1) of the organic solvent solution constituting the first photosensitive layer resin composition and polyamide acid synthesized in Synthesis Example 7 was used as the component (A2) of the organic solvent solution constituting the second photosensitive layer resin composition, thereby producing a photosensitive dry film resist which is in the B stage state.

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 50 μm
Adhesiveness: Proper
Flame retardant: Proper
Electric reliability: Proper (line/space=100/100 μm: 3.6×10¹¹Ω, line/space=25/25 μm: 2.4×10⁸Ω)
Solder heat resistance: 280° C. This is regarded as being proper.
Tucking property in the B stage state: Free from any tuck.
This is regarded as being proper.
Warpage: 3 mm. This is regarded as being proper.

### Example 8

The same operation as in Example 5 was carried out except that polyamide acid synthesized in Synthesis Example 1 was used as the component (A2) of the organic solvent solution constituting the second photosensitive layer resin composition, thereby producing a photosensitive dry film resist in the B stage state.

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 50 μm
Adhesiveness: Proper
Flame retardant: Proper
Electric reliability: Proper (line/space=100/100 μm: 7.6×10¹¹Ω, line/space=25/25 μm: 4.2×10⁸Ω)
Solder heat resistance: 290° C. This is regarded as being proper.
Tucking property in the B stage state: Free from any tuck.
This is regarded as being proper.
Warpage: 5 mm. This is regarded as being proper.

### Example 9

The same operation as in Example 5 was carried out except that polyamide acid synthesized in Synthesis Example 8 was used, thereby producing a photosensitive dry film resist.

### <Results of Property Evaluation>

The results of property evaluation carried out with respect to the resultant photosensitive dry film resist are as follows.
Developing property: A square hole of 100 μm×100 μm and a square hole of 200 μm×200 μm were developed without any residue. This is regarded as being proper.
Alkaline solubility: The photosensitive dry film resist was dissolved in 1 wt % of sodium carbonate aqueous solution in 30 seconds.
Resolution: 60 μm
Adhesiveness: Proper
Flame retardant: Proper
Electric reliability: Proper (line/space=100/100 μm: 5.9×10¹¹Ω, line/space=25/25 μm: 5.0×10⁸Ω)
Solder heat resistance: 280° C. This is regarded as being proper.
Tucking property in the B stage state: Free from any tuck.
This is regarded as being proper.
Warpage: 1 mm or less. This is regarded as being proper.

### Example 10

The same operation as in Example 5 was carried out except that polyamide acid synthesized in Synthesis Example 9 was used, thereby producing a photosensitive dry film resist.

### <Results of Property Evaluation>

The results of property evaluation carried out with respect to the resultant photosensitive dry film resist are as follows.
Developing property: A square hole of 100 μm×100 μm and a square hole of 200 μm×200 μm were developed without any residue. This is regarded as being proper.
Alkaline solubility: The photosensitive dry film resist was dissolved in 1 wt % sodium carbonate aqueous solution in 30 seconds.
Resolution: 70 μm
Adhesiveness: Proper
Flame retardant: Proper
Electric reliability: Proper (line/space=100/100 μm: 6.4×10¹¹Ω, line/space=25/25 μm: 5.2×10⁸Ω)
Solder heat resistance: 280° C. This is regarded as being proper.
Tucking property in the B stage state: Free from any tuck.
This is regarded as being proper.
Warpage: 1 mm or less. This is regarded as being proper.

### Example 11

The same operation as in Example 5 was carried out except that polyamide acid synthesized in Synthesis Example 10 was used, thereby producing a photosensitive dry film resist.

### <Results of Property Evaluation>

The results of property evaluation carried out with respect to the resultant photosensitive dry film resist are as follows.
Developing property: A square hole of 200 μm×200 μm was developed without any residue. This is regarded as being proper.
Alkaline solubility: The photosensitive dry film resist was dissolved in 1 wt % of sodium carbonate aqueous solution in 30 seconds.
Resolution: 130 μm
Adhesiveness: Proper
Flame retardant: Proper
Electric reliability: Proper (line/space=100/100 μm: 4.4×10¹¹Ω, line/space=25/25 μm: 4.7×10⁸Ω)
Solder heat resistance: 290° C. This is regarded as being proper.
Tucking property in the B stage state: Free from any tuck.
This is regarded as being proper.
Warpage: 4 mm. This is regarded as being proper.

### Example 12

The same operation as in Example 3 was carried out except that the organic solvent solution constituting the first photosensitive layer and the organic solvent solution constituting the second photosensitive layer both of which had been prepared in Example 3 were used and the thickness of the first photosensitive layer was set to 10 μm and the thickness of the first photosensitive layer was set to 15 μm, thereby producing a photosensitive dry film resist in the B stage state.

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 50 μm
Adhesiveness: Proper
Flame retardant: Proper
Electric reliability: Proper (line/space=100/100 μm: 9.0×10¹¹Ω, line/space=25/25 μm: 1.5×10⁹Ω)
Solder heat resistance: 290° C. This is regarded as being proper.
Tucking property in the B stage state: Free from any tuck.
This is regarded as being proper.
Warpage: 1 mm or less. This is regarded as being proper.

### Comparative Example 1

### <Production of Photosensitive Dry Film Resist>

The following components were mixed, and dioxolane was added and evenly dissolved so that its solid content wt % (Sc)=40%, thereby producing an organic solvent solution constituting the first photosensitive layer and an organic solvent solution constituting the second photosensitive layer.

### <Organic Solvent Solution Constituting First Photosensitive Layer>

### Binder Polymer (A1)

Polyurethane resin (FS-141 (commercial name) produced by Dainichiseika Color & Chemicals Mfg. Co., Ltd.) . . . 100 parts by weight

### Flame Retardant (D1)

Phosphazene compound (SPE-100 (commercial name) produced by Otsuka Chemicals Inc.) . . . 50 parts by weight

### <Organic Solvent Solution Constituting Second Photosensitive Layer>

### Binder Polymer (A2)

Polyurethane resin (FS-141 (commercial name) produced by Dainichiseika Color & Chemicals Mfg. Co., Ltd.) . . . 100 parts by weight

### <Results of Property Evaluation>

The results of property evaluation carried out with respect to the resultant photosensitive dry film resist are as follows.
Alkaline solubility: The photosensitive dry film resist was not dissolved in 1 wt % of sodium carbonate aqueous solution even in 180 seconds and was not dissolved in 1 wt % of sodium hydrate aqueous solution even in 180 seconds.
Developing property: Neither a square hole of 100 μm×100 μm nor a square hole of 200 μm×200 μm were developed. This is regarded as being improper.
Resolution: — (failed to develop)
Adhesiveness: Partial exfoliation was found. This is regarded as being improper
Flame retardant: Proper
Warpage: 4 mm. This is regarded as being proper.
Electric reliability: Proper (line/space=100/100 μm: 5.4×108Ω, line/space=25/25 μm: short-circuit occurred in 300 hours)
Solder heat resistance: Swollenness occurred at 260° C.
This is regarded as being improper.
Tucking property in the B stage state: Free from any tuck.
This is regarded as being proper.

In this manner, the developing property cannot be realized by a non-photosensitive material including: a binder polymer (A) having no acid functional group; no (meth)acrylic compound (B); and no photoreaction initiator (C). Further, the non-photosensitive material is inferior in the adhesiveness and the solder heat resist.

### Comparative Example 2

### <Production of Photosensitive Dry Film Resist>

The following components were mixed, and dioxolane was added and evenly dissolved so that its solid content wt % (Sc)=40%, thereby producing an organic solvent solution constituting the first photosensitive layer.

### <Organic Solvent Solution Constituting First Photosensitive Layer>

### Binder Polymer (A1)

Polyamide acid synthesized in Synthesis Example 3 (in a solid phase) . . . 100 parts by weight

### (Meth)acrylic Compound (B1)

Pentaerythtolacrylate (M-305 (commercial name) produced by TOAGOSEI CO., LTD.) . . . 25 parts by weight

Bisphenol A EO denaturalized di(meth)acrylate (FA321M (commercial name) produced by Hitachi Chemical Co., Ltd.) . . . 25 parts by weight

### Photoreaction Initiator (C1)

Bis(2,4,6-trimethylbenzoyl)phenylphosphineoxide (IRGACURE 819 produced by Ciba Specialty Chemicals) . . . 2 parts by weight

### Flame Retardant (D1)

Bisphenol A bis (diphenyl) phosphate (CR-741 (commercial name) produced by DAIHACHI CHEMICAL INDUSTRY CO., LTD) . . . 20 parts by weight

The organic solvent solution constituting the photosensitive resin composition arranged in the foregoing manner was prepared, thereby producing a photosensitive dry film resist which was in the B stage state and whose first photosensitive layer had the thickness of 25 μm and which had no second photosensitive layer.

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 60 seconds.
Developing property: A square hole of 100 μm×100 μm was not developed, but a square hole of 200 μm×200 μm was developed. This is regarded as being proper.
Resolution: 150 μm
Adhesiveness: Proper
Flame retardant: Proper
Warpage: 4 mm. This is regarded as being proper.
Electric reliability: Improper (line/space=100/100 μm: short-circuit occurred in 200 hours, line/space=25/25 μm: short-circuit occurred in 100 hours)
Solder heat resistance: 260° C. This is regarded as being proper.
Tucking property in the B stage state: The photosensitive dry film resist is likely to be tucked. This is regarded as being improper.

In this manner, the photosensitive dry film resist having no second photosensitive layer is inferior in the developing property, the resolution, and the electric reliability, and is likely to be tucked in the B stage state, so that it is difficult to handle the photosensitive dry film resist.

### Comparative Example 3

### <Production of Photosensitive Dry Film Resist>

The following components were mixed, and dioxolane was added and evenly dissolved so that its solid content wt % (Sc)=40%, thereby producing an organic solvent solution constituting the first photosensitive layer and an organic solvent solution constituting the second photosensitive layer. The direct application process was carried out so as to produce a photosensitive dry film resist which is in the B stage state and whose first photosensitive layer had the thickness of 20 μm and second photosensitive layer had the thickness of 5 μm.

### <Organic Solvent Solution Constituting First Photosensitive Layer>

### Binder Polymer (A1)

Polyamide acid synthesized in Synthesis Example 3 (in a solid phase) . . . 100 parts by weight

### (Meth)acrylic Compound (B1)

Pentaerythtolacrylate (M-305 (commercial name) produced by TOAGOSEI CO., LTD.) . . . 40 parts by weight

Bisphenol A EO denaturalized di(meth)acrylate (FA321M (commercial name) produced by Hitachi Chemical Co., Ltd.) . . . 10 parts by weight

### Photoreaction Initiator (C1)

Bis(2,4,6-trimethylbenzoyl)phenylphosphineoxide (IRGACURE 819 produced by Ciba Specialty Chemicals) . . . 2 parts by weight

### <Organic Solvent Solution Constituting Second Photosensitive Layer>

### Binder Polymer (A2)

Polyamide acid synthesized in Synthesis Example 3 (in a solid phase) 100 parts by weight

### (Meth)acrylic Compound (B2)

Pentaerythritolacrylate (M-305 (commercial name) produced by TOAGOSEI CO., LTD.) . . . 20 parts by weight

### Photoreaction Initiator (C2)

Bis(2,4,6-trimethylbenzoyl)phenylphosphineoxide (IRGACURE 819 produced by Ciba Specialty Chemicals) . . . 1 part by weight

### Flame Retardant (D2)

Bisphenol A bis (diphenyl) phosphate (CR-741 (commercial name) produced by DAIHACHI CHEMICAL INDUSTRY CO., LTD) . . . 30 parts by weight

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 60 seconds.
Developing property: In an aperture of each of a square hole of 100 μm×100 μm and a square hole of 200 μm×200 μm, a residue occurred. This is regarded as being improper.
Resolution: — (failed to develop)
Adhesiveness: Proper
Flame retardant: Improper
Warpage: 5 mm. This is regarded as being proper.
Electric reliability: Improper (line/space=100/100 μm: short-circuit occurred in 100 hours, line/space=25/25 μm: short-circuit occurred in 50 hours)
Solder heat resistance: 260° C. This is regarded as being proper.
Tucking property in the B stage state: The photosensitive dry film resist was slightly tucked. This is regarded as being proper.

In this manner, the multi-layer structure arranged so that the first photosensitive layer does not contain the flame retardant and the second photosensitive layer contains the flame retardant is inferior in the developing property, the resolution, the flame retardancy, and the electric reliability.

### Comparative Example 4

The same operation as in Example 4 was carried out except that the thickness of the first photosensitive layer was 25 μm and the second photosensitive layer was not provided, thereby producing a photosensitive dry film resist.

### <Results of Property Evaluation>

The results of property evaluation carried out with respect to the resultant photosensitive dry film resist are as follows.
Alkaline solubility: The photosensitive dry film resist was not dissolved in 1 wt % of sodium carbonate aqueous solution even in 180 seconds. The photosensitive dry film resist was dissolved in 1 wt % of sodium hydrate aqueous solution in 60 seconds.
Developing property: In an aperture of each of a square hole of 100 μm×100 μm and a square hole of 200 μm×200 μm, a residue occurred. This is regarded as being improper.
Resolution: — (failed to develop)
Adhesiveness: Improper
Flame retardant: Proper
Warpage: 4 mm. This is regarded as being proper.
Electric reliability: Improper (line/space=100/100 μm: short-circuit occurred in 200 hours, line/space=25/25 μm: short-circuit occurred in 50 hours)
Solder heat resistance: 290° C. This is regarded as being proper.
Tucking property in the B stage state: The photosensitive dry film resist was slightly tucked. This is regarded as being proper.

In this manner, the photosensitive dry film resist which does not have the second photosensitive layer is inferior in the developing property, the adhesiveness , and the electric reliability, and is likely to be tucked in the B stage state.

### Comparative Example 5

The same operation as in Example 5 was carried out except that polyamide acid synthesized in Synthesis Example 1 was used as the component (A1) of the organic solvent solution constituting the first photosensitive layer resin composition, thereby producing a photosensitive dry film resist which is in the B stage state and whose first photosensitive layer had the thickness of 25 μm and second photosensitive layer had the thickness of 0 μm (the second photosensitive layer was not provided).

### <Results of Property Evaluation>

The results of property evaluation carried out with respect to the resultant photosensitive dry film resist are as follows.
Alkaline solubility: The photosensitive dry film resist was dissolved in 1 wt % of sodium carbonate aqueous solution in 30 seconds.
Developing property: A square hole of 100 μm×100 μm and a square hole of 200 μm×200 μm were developed without any residue. This is regarded as being proper.
Resolution: 180 μm
Adhesiveness: Proper
Flame retardant: Proper
Electric reliability: Improper (line/space=100/100 μm: short-circuit occurred in 350 hours, line/space=25/25 μm: short-circuit occurred in 150 hours)
Solder heat resistance: 280° C. This is regarded as being proper.
Tucking property in the B stage state: Free from any tuck.
This is regarded as being proper.
Warpage: In a cylindrical manner. This is regarded as being improper.

The blending conditions and thickness settings of Examples are shown in Tables 1 to 3. The blending conditions and thickness settings of Comparative Examples are shown in Table 4. The results of property evaluation are shown in Tables 5 to 7.

TABLE 1

| | | | Ex. 1 | Ex. 2 | Ex. 3 | Ex. 4 |
|---|---|---|---|---|---|---|
| First photosensitive | (A1) | vinyl polymer | 100 | | | |
| layer Components | | containing | | | | |
| | | carboxyl group | | | | |
| | | (parts by weight) | | | | |
| | | polyamide acid | | (Syn. Ex. 1) | (Syn. Ex. 2) | |
| | | (parts by weight) | | 100 | 100 | |
| | | soluble polyimide | | | | (Syn. Ex. 4) |
| | | containing | | | | 100 |
| | | carboxyl group | | | | |
| | | (parts by weight) | | | | |
| | | polyurethane resin | | | | |
| | | (parts by weight) | | | | |
| | (B1) | (meth)acrylic compound | 40 | 50 | 50 | 50 |
| | | (parts by weight) | | | | |
| | (C1) | photoreaction initiator | 1 | 2 | 2 | 2 |
| | | (parts by weight) | | | | |
| | (D1) | Flame retardant | 30 | 15 | 20 | 15 |
| | | (parts by weight) | | | | |
| Second photosensitive | (A2) | vinyl polymer | 100 | | | |
| layer Components | | containing | | | | |
| | | carboxyl group | | | | |
| | | (parts by weight) | | | | |
| | | polyamide acid | | (Syn. Ex. 1) | (Syn. Ex. 2) | |
| | | (parts by weight) | | 100 | 100 | |
| | | soluble polyimide | | | | (Syn. Ex. 4) |
| | | containing | | | | 100 |
| | | carboxyl group | | | | |
| | | (parts by weight) | | | | |
| | | polyurethane resin | | | | |
| | | (parts by weight) | | | | |
| | (B2) | (meth)acrylic compound | 40 | 40 | 30 | 50 |
| | | (parts by weight) | | | | |
| | (C2) | photoreaction initiator | 1 | 1 | 1 | 2 |
| | | (parts by weight) | | | | |
| | (D2) | Flame retardant | | | | |
| | | (parts by weight) | | | | |
| | (E2) | other component | | | | 11 |
| | | (parts by weight) | | | | |

| Thickness | First photosensitive | 20 | 20 | 20 | 20 |
|---|---|---|---|---|---|
| | layer thickness | | | | |
| | (μm) | | | | |
| | Second photosensitive | 5 | 5 | 5 | 5 |
| | layer thickness | | | | |
| | (μm) | | | | |

TABLE 2

| | | | Ex. 5 | Ex. 6 | Ex. 7 | Ex. 8 |
|---|---|---|---|---|---|---|
| First photosensitive | (A1) | vinyl polymer | | | | |
| layer Components | | containing | | | | |
| | | carboxyl group | | | | |
| | | (parts by weight) | | | | |
| | | polyamide acid | (Syn. Ex. 5) | (Syn. Ex. 6) | (Syn. Ex. 7) | (Syn. Ex. 5) |
| | | (parts by weight) | 100 | 100 | 100 | 100 |
| | | soluble polyimide | | | | |
| | | containing | | | | |
| | | carboxyl group | | | | |
| | | (parts by weight) | | | | |
| | | polurethane resin | | | | |
| | | (parts by weight) | | | | |
| | (B1) | (meth)acrylic compound | 50 | 50 | 50 | 50 |
| | | (parts by weight) | | | | |
| | (C1) | photoreaction initiator | 2 | 2 | 2 | 2 |
| | | (parts by weight) | | | | |
| | (D1) | Flame retardant | 15 | 20 | 20 | 15 |
| | | (parts by weight) | | | | |
| Second photosensitive | (A2) | vinyl polymer | | | | |
| layer Components | | containing | | | | |
| | | carboxyl group | | | | |
| | | (parts by weight) | | | | |
| | | polyamide acid | (Syn. Ex. 5) | (Syn. Ex. 6) | (Syn. Ex. 7) | (Syn. Ex. 1) |
| | | (parts by weight) | 100 | 100 | 100 | 100 |
| | | soluble polyimide | | | | |
| | | containing | | | | |
| | | carboxyl group | | | | |
| | | (parts by weight) | | | | |
| | | polurethane resin | | | | |
| | | (parts by weight) | | | | |
| | (B2) | (meth)acrylic compound | 40 | 30 | 30 | 40 |
| | | (parts by weight) | | | | |
| | (C2) | photoreaction initiator | 1 | 1 | 1 | 1 |
| | | (parts by weight) | | | | |
| | (D2) | Flame retardant | | | | |
| | | (parts by weight) | | | | |
| | (E2) | other component | | | | |
| | | (parts by weight) | | | | |

| Thickness | First photosensitive | 20 | 20 | 20 | 20 |
|---|---|---|---|---|---|
| | layer thickness | | | | |
| | (μm) | | | | |
| | Second photosensitive | 5 | 5 | 5 | 5 |
| | layer thickness | | | | |
| | (μm) | | | | |

TABLE 3

| | | | Ex. 9 | Ex. 10 | Ex. 11 | Ex. 12 |
|---|---|---|---|---|---|---|
| First photosensitive | (A1) | vinyl polymer | | | | |
| layer Components | | containing | | | | |
| | | carboxyl group | | | | |
| | | (parts by weight) | | | | |
| | | polyamide acid | (Syn. Ex. 8) | (Syn. Ex. 9) | (Syn. Ex. 10) | (Syn. Ex. 2) |
| | | (parts by weight) | 100 | 100 | 100 | 100 |
| | | soluble polyimide | | | | |
| | | containing | | | | |
| | | carboxyl group | | | | |
| | | (parts by weight) | | | | |
| | | polurethane resin | | | | |
| | | (parts by weight) | | | | |
| | (B1) | (meth)acrylic compound | 50 | 50 | 50 | 50 |
| | | (parts by weight) | | | | |
| | (C1) | photoreaction initiator | 2 | 2 | 2 | 2 |
| | | (parts by weight) | | | | |
| | (D1) | Flame retardant | 15 | 15 | 15 | 20 |
| | | (parts by weight) | | | | |
| Second photosensitive | (A2) | vinyl polymer | | | | |
| layer Components | | containing | | | | |
| | | carboxyl group | | | | |
| | | (parts by weight) | | | | |
| | | polyamide acid | (Syn. Ex. 8) | (Syn. Ex. 9) | (Syn. Ex. 10) | (Syn. Ex. 2) |
| | | (parts by weight) | 100 | 100 | 100 | 100 |
| | | soluble polyimide | | | | |
| | | containing | | | | |
| | | carboxyl group | | | | |
| | | (parts by weight) | | | | |
| | | polurethane resin | | | | |
| | | (parts by weight) | | | | |
| | (B2) | (meth)acrylic compound | 40 | 40 | 40 | 30 |
| | | (parts by weight) | | | | |
| | (C2) | photoreaction initiator | 1 | 1 | 1 | 1 |
| | | (parts by weight) | | | | |
| | (D2) | Flame retardant | | | | |
| | | (parts by weight) | | | | |
| | (E2) | other component | | | | |
| | | (parts by weight) | | | | |

| Thickness | First photosensitive | 20 | 20 | 20 | 10 |
|---|---|---|---|---|---|
| | layer thickness | | | | |
| | (μm) | | | | |
| | Second photosensitive | 5 | 5 | 5 | 15 |
| | layer thickness | | | | |
| | (μm) | | | | |

TABLE 4

| | | | C. Ex. 1 | C. Ex. 2 | C. Ex. 3 | C. Ex. 4 | C. Ex. 5 |
|---|---|---|---|---|---|---|---|
| First photosensitive | (A1) | vinyl polymer | | | | | |
| layer Components | | containing | | | | | |
| | | carboxyl group | | | | | |
| | | (parts by weight) | | | | | |
| | | polyamide acid | | (Syn. Ex. 3) | (Syn. Ex. 3) | | (Syn. Ex. 1) |
| | | (parts by weight) | | 100 | 100 | | 100 |
| | | soluble polyimide | | | | (Syn. Ex. 4) | |
| | | containing | | | | 100 | |
| | | carboxyl group | | | | | |
| | | (parts by weight) | | | | | |
| | | polyurethane resin | 100 | | | | |
| | | (parts by weight) | | | | | |
| | (B1) | (meth)acrylic compound | | 50 | 50 | 50 | 50 |
| | | (parts by weight) | | | | | |
| | (C1) | photoreaction initiator | | 2 | 2 | 2 | 2 |
| | | (parts by weight) | | | | | |
| | (D1) | Flame retardant | 50 | 20 | | 15 | 15 |
| | | (parts by weight) | | | | | |
| Second photosensitive | (A2) | vinyl polymer | | | | | |
| layer Components | | containing | | | | | |
| | | carboxyl group | | | | | |
| | | (parts by weight) | | | | | |
| | | polyamide acid | | | (Syn. Ex. 3) | | |
| | | (parts by weight) | | | 100 | | |
| | | soluble polyimide | | | | | |
| | | containing | | | | | |
| | | carboxyl group | | | | | |
| | | (parts by weight) | | | | | |
| | | polurethane resin | 100 | | | | |
| | | (parts by weight) | | | | | |
| | (B2) | (meth)acrylic compound | | | 20 | | |
| | | (parts by weight) | | | | | |
| | (C2) | photoreaction initiator | | | 1 | | |
| | | (parts by weight) | | | | | |
| | (D2) | Flame retardant | | | 30 | | |
| | | (parts by weight) | | | | | |
| | (E2) | other component | | | | | |
| | | (parts by weight) | | | | | |

| Thickness | First photosensitive | 20 | 25 | 20 | 25 | 25 |
|---|---|---|---|---|---|---|
| | layer thickness | | | | | |
| | (μm) | | | | | |
| | Second photosensitive | 5 | 0 | 5 | 0 | 0 |
| | layer thickness | | | | | |
| | (μm) | | | | | |

TABLE 5

| | Ex. 1 | Ex. 2 | Ex. 3 | Ex. 4 | Ex. 5 | Ex. 6 |
|---|---|---|---|---|---|---|
| Alcali | Sodium carbonate | Sodium carbonate | Sodium carbonate | Sodium hydroxide | Sodium carbonate | Sodium carbonate |
| solubility | aqueous solution | aqueous solution | aqueous solution | aqueous solution | aqueous solution | aqueous solution |
| | 30 second | 30 second | 30 second | 30 second | 30 second | 30 second |
| Developing | Proper | Proper | Proper | Proper | Proper | Proper |
| property | | | | | | |
| Resolution | 70 μm | 70 μm | 50 μm | 90 μm | 70 μm | 50 μm |
| Adhesiveness | Proper | Proper | Proper | Proper | Proper | Proper |
| Flame | Proper | Proper | Proper | Proper | Proper | Proper |
| retardancy | | | | | | |
| Electric | Proper | Proper | Proper | Proper | Proper | Proper |
| reliability | | | | | | |
| Resistance: | 1.7 × 10⁸Ω | 5.4 × 10¹¹Ω | 5.6 × 10¹¹Ω | 5.7 × 10⁸Ω | 5.4 × 10¹¹Ω | 5.0 × 10¹¹Ω |
| (line/space = | | | | | | |
| 100/100 μm) | | | | | | |
| Resistance: | 4.5 × 10⁶Ω | 3.7 × 10⁸Ω | 5.4 × 10⁸Ω | 3.4 × 10⁶Ω | 5.7 × 10⁸Ω | 4.4 × 10⁸Ω |
| (line/space = | | | | | | |
| 25/25 μm) | | | | | | |
| Solder heat | Proper | Proper | Proper | Proper | Proper | Proper |
| resistance | (260° C.) | (290° C.) | (290° C.) | (300° C.) | (290° C.) | (290° C.) |
| Tucking | Proper | Proper | Proper | Proper | Proper | Proper |
| property in B | (tuck-free) | (tuck-free) | (tuck-free) | (tuck-free) | (tuck-free) | (tuck-free) |
| stage state | | | | | | |
| Warpage | Proper | Improper | Proper | Proper | Proper | Proper |
| | 4 mm | Cylindrical | 1 mm or less | 3 mm | 1 mm or less | 1 mm or less |
| | | manner | | | | |

TABLE 6

| | Ex. 7 | Ex. 8 | Ex. 9 | Ex. 10 | Ex. 11 | Ex. 12 |
|---|---|---|---|---|---|---|
| Alcali | Sodium carbonate | Sodium carbonate | Sodium carbonate | Sodium carbonate | Sodium carbonate | Sodium carbonate |
| solubility | aqueous solution | aqueous solution | aqueous solution | aqueous solution | aqueous solution | aqueous solution |
| | 30 second | 30 second | 30 second | 30 second | 30 second | 30 second |
| Developing | Proper | Proper | Proper | Proper | Proper | Proper |
| property | | | | | | |
| Resolution | 50 μm | 50 μm | 60 μm | 70 μm | 130 μm | 50 μm |
| Adhesiveness | Proper | Proper | Proper | Proper | Proper | Proper |
| Flame | Proper | Proper | Proper | Proper | Proper | Proper |
| retardancy | | | | | | |
| Electric | Proper | Proper | Proper | Proper | Proper | Proper |
| reliability | | | | | | |
| Resistance: | 3.6 × 10¹¹Ω | 7.6 × 10¹¹Ω | 5.9 × 10¹¹Ω | 6.4 × 10¹¹Ω | 4.4 × 10¹¹Ω | 9.0 × 10¹¹Ω |
| (line/space = | | | | | | |
| 100/100 μm) | | | | | | |
| Resistance: | 2.4 × 10⁸Ω | 4.2 × 10⁸Ω | 5.0 × 10⁸Ω | 5.2 × 10⁸Ω | 4.7 × 10⁸Ω | 1.5 × 10⁹Ω |
| (line/space = | | | | | | |
| 25/25 μm) | | | | | | |
| Solder heat | Proper | Proper | Proper | Proper | Proper | Proper |
| resistance | (280° C.) | (290° C.) | (280° C.) | (280° C.) | (290° C.) | (290° C.) |
| Tucking | Proper | Proper | Proper | Proper | Proper | Proper |
| property in B | (tuck-free) | (tuck-free) | (tuck-free) | (tuck-free) | (tuck-free) | (tuck-free) |
| stage state | | | | | | |
| Warpage | Proper | Proper | Proper | Proper | Proper | Proper |
| | 3 mm | 5 mm | 1 mm or less | 1 mm or less | 4 mm | 1 mm or less |

TABLE 7

| | C. Ex. 1 | C. Ex. 2 | C. Ex. 3 | C. Ex. 4 | C. Ex. 5 |
|---|---|---|---|---|---|
| Alcali | Improper (not | Sodium carbonate | Sodium carbonate | Sodium hydroxide | Sodium carbonate |
| solubility | dissolved) | aqueous solution | aqueous solution | aqueous solution | aqueous solution |
| | | 60 second | 60 second | 60 second | 30 second |
| Developing | Improper | Proper | Improper | Improper | Proper |
| property | | | | | |
| Resolution | — (not | 150 μm | — (not | — (not | 180 μm |
| | developed) | | developed) | developed) | |
| Adhesiveness | Improper | Proper | Proper | Improper | Proper |
| Flame | Proper | Proper | Improper | Proper | Proper |
| retardancy | | | | | |
| Electric | Proper | Improper | Improper | Improper | Improper |
| reliability | | | | | |
| Resistance: | 5.4 × 10⁸Ω | Short-circuit | Short-circuit | Short-circuit | Short-circuit |
| (line/space = | | occurred in | occurred in | occurred in | occurred in |
| 100/100 μm) | | 200 hours | 100 hours | 200 hours | 350 hours |
| Resistance: | Short-circuit | Short-circuit | Short-circuit | Short-circuit | Short-circuit |
| (line/space = | occurred in | occurred in | occurred in | occurred in | occurred in |
| 25/25 μm) | 300 hours | 100 hours | 50 hours | 50 hours | 150 hours |
| Solder heat | Improper | Proper | Proper | Proper | Proper |
| resistance | (lower than | (260° C.) | (260° C.) | (290° C.) | (280° C.) |
| | 260° C.) | | | | |
| Tucking | Proper | Improper | Proper | Proper | Proper |
| property in B | (tuck-free) | (likely to | (slightly | (slightly | (tuck-free) |
| stage state | | be tucked) | tucked) | tucked) | |
| Warpage | Proper | Proper | Proper | Proper | Improper |
| | 4 mm | 4 mm | 5 mm | 4 mm | Cylindrical |
| | | | | | manner |

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

As described above, the photosensitive dry film resist according to the present invention has a multi-layer structure which includes at least: a first photosensitive layer containing a flame retardant; and a second photosensitive layer containing no or a small amount of flame retardant. Thus, unlike a conventional single-layer structure, it is possible to realize a photosensitive dry film resist whose flame retardancy, electric reliability, and photosensitivity are improved and which is excellent in a water system developing property, resolution, flame retardancy, adhesiveness, moisture resistance, and electric reliability. Therefore, the photosensitive dry film resist according to the present invention is applicable to a field for producing various kinds of resin molding products such as a film or a laminate containing photosensitive polyimide. Furthermore, the photosensitive dry film resist is widely applicable also to a field related to production of an electronic component using such film or laminate.

1. A multi-layer photosensitive dry film resist, comprising at least:
a first photosensitive layer which essentially includes
a binder polymer (A1),
a (meth)acrylic compound (B1),
a photoreaction initiator (C1), and
a flame retardant (D1); and
a second photosensitive layer which essentially includes
a binder polymer (A2), and
a (meth)acrylic compound (B2),
and which substantially does not include a flame retardant (D2), wherein:
when a weight ratio of the flame retardant (D1) to an entire weight of the first photosensitive layer is defined as a first photosensitive layer flame retardant content and a weight ratio of the flame retardant (D2) to an entire weight of the second photosensitive layer is defined as a second photosensitive layer flame retardant content, the second photosensitive layer flame retardant content is 0 wt % or more and 10 wt % or less, and in case where the first photosensitive layer flame retardant content is 100, the second photosensitive layer flame retardant content is 0 or more and 50 or less.

2. The multi-layer photosensitive dry film resist as set forth in claim 1, wherein the second photosensitive layer further includes a photoreaction initiator (C2) as an essential component.

3. The multi-layer photosensitive dry film resist as set forth in claim 1, wherein the second photosensitive layer is an outermost layer of a multi-layer structure.

4. The multi-layer photosensitive dry film resist as set forth in claim 1, wherein a phosphorus compound is used as the flame retardant (D1) and/or the flame retardant (D2).

5. The multi-layer photosensitive dry film resist as set forth in claim 1, wherein vinyl polymer containing carboxyl group is used as the binder polymer (A1) and/or the binder polymer (A2).

6. The multi-layer photosensitive dry film resist as set forth in claim 1, wherein polyamide acid is used as the binder polymer (A1) and/or the binder polymer (A2).

7. The multi-layer photosensitive dry film resist as set forth in claim 1, wherein polyamide acid partially made of polysiloxane diamine represented by formula (1) is used as the binder polymer (A1) and/or the binder polymer (A2), 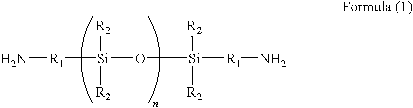
where each R₁ independently represents a hydrocarbon whose carbon number is 1 to 5, and each R₂ independently represents an organic group selected from an alkyl group whose carbon number is 1 to 5 and a phenyl group, and n represents an integer from 1 to 20.

8. The multi-layer photosensitive dry film resist as set forth in claim 1, wherein polyamide acid having a constitutional unit represented by formula (2) and a constitutional unit represented by formula (3) is used as the binder polymer (A1) and/or the binder polymer (A2), 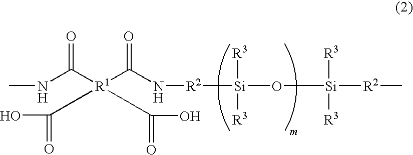
where R¹ represents a tetravalent organic group, each R² independently represents an alkylene group whose carbon number is 2 to 5, and each R³ independently represents a methyl group or a phenyl group, and a content of the phenyl group in R³ is 15% or more and 40% or less, and m is an integer of 4 or more and 20 or less, 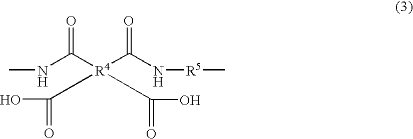
where R⁴ represents a tetravalent organic group, and R⁵ represents a bivalent organic group obtained by excluding two amino groups from aromatic diamine.

9. The multi-layer photosensitive dry film resist as set forth in claim 8, wherein the polyamide acid further has a structure represented by formula (4) 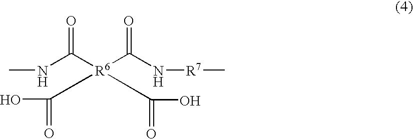
where R⁶ represents a tetravalent organic group and R⁷ has a constitutional unit represented by formula a, b, c, d, e, f, or g, 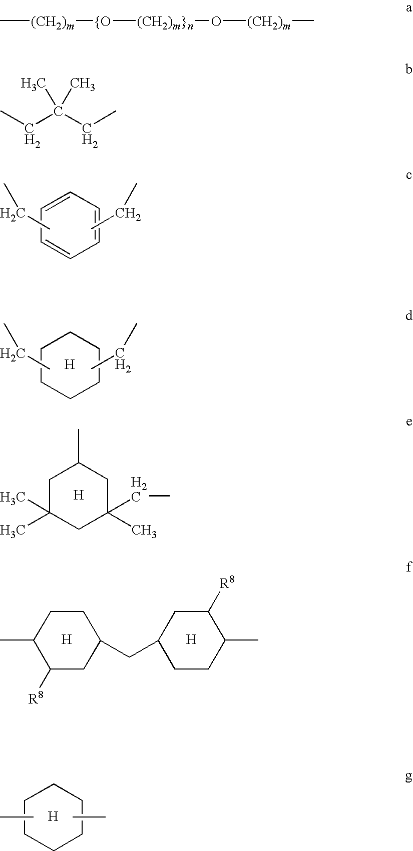
where m of the formula a represents an integer ranging from 1 to 20, n of the formula a represents an integer ranging from 0 to 10, R⁸ of the formula f represents a hydrogen atom, a methyl group, an ethyl group, or a butyl group.

10. The multi-layer photosensitive dry film resist as set forth in claim 1, wherein polyamide acid having a constitutional unit represented by formula (4) and a constitutional unit represented by formula (3) is used as the binder polymer (A1) and/or the binder polymer (A2), 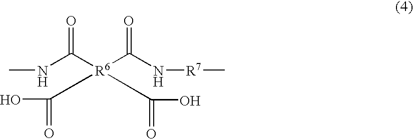
where R⁶ represents a tetravalent organic group and R⁷ has a constitutional unit represented by formula a, b, c, d, e, f, or g, 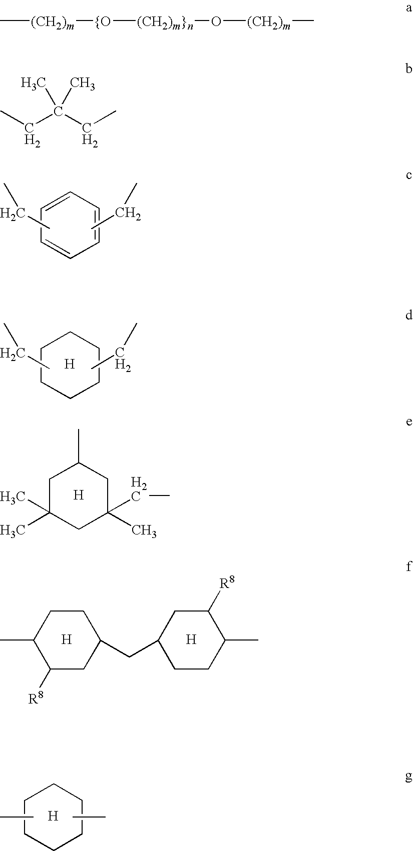
where m of the formula a represents an integer ranging from 1 to 20, n of the formula a represents an integer ranging from 0 to 10, R⁸ of the formula f represents a hydrogen atom, a methyl group, an ethyl group, or a butyl group, 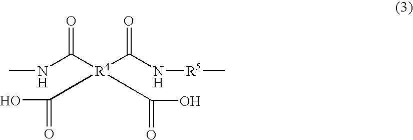
where R⁴ represents a tetravalent organic group, and R⁵ represents a bivalent organic group obtained by excluding two amino groups from aromatic diamine.

11. The multi-layer photosensitive dry film resist as set forth in claim 8, wherein the constitutional unit represented by the formula (3) includes a constitutional unit in which at least one of aromatic rings bound to the two amino groups of the aromatic diamine in R⁵ of the formula (3) has two bonds at a meta position with respect to a main chain.

12. The multi-layer photosensitive dry film resist as set forth in claim 8, wherein the aromatic diamine is m-phenylene diamine, 3,3′-diaminodiphenylmethane, 3,3′-diaminodiphenylether, 3,3′-diaminodiphenylsulfide, 3,3′-diaminodiphenylsulfone, 3,3′-diamino benzanilide, 2,2-bis (3-aminophenyl)hexafluoropropane, 2,2-bis[4-(3-aminophenoxy)phenyl]propane, 2,2-bis[4-(3-aminophenoxy)phenyl]sulfone, 2,2-bis[4-(3-aminophenoxy)phenyl]hexafluoropropane, 1,4-bis(3-aminophenoxy)benzene, 4,4′-bis(3-aminophenoxy)-biphenyl, 1,3-bis(3-aminophenoxy)benzene, bis[4-(3-aminophenoxy)phenyl]sulfone, or 2,2-bis(3-aminophenyl)propane.

13. The multi-layer photosensitive dry film resist as set forth in claim 1, wherein soluble polyimide containing carboxyl group and/or hydroxyl group is used as the binder polymer (A1) and/or the binder polymer (A2).

14. The multi-layer photosensitive dry film resist as set forth in claim 1, wherein soluble polyimide containing carboxyl group and/or hydroxyl group which soluble polyimide is partially made of polysiloxane diamine represented by formula (1) is used as the binder polymer (A1) and/or the binder polymer (A2), 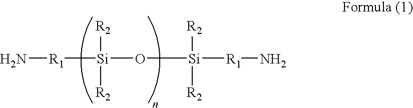
where each R₁ independently represents a hydrocarbon whose carbon number is 1 to 5, and each R₂ independently represents an organic group selected from an alkyl group whose carbon number is 1 to 5 and a phenyl group, and n represents an integer from 1 to 20.

15. The multi-layer photosensitive dry film resist as set forth in claim 1, wherein: when a thickness of the first photosensitive layer is regarded as 100, a thickness of the second photosensitive layer is 500 or less.

16. A printed wiring board, comprising as an insulating protection layer the multi-layer photosensitive dry film resist as set forth in claim 1.

17. The printed wiring board as set forth in claim 16, wherein the photosensitive dry film resist is such that the second photosensitive layer serves as an outermost layer which is in contact with a circuit face and the first photosensitive layer serves as the other outermost layer.

18. A method for producing a printed wiring board, comprising the step of curing the photosensitive dry film resist as set forth in claim 1 at 180° C. or lower so as to form an insulating protection layer.

19. The multi-layer photosensitive dry film resist as set forth in claim 10, wherein the constitutional unit represented by the formula (3) includes a constitutional unit in which at least one of aromatic rings bound to the two amino groups of the aromatic diamine in R⁵ of the formula (3) has two bonds at a meta position with respect to a main chain.

20. The multi-layer photosensitive dry film resist as set forth in claim 10, wherein the aromatic diamine is m-phenylene diamine, 3,3′-diaminodiphenylmethane, 3,3′-diaminodiphenylether, 3,3′-diaminodiphenylsulfide, 3,3′-diaminodiphenylsulfone, 3,3′-diamino benzanilide, 2,2-bis(3-aminophenyl)hexafluoropropane, 2,2-bis[4-(3-aminophenoxy)phenyl]propane, 2,2-bis[4-(3-aminophenoxy)phenyl]sulfone, 2,2-bis[4-(3-aminophenoxy)phenyl]hexafluoropropane, 1,4-bis(3-aminophenoxy)benzene, 4,4′-bis(3-aminophenoxy)-biphenyl, 1,3-bis(3-aminophenoxy)benzene, bis[4-(3-aminophenoxy)phenyl]sulfone, or 2,2-bis(3-aminophenyl)propane.
